(19) United States
(12) Patent Application Publication
(10) Pub. No.: US 2024/0206216 A1
(43) Pub. Date: Jun. 20, 2024

(54) Display Apparatus and Method For Manufacturing Display Apparatus

(71) Applicant: Semiconductor Energy Laboratory Co., Ltd., Kanagawa-ken (JP)

(72) Inventors: Daisuke KUBOTA, Atsugi, Kanagawa (JP); Akio YAMASHITA, Atsugi, Kanagawa (JP); Taisuke KAMADA, Niiza, Saitama (JP); Daiki NAKAMURA, Atsugi, Kanagawa (JP)

(73) Assignee: Semiconductor Energy Laboratory Co., Ltd., Kanagawa-ken (JP)

(21) Appl. No.: 18/288,333

(22) PCT Filed: Apr. 18, 2022
(86) PCT No.: PCT/IB2022/053598

§ 371 Date: Oct. 25, 2023

(30) Foreign Application Priority Data
Apr. 30, 2021 (JP) 2021-077918

(51) Int. Cl. H10K 50/13; H10K 50/15; H10K 50/16; H10K 71/20

(52) U.S. Cl. CPC H10K 50/13; H10K 50/156; H10K 50/166; H10K 71/231

(57) ABSTRACT

A display apparatus that has a light detection function and has a light detection function with high accuracy is provided. The display apparatus includes a light-receiving device and a first light-emitting device. The light-receiving device includes a first electrode, a light-receiving layer, and a common electrode that are stacked in this order. The first light-emitting device includes a second electrode, a first EL layer, and the common electrode that are stacked in this order. The light-receiving layer includes a first layer, a second layer, and an active layer between the first layer and the second layer. The first layer contains a first substance having a hole-transport property, and the second layer contains a second substance having an electron-transport property. An end portion of the active layer, an end portion of the first layer, and an end portion of the second layer are aligned or substantially aligned with one another. The first EL layer includes a third layer, a fourth layer, and a first light-emitting layer between the third layer and the fourth layer. The third layer contains a third substance having a hole-transport property, and the fourth layer contains a fourth substance having an electron-transport property.

### TECHNICAL FIELD

One embodiment of the present invention relates to a display apparatus. One embodiment of the present invention relates to a method for manufacturing a display apparatus.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a fabricating method thereof. A semiconductor device refers to any device that can function by utilizing semiconductor characteristics.

### BACKGROUND ART

In recent years, display apparatuses have been used in a variety of devices such as information terminal devices such as smartphones, tablet terminals, and laptop PCs, television devices, and monitor devices. In addition, display apparatuses have been required to have a variety of functions such as a touch sensor function and a function of capturing images of fingerprints for authentication, in addition to a function of displaying images.

Light-emitting apparatuses including light-emitting devices (also referred to as light-emitting elements) have been developed as display apparatuses, for example. Light-emitting devices (also referred to as EL devices or EL elements) utilizing electroluminescence (EL) have features such as ease of reduction in thickness and weight, high-speed response to input signals, and driving with a constant DC voltage power source, and have been used in display apparatuses. For example, Patent Document 1 discloses a flexible light-emitting apparatus using an organic EL device (also referred to as organic EL element).

### REFERENCE

### Patent Document

[Patent Document 1] Japanese Published Patent Application No. 2014-197522

### SUMMARY OF THE INVENTION

### Problems to be Solved by the Invention

An object of one embodiment of the present invention is to provide a high-resolution display apparatus having a light detection function. An object of one embodiment of the present invention is to provide a display apparatus having a light detection function with high accuracy. An object of one embodiment of the present invention is to provide a display apparatus having a light detection function and low power consumption. An object of one embodiment of the present invention is to provide a highly reliable display apparatus having a light detection function. An object of one embodiment of the present invention is to provide a novel display apparatus.

Note that the description of these objects does not preclude the existence of other objects. Note that one embodiment of the present invention does not have to achieve all of these objects. Note that other objects can be derived from the description of the specification, the drawings, the claims, and the like.

### Means for Solving the Problems

One embodiment of the present invention is a display apparatus including a light-receiving device and a first light-emitting device. The light-receiving device includes a first electrode, a light-receiving layer, and a common electrode that are stacked in this order. The first light-emitting device includes a second electrode, a first EL layer, and the common electrode that are stacked in this order. The light-receiving layer includes a first layer, a second layer, and an active layer between the first layer and the second layer. The first layer contains a first substance having a hole-transport property, and the second layer contains a second substance having an electron-transport property. An end portion of the active layer, an end portion of the first layer, and an end portion of the second layer are aligned or substantially aligned with one another. The first EL layer includes a third layer, a fourth layer, and a first light-emitting layer between the third layer and the fourth layer. The third layer contains a third substance having a hole-transport property, and the fourth layer contains a fourth substance having an electron-transport property. An end portion of the first light-emitting layer is positioned inward from an end portion of the third layer and positioned inward from an end portion of the fourth layer.

In the display apparatus, the active layer preferably includes a region overlapping with the first electrode with the first layer therebetween.

In the display apparatus, the active layer preferably includes a region overlapping with the first electrode with the second layer therebetween.

In the display apparatus, the first light-emitting layer preferably includes a region overlapping with the second electrode with the third layer therebetween.

In the display apparatus, the first light-emitting layer preferably includes a region overlapping with the second electrode with the fourth layer therebetween.

In the display apparatus, the end portion of the third layer and the end portion of the fourth layer are preferably aligned or substantially aligned with each other.

In the display apparatus, the first substance preferably differs from the third substance.

In the display apparatus, the second substance preferably differs from the fourth substance.

In the display apparatus, the active layer preferably contains a fifth substance, and the first light-emitting layer preferably contains a sixth substance differing from the fifth substance.

The display apparatus preferably includes a second light-emitting device. The second light-emitting device preferably includes a third electrode, a second EL layer, and the common electrode that are stacked in this order. The second EL layer preferably includes the third layer, the fourth layer, and a second light-emitting layer between the third layer and the fourth layer.

The display apparatus preferably includes a second light-emitting device. The second light-emitting device preferably includes a third electrode, a second EL layer, and the common electrode that are stacked in this order. The second EL layer preferably includes a fifth layer, a sixth layer, and a second light-emitting layer between the fifth layer and the sixth layer. The fifth layer preferably contains the third substance, and the sixth layer preferably contains the fourth substance.

In the display apparatus, the second light-emitting layer preferably contains a seventh substance differing from the sixth substance.

One embodiment of the present invention is a method for manufacturing a display apparatus, including a step of forming a first electrode and a second electrode; a step of forming a light-receiving film over the first electrode and the second electrode; a step of forming a first sacrificial layer having an island shape comprising a region overlapping with the first electrode, over the light-receiving film; a step of etching the light-receiving film using the first sacrificial layer as a mask to form a light-receiving layer and expose the second electrode; a step of forming a first functional film over the first sacrificial layer and the second electrode; a step of forming a light-emitting layer having an island shape including a region overlapping with the second electrode, over the first functional film, with the use of a metal mask; a step of forming a second functional film over the light-emitting layer and the first functional film; a step of forming a second sacrificial layer having an island shape including a region overlapping with the light-emitting layer, over the second functional film; a step of etching the first functional film and the second functional film using the second sacrificial layer as a mask to form a first functional layer and a second functional layer and expose the first sacrificial layer; a step of removing the first sacrificial layer and the second sacrificial layer to expose the light-receiving layer and the second functional layer; and a step of forming a common electrode over the light-receiving layer and the second functional layer. The first functional layer contains a substance having a hole-transport property, and the second functional layer contains a substance having an electron-transport property.

One embodiment of the present invention is a method for manufacturing a display apparatus, including a step of forming a first electrode and a second electrode; a step of forming a light-receiving film over the first electrode and the second electrode; a step of forming a sacrificial layer having an island shape including a region overlapping with the first electrode, over the light-receiving film; a step of etching the light-receiving film using the sacrificial layer as a mask to form a light-receiving layer and expose the second electrode; a step of forming a first functional layer over the sacrificial layer and forming a second functional layer over the second electrode; a step of forming a light-emitting layer having an island shape including a region overlapping with the second electrode, over the second functional layer, with the use of a metal mask; a step of forming a third functional layer over the first functional layer and forming a fourth functional layer over the light-emitting layer; a step of removing the sacrificial layer to lift off the first functional layer and the third functional layer and expose the light-receiving layer; and a step of forming a common electrode over the light-receiving layer and the fourth functional layer. The second functional layer contains a substance having a hole-transport property, and the fourth functional layer contains a substance having an electron-transport property.

### Effect of the Invention

According to one embodiment of the present invention, a high-resolution display apparatus having a light detection function can be provided. According to one embodiment of the present invention, a display apparatus having a light detection function with high accuracy can be provided. According to one embodiment of the present invention, a display apparatus having a light detection function and low power consumption can be provided. According to one embodiment of the present invention, a highly reliable display apparatus having a light detection function can be provided. According to one embodiment of the present invention, a novel display apparatus can be provided.

Note that the description of these effects does not preclude the existence of other effects. Note that one embodiment of the present invention does not need to have all of these effects. Note that other effects can be derived from the description of the specification, the drawings, and the claims.

### BRIEF DESCRIPTION OF THE DRAWINGS

FIG. 1A to FIG. 1D are cross-sectional views illustrating a structure example of a display apparatus.

FIG. 1E is a diagram illustrating an example of a captured image.

FIG. 2A to FIG. 2D are cross-sectional views illustrating structure examples of a display apparatus.

FIG. 3A and FIG. 3B are cross-sectional views illustrating a structure example of a display apparatus.

FIG. 4A is a top view illustrating a structure example of a display apparatus. FIG. 4B is a cross-sectional view illustrating a structure example of the display apparatus.

FIG. 5A and FIG. 5B are cross-sectional views illustrating structure examples of a display apparatus.

FIG. 6A to FIG. 6C are cross-sectional views illustrating structure examples of a display apparatus.

FIG. 7A to FIG. 7C are cross-sectional views illustrating structure examples of a display apparatus.

FIG. 8A to FIG. 8C are cross-sectional views illustrating structure examples of a display apparatus.

FIG. 9A and FIG. 9B are cross-sectional views illustrating a structure example of a display apparatus.

FIG. 10A to FIG. 10E are cross-sectional views illustrating an example of a method for manufacturing a display apparatus.

FIG. 11A to FIG. 11D are cross-sectional views illustrating an example of a method for manufacturing a display apparatus.

FIG. 12A to FIG. 12D are cross-sectional views illustrating an example of a method for manufacturing a display apparatus.

FIG. 13A to FIG. 13D are cross-sectional views illustrating an example of a method for manufacturing a display apparatus.

FIG. 14A to FIG. 14C are cross-sectional views illustrating an example of a method for manufacturing a display apparatus.

FIG. 15A to FIG. 15D are cross-sectional views illustrating an example of a method for manufacturing a display apparatus.

FIG. 16A to FIG. 16D are cross-sectional views illustrating an example of a method for manufacturing a display apparatus.

FIG. 17A to FIG. 17D are cross-sectional views illustrating an example of a method for manufacturing a display apparatus.

FIG. 18A to FIG. 18D are cross-sectional views illustrating an example of a method for manufacturing a display apparatus.

FIG. 19A and FIG. 19B are cross-sectional views illustrating an example of a method for manufacturing a display apparatus.

FIG. 20A and FIG. 20B are top views each illustrating a structure example of a display apparatus.

FIG. 21 is a perspective view illustrating a structure example of a display apparatus.

FIG. 22 is a cross-sectional view illustrating a structure example of a display apparatus.

FIG. 23 is a cross-sectional view illustrating a structure example of a display apparatus.

FIG. 24 is a cross-sectional view illustrating a structure example of the display apparatus.

FIG. 25 is a cross-sectional view illustrating a structure example of a display apparatus.

FIG. 26 is a cross-sectional view illustrating a structure example of a display apparatus.

FIG. 27A to FIG. 27D are cross-sectional views illustrating structure examples of a light-emitting device.

FIG. 28A to FIG. 28G are cross-sectional views illustrating structure examples of a light-emitting and light-receiving device.

FIG. 29A to FIG. 29E are diagrams each illustrating an example of an electronic device.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, they are not limited to the illustrated scale.

In this specification and the like, ordinal numbers such as “first,” “second,” and the like are used in order to avoid confusion among components and do not limit the number.

In this specification and the like, the term “film” and the term “layer” can be interchanged with each other. For example, in some cases, the term “conductive layer” or “insulating layer” can be interchanged with the term “conductive film” or “insulating film.”

Note that in this specification and the like, an EL layer means a layer containing at least a light-emitting substance (also referred to as a light-emitting layer) or a stacked-layer body including the light-emitting layer provided between a pair of electrodes of a light-emitting device.

In this specification and the like, a display panel that is one embodiment of a display apparatus has a function of displaying (outputting) an image or the like on (to) a display surface.

Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, a display apparatus of one embodiment of the present invention is described.

The display apparatus of one embodiment of the present invention includes a display portion, and the display portion includes a plurality of pixels arranged in a matrix. The pixel includes a light-emitting device and a light-receiving device (also referred to as a light-receiving element). The light-emitting device functions as a display device (also referred to as a display element). In the display apparatus of one embodiment of the present invention, the light-emitting devices are arranged in a matrix in the display portion, and an image can be displayed on the display portion. In addition, the display apparatus of one embodiment of the present invention has a function of detecting light with the use of the light-receiving devices.

The light-receiving devices are arranged in a matrix in the display portion of the display apparatus of one embodiment of the present invention, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the case where the light-receiving devices are used as an image sensor, the display apparatus can capture an image with the use of the light-receiving devices. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, a small and lightweight electronic device can be achieved.

In the case where the light-receiving devices are used as the touch sensor, the display apparatus can detect the approach or contact of a target with the use of the light-receiving devices.

Note that in this specification and the like, a device manufactured using a metal mask or an FMM (a fine metal mask or a high-resolution metal mask) is sometimes referred to as a device having an MM (metal mask) structure. In addition, in this specification and the like, a device manufactured without using a metal mask or an FMM is sometimes referred to as a device having an MML (metal maskless) structure.

More specific examples are described below with reference to drawings.

### Structure Example 1

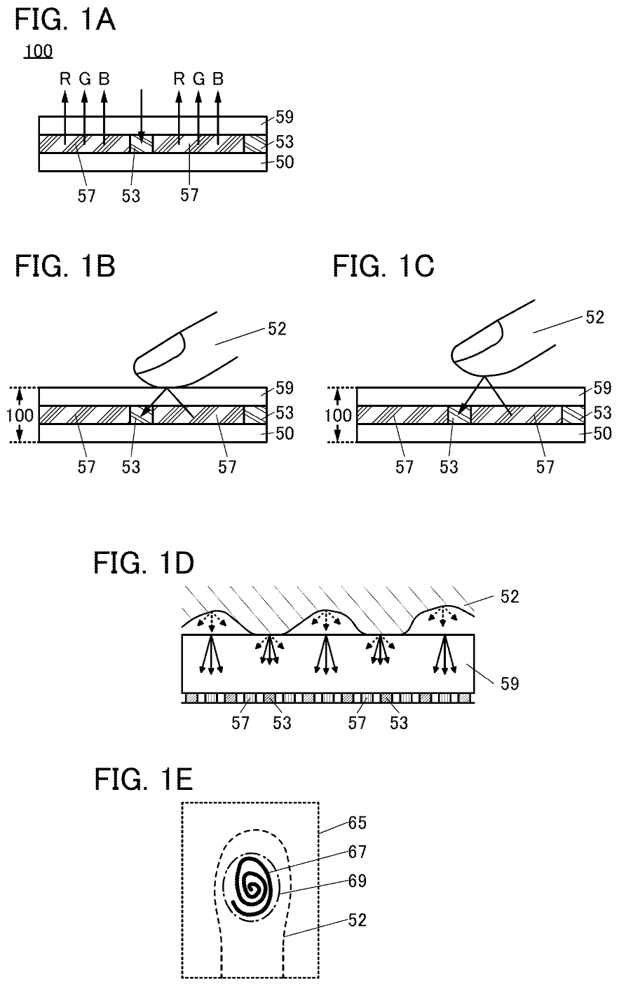

FIG. 1A to FIG. 1D illustrate cross-sectional views illustrating a structure example of the display apparatus of one embodiment of the present invention.

A display apparatus 100 illustrated in FIG. 1A includes a layer 53 including light-receiving devices and a layer 57 including light-emitting devices, between a substrate 50 and a substrate 59.

FIG. 1A illustrates a structure in which light of red (R), green (G), and blue (B) is emitted from the layer 57 including light-emitting devices and light is incident on the layer 53 including light-receiving devices. Note that the light emitted from the layer 57 and the light incident on the layer 53 are indicated by arrows in FIG. 1A.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a wavelength range of visible light is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

In the display apparatus of one embodiment of the present invention, the plurality of pixels arranged in a matrix are provided in the display portion. One pixel includes one or more subpixels. Each of the subpixels includes a light-emitting device or a light-receiving device. A pixel can include four subpixels, for example. Specifically, one pixel can include a subpixel that includes a light-emitting device emitting red (R) light, a subpixel that includes a light-emitting device emitting green (G) light, a subpixel that includes a light-emitting device emitting blue (B) light, and a subpixel that includes a light-receiving device.

Note that the combination of the colors of light emitted by the light-emitting devices included in the pixel is not limited to three colors of red (R), green (G), and blue (B). The combination of the colors of light emitted by the light-emitting devices included in the pixel can be, for example, three colors of yellow (Y), cyan (C), and magenta (M). Note that the number of colors of light emitted by the light-emitting devices included in the pixel may be four or more.

The pixel may include five or more subpixels. Specifically, one pixel can include four kinds of light-emitting devices of red (R), green (G), blue (B), and white (W) and a light-receiving device. Alternatively, one pixel can include four kinds of light-emitting devices of red (R), green (G), blue (B), and infrared (IR) and a light-receiving device. Note that the light-receiving device may be provided in all the pixels or may be provided in some of the pixels. Note that one pixel may include a plurality of light-receiving devices. For example, one pixel can include three kinds of light-emitting devices of red (R), green (G), and blue (B), a light-receiving device that has sensitivity in the wavelength range of visible light, and a light-receiving device that has sensitivity in the wavelength range of infrared light.

The display apparatus of one embodiment of the present invention can have a function of detecting a target in contact with the display apparatus. The target is not particularly limited and can be a living body or an object. In the case where the target is a living body, the display apparatus can have a function of detecting a finger or a palm, for example. As illustrated in FIG. 1B, a finger 52 in contact with the display apparatus 100 reflects light emitted by the light-emitting devices included in the layer 57, and the light-receiving devices included in the layer 53 detect the reflected light. Thus, the contact of the finger 52 with the display apparatus 100 can be detected. That is, the display apparatus of one embodiment of the present invention can have a function of a touch sensor. As illustrated in FIG. 1C, the finger 52 approaching the display apparatus 100 reflects light emitted by the light-emitting devices included in the layer 57, and the light-receiving devices included in the layer 53 detect the reflected light. Thus, the approach of the finger 52 to the display apparatus 100 can be detected. That is the display apparatus of one embodiment of the present invention can have a function of a near-touch sensor.

In the case where the display apparatus 100 has a function of a near-touch sensor, even when the finger 52 is not in contact with the display apparatus 100, the finger 52 can be detected when the finger 52 approaches the display apparatus 100. For example, a structure is preferable in which the display apparatus 100 can detect the finger 52 when a distance between the display apparatus 100 and the finger 52 is more than or equal to 0.1 mm and less than or equal to 300 mm, preferably more than or equal to 3 mm and less than or equal to 50 mm. With this structure, the display apparatus 100 can be operated without a direct contact of the finger 52 with the display apparatus 100; in other words, the display apparatus 100 can be operated in a contactless (touchless) manner. With the above structure, the display apparatus 100 can be operated with a reduced risk of making the display apparatus 100 dirty or damaging the display apparatus 100 or without the finger 52 being in direct contact with a dirt (e.g., dust, bacteria, or a virus) that can be attached to the display apparatus 100.

The display apparatus of one embodiment of the present invention can have a function of capturing an image of a target in contact with the display apparatus. The display apparatus can have a function of detecting the fingerprint of the finger 52, for example. FIG. 1D schematically illustrates an enlarged view of a contact portion in a state where the finger 52 touches the substrate 59. Furthermore, FIG. 1D illustrates a state where the layers 57 including light-emitting devices and the layers 53 including light-receiving devices are alternately arranged.

The fingerprint of the finger 52 is formed of depressions and projections. Therefore, as illustrated in FIG. 1D, the projections of the fingerprint touch the substrate 59.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 52. Meanwhile, regular reflection components are dominant in the light reflected from the interface between the substrate 59 and the air.

The intensity of light that is reflected on a contact surface or a non-contact surface between the finger 52 and the substrate 59 and is incident on the layer 53 positioned directly below the contact surface or the non-contact surface is the sum of intensities of regularly reflected light and diffusely reflected light. As described above, regularly reflected light (indicated by solid arrows) is dominant in the depressions of the finger 52 where the finger 52 does not touch the substrate 59, whereas diffusely reflected light (indicated by dashed arrows) from the finger 52 is dominant in the projections where the finger 52 touches the substrate 59. Thus, the intensity of light received by the light-receiving device of the layer 53 positioned directly below the depression is higher than the intensity of light received by the light-receiving device of the layer 53 positioned directly below the projection. Accordingly, an image of the fingerprint of the finger 52 can be captured using the light-receiving devices.

In the case where an arrangement interval between the light-receiving devices of the layers 53 is smaller than a distance between two projections of a fingerprint, preferably a distance between a depression and a projection adjacent to each other, a clear fingerprint image can be obtained. A distance between a depression and a projection of a human's fingerprint is generally within a range from 150 μm to 250 μm; thus, the arrangement interval between the light-receiving devices is, for example, less than or equal to 400 μm, preferably less than or equal to 200 μm, further preferably less than or equal to 150 μm, still further preferably less than or equal to 120 μm, yet further preferably less than or equal to 100 μm, yet still further preferably less than or equal to 50 μm. The arrangement interval is preferably as small as possible, and can be more than or equal to 1 μm, more than or equal to 10 μm, or more than or equal to 20 μm, for example.

FIG. 1E is an example of a fingerprint image captured by the display apparatus of one embodiment of the present invention. In FIG. 1E, the outline of the finger 52 is indicated by a dashed line and the outline of a contact portion 69 is indicated by a dashed-dotted line in a region 65. In the region 65, a high-contrast image of a fingerprint 67 can be captured owing to a difference in the amount of light incident on the light-receiving devices. Furthermore, fingerprint authentication can be performed using the obtained fingerprint image. Note that the example of capturing the fingerprint image with the finger regarded as a target is described here; however, one embodiment of the present invention is not limited thereto. For example, the display apparatus can detect a palm in contact with or approaching the display portion. In addition, the display apparatus can capture a palm print image and can perform palm print authentication using the obtained palm print image.

As described above, in the display apparatus of one embodiment of the present invention, the light-receiving device can detect light that is emitted from the light-emitting device to be delivered on the target and is reflected by the target. Accordingly, the target in contact with or approaching the display portion can be detected even in a dark place. Furthermore, the display apparatus can perform authentication such as fingerprint authentication and palm print authentication.

Providing the light-receiving devices in the display portion eliminates the need for attachment of an external sensor to the display apparatus. Thus, the number of components can be reduced, whereby a small and lightweight display apparatus can be achieved.

As the substrate 50, a substrate having heat resistance high enough to withstand the formation of the light-emitting device and the light-receiving device can be used. In the case where an insulating substrate is used as the substrate 50, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium or the like, or a semiconductor substrate such as an SOI substrate can be used.

As the substrate 50, it is particularly preferable to use the above-described insulating substrate or semiconductor substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### Structure Example 2

### Structure Example 2-1

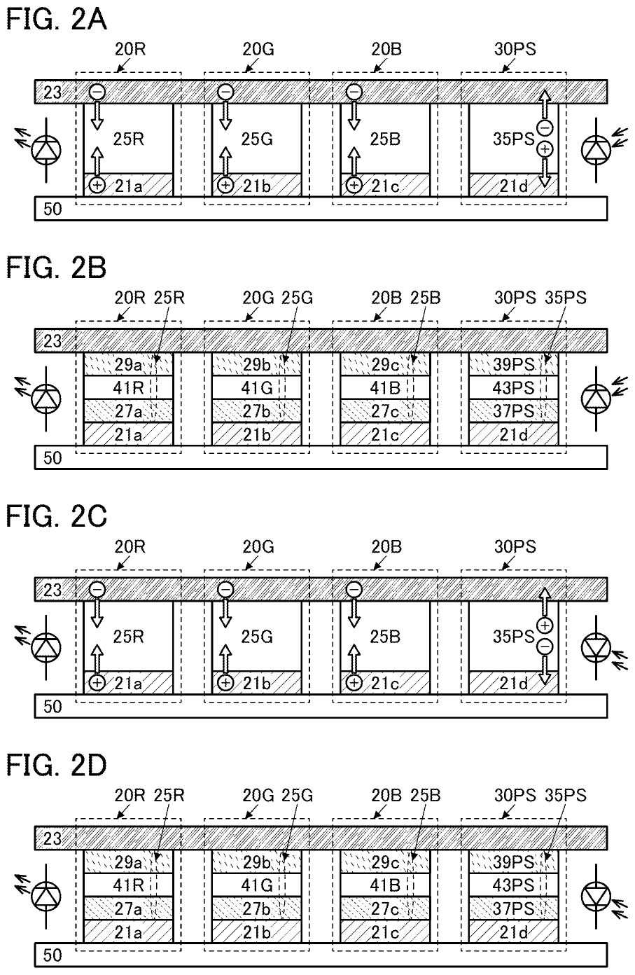

Structures of light-emitting devices and a light-receiving device that can be used in a display apparatus of one embodiment of the present invention are described. FIG. 2A is a schematic cross-sectional view of the display apparatus of one embodiment of the present invention. FIG. 2A illustrates structures of a light-emitting device 20R, a light-emitting device 20G, a light-emitting device 20B, and a light-receiving device 30PS that can be used in the display apparatus.

The light-emitting device 20R, the light-emitting device 20G, and the light-emitting device 20B each have a function of emitting light (hereinafter, also referred to as a light-emitting function). As the light-emitting device 20R, the light-emitting device 20G, and the light-emitting device 20B, EL elements such as OLEDs (Organic Light Emitting Diodes) or QLEDs (Quantum-dot Light Emitting Diodes) are preferably used. Examples of a light-emitting substance contained in the EL element include a substance exhibiting fluorescence (a fluorescent material), a substance exhibiting phosphorescence (a phosphorescent material), an inorganic compound (such as a quantum dot material), and a substance exhibiting thermally activated delayed fluorescence (TADF (Thermally Activated Delayed Fluorescence) material). Note that as a TADF material, a material that is in a thermal equilibrium state between a singlet excited state and a triplet excited state may be used. Such a TADF material has a short light emission lifetime (excitation lifetime) and thus can inhibit a reduction in efficiency of the light-emitting device in a high-luminance region.

The light-emitting device 20R includes an electrode 21a, an EL layer 25R, and an electrode 23. The light-emitting device 20G includes an electrode 21b, an EL layer 25G, and the electrode 23. The light-emitting device 20B includes an electrode 21c, an EL layer 25B, and the electrode 23. In the light-emitting device 20R, the EL layer 25R sandwiched between the electrode 21a and the electrode 23 includes at least a light-emitting layer 41R. The light-emitting layer 41R contains a light-emitting substance that emits light. The EL layer 25R emits light when voltage is applied between the electrode 21a and the electrode 23. Similarly, the EL layer 25G includes at least a light-emitting layer 41G. The light-emitting layer 41G contains a light-emitting substance that emits light. The EL layer 25G emits light when voltage is applied between the electrode 21b and the electrode 23. The EL layer 25B includes at least a light-emitting layer 41B. The light-emitting layer 41B contains a light-emitting substance that emits light. The EL layer 25B emits light when voltage is applied between the electrode 21c and the electrode 23.

Each of the EL layer 25R, the EL layer 25G, and the EL layer 25B may include one or more of a layer containing a substance having a high hole-injection property (hereinafter, referred to as a hole-injection layer), a layer containing a substance having a high hole-transport property (hereinafter, referred to as a hole-transport layer), a layer containing a substance having a high electron-transport property (hereinafter, referred to as an electron-transport layer), a layer containing a substance having a high electron-injection property (hereinafter, referred to as an electron-injection layer), a carrier-blocking layer, an exciton-blocking layer, and a charge-generation layer. The hole-injection layer, the hole-transport layer, the electron-transport layer, the electron-injection layer, the carrier-blocking layer, the exciton-blocking layer, and the charge-generation layer can also be referred to as functional layers.

Note that in this specification and the like, in the case where a matter common to the light-emitting device 20R, the light-emitting device 20G, and the light-emitting device 20B is described or the case where the light-emitting device 20R, the light-emitting device 20G, and the light-emitting device 20B need not be distinguished from one another, they are simply referred to as light-emitting devices 20 in some cases. Similarly, the EL layer 25R, the EL layer 25G, and the EL layer 25B are simply referred to as EL layers 25 in some cases. The same applies the other constituent elements.

The light-receiving device 30PS has a function of detecting light (hereinafter, also referred to as a light-receiving function). The light-receiving device 30PS has a function of detecting visible light. The light-receiving device 30PS has sensitivity to visible light. The light-receiving device 30PS further preferably has a function of detecting visible light and infrared light. The light-receiving device 30PS preferably has sensitivity to visible light and infrared light. For example, a pn or pin photodiode can be used as the light-receiving device 30PS.

The light-receiving device 30PS includes an electrode 21d, a light-receiving layer 35PS, and the electrode 23. The light-receiving layer 35PS sandwiched between the electrode 21d and the electrode 23 includes at least an active layer. The light-receiving device 30PS functions as a photoelectric conversion device; charge can be generated by light incident on the light-receiving layer 35PS and extracted as a current. At this time, voltage may be applied between the electrode 21d and the electrode 23. The amount of generated charge is determined depending on the amount of light incident on the light-receiving layer 35PS.

The light-receiving layer 35PS may further include one or more of a hole-transport layer, an electron-transport layer, a layer containing a bipolar substance (a substance having a high electron-transport property and a high hole-transport property), and a carrier-blocking layer. The light-receiving layer 35PS may include a layer containing a substance that can be used for a hole-injection layer. The layer can function as a hole-transport layer in the light-receiving device 30PS. In addition, the light-receiving layer 35PS may include a layer containing a substance that can be used for an electron-injection layer. The layer can function as an electron-transport layer in the light-receiving device 30PS. Note that a substance having a hole-injection property can also be regarded as having a hole-transport property. The substance having an electron-injection property can also regarded as having an electron-transport property. Therefore, in this specification and the like, a substance having a hole-injection property is referred to as a substance having a hole-transport property in some cases. Similarly, a substance having an electron-injection property is referred to as a substance having an electron-transport property in some cases.

The active layer contains a semiconductor. Examples of the semiconductor include an inorganic semiconductor such as silicon, and an organic semiconductor including an organic compound. It is particularly preferable to use an organic photodiode including a layer containing an organic semiconductor, as the light-receiving device 30PS. An organic photodiode, which is easily made thin, lightweight, and large in area and has a high degree of freedom for shape and design, can be used in a variety of display apparatuses. An organic semiconductor is preferably used because in that case the EL layer included in the light-emitting device 20 and the light-receiving layer included in the light-receiving device 30PS can be formed by the same method (e.g., a vacuum evaporation method) with the same manufacturing apparatus.

In the display apparatus of one embodiment of the present invention, organic EL devices can be used as the light-emitting device 20R, the light-emitting device 20G, and the light-emitting device 20B, and an organic photodiode can be suitably used as the light-receiving device 30PS. The organic EL devices and the organic photodiode can be formed over the same substrate. Thus, the organic photodiode can be incorporated in the display apparatus including the organic EL devices. The display apparatus of one embodiment of the present invention has one or both of an image capturing function and a sensing function in addition to an image displaying function.

The electrode 21a, the electrode 21b, the electrode 21c, and the electrode 21d are provided on the same plane. In the structure illustrated in FIG. 2A, the electrode 21a, the electrode 21b, the electrode 21c, and the electrode 21d are provided over the substrate 50. The same material can be used for the electrode 21a, the electrode 21b, the electrode 21c, and the electrode 21d. Furthermore, the electrode 21a, the electrode 21b, the electrode 21c, and the electrode 21d can be formed through the same processes. For example, the electrode 21a, the electrode 21b, the electrode 21c, and the electrode 21d can be formed through processing a conductive film formed over the substrate 50 into island-like shapes. When the electrode 21a, the electrode 21b, the electrode 21c, and the electrode 21d are formed through the same processes, the productivity of the display apparatus can be increased.

Each of the electrode 21a, the electrode 21b, the electrode 21c, and the electrode 21d can be referred to as a pixel electrode. The electrode 23 is a layer shared by the light-emitting device 20R, the light-emitting device 20G, the light-emitting device 20B, and the light-receiving device 30PS and can be referred to as a common electrode. A conductive film transmitting visible light and infrared light is used as the pixel electrode or the common electrode through which light exits or enters. A conductive film reflecting visible light and infrared light is preferably used as the electrode through which light neither exits nor enters.

FIG. 2A schematically shows that the electrode 21a, the electrode 21b, the electrode 21c, and the electrode 21d function as anodes and the electrode 23 functions as a cathode in the light-emitting device 20R, the light-emitting device 20G, the light-emitting device 20B, and the light-receiving device 30PS. For easy understanding of the direction of the anode and the cathode, a circuit symbol of a light-emitting diode is shown on the left of the light-emitting device 20R and a circuit symbol of a photodiode is shown on the right of the light-receiving device 30PS in FIG. 2A. In addition, an electron is indicated by a circle with a sign of − (minus), a hole is indicated by a circle with a sign of + (plus), and flow directions of electrons and holes are schematically indicated by arrows.

The electrode 21a, the electrode 21b, and the electrode 21c, which function as anodes in the light-emitting device 20R, the light-emitting device 20G, and the light-emitting device 20B, are electrically connected to a first wiring that supplies a first potential. The electrode 23, which functions as a cathode in the light-emitting device 20R, the light-emitting device 20G, the light-emitting device 20B, and the light-receiving device 30PS, is electrically connected to a second wiring that supplies a second potential. The second potential is a potential lower than the first potential. The electrode 21d, which functions as an anode in the light-receiving device 30PS, is electrically connected to a third wiring that supplies a third potential. Here, a reverse bias voltage is applied to the light-receiving device 30PS. That is, the third potential is a potential lower than the second potential.

FIG. 2B illustrates a specific example of the structure illustrated in FIG. 2A. In the light-emitting device 20R, the EL layer 25R includes a first layer 27a, the light-emitting layer 41R, and a second layer 29a that are stacked in this order. In the light-emitting device 20G, the EL layer 25G includes a first layer 27b, the light-emitting layer 41G, and a second layer 29b that are stacked in this order. In the light-emitting device 20B, the EL layer 25B includes a first layer 27c, the light-emitting layer 41B, and a second layer 29c that are stacked in this order.

Note that in the light-emitting device 20R, a structure including the first layer 27a, the light-emitting layer 41R, and the second layer 29a provided between the pair of electrodes (the electrode 21a and the electrode 23) can function as a single light-emitting unit; the structure of the light-emitting device 20R is referred to as a single structure in some cases in this specification and the like. The same applies to the light-emitting device 20G and the light-emitting device 20B.

The first layer 27a, the first layer 27b, and the first layer 27c are positioned on the electrodes 21a, 21b, and 21c side (the electrodes 21a, 21b, and 21c function as anodes in the light-emitting device 20R, the light-emitting device 20G, and the light-emitting device 20B). The first layer 27a, the first layer 27b, and the first layer 27c can each be a hole-transport layer or a hole-injection layer. Alternatively, the first layer 27a, the first layer 27b, and the first layer 27c may each have a stacked-layer structure of a hole-injection layer and a hole-transport layer over the hole-injection layer. Furthermore, the hole-injection layer may have a stacked-layer structure, and the hole-transport layer may have a stacked-layer structure. Alternatively, the first layer 27a, the first layer 27b, and the first layer 27c may each contain a substance having a hole-transport property and a substance having a hole-injection property. Note that in this specification and the like, the first layer 27a, the first layer 27b, and the first layer 27c are sometimes referred to as functional layers.

The same material can be used for the first layer 27a, the first layer 27b, and the first layer 27c. Furthermore, the first layer 27a, the first layer 27b, and the first layer 27c can be formed through the same processes. For example, the first layer 27a, the first layer 27b, and the first layer 27c can be formed through processing a film that is to be the first layer 27a, the first layer 27b, and the first layer 27c. When the first layer 27a, the first layer 27b, and the first layer 27c are formed through the same processes, the productivity of the display apparatus can be increased.

The second layer 29a, the second layer 29b, and the second layer 29c are positioned on the electrode 23 side (the electrode 23 functions as a cathode in the light-emitting device 20R, the light-emitting device 20G, and the light-emitting device 20B). The second layer 29a, the second layer 29b, and the second layer 29c can each be an electron-transport layer or an electron-injection layer. Alternatively, the second layer 29a, the second layer 29b, and the second layer 29c may each have a stacked-layer structure of an electron-transport layer and an electron-injection layer over the electron-transport layer. Furthermore, the electron-injection layer may have a stacked-layer structure, and the electron-transport layer may have a stacked-layer structure. Alternatively, the second layer 29a, the second layer 29b, and the second layer 29c may each contain a substance having an electron-transport property and a substance having an electron-injection property. Note that in this specification and the like, the second layer 29a, the second layer 29b, and the second layer 29c are sometimes referred to as functional layers.

The same material can be used for the second layer 29a, the second layer 29b, and the second layer 29c. Furthermore, the second layer 29a, the second layer 29b, and the second layer 29c can be formed through the same processes. For example, the second layer 29a, the second layer 29b, and the second layer 29c can be formed through processing a film that is to be the second layer 29a, the second layer 29b, and the second layer 29c. When the second layer 29a, the second layer 29b, and the second layer 29c are formed through the same processes, the productivity of the display apparatus can be increased.

As illustrated in FIG. 2B, the light-receiving layer 35PS in the light-receiving device 30PS includes a third layer 37PS, an active layer 43PS, and a fourth layer 39PS that are stacked in this order.

The third layer 37PS that is positioned on the electrode 21d side (the electrode 21d functions as the anode of the light-receiving device 30PS) can be a hole-transport layer. The substance having a hole-transport property contained in the third layer 37PS may differ from the substance having a hole-transport property contained in the first layer 27a, the first layer 27b, and the first layer 27c. The third layer 37PS included in the light-receiving device 30PS is preferably formed through a process different from processes for layers constituting the light-emitting devices 20 (e.g., the first layer 27a, the first layer 27b, and the first layer 27c). When the third layer 37PS is formed through a different process, a material more suitable for the light-receiving device 30PS can be used for the third layer 37PS. Note that in this specification and the like, the third layer 37PS is sometimes referred to as a functional layer.

A material usable for the first layer 27a, the first layer 27b, and the first layer 27c can be used for the third layer 37PS. The substance having a hole-transport property contained in the third layer 37PS may be the same as the substance having a hole-transport property contained in the first layer 27a, the first layer 27b, and the first layer 27c. The third layer 37PS may have a stacked-layer structure.

The fourth layer 39PS that is positioned on the electrode 23 side (the electrode 23 functions as the cathode of the light-receiving device 30PS) can be an electron-transport layer. The substance having an electron-transport property contained in the fourth layer 39PS may differ from the substance having an electron-transport property contained in the second layer 29a, the second layer 29b, and the second layer 29c. The fourth layer 39PS included in the light-receiving device 30PS is preferably formed through a process different from processes for layers constituting the light-emitting devices 20 (e.g., the second layer 29a, the second layer 29b, and the second layer 29c). When the fourth layer 39PS is formed through a different process, a material more suitable for the light-receiving device 30PS can be used for the fourth layer 39PS. Note that in this specification and the like, the fourth layer 39PS is sometimes referred to as a functional layer.

A material usable for the second layer 29a, the second layer 29b, and the second layer 29c can be used for the fourth layer 39PS. The substance having an electron-transport property contained in the fourth layer 39PS may be the same as the substance having an electron-transport property contained in the second layer 29a, the second layer 29b, and the second layer 29c. The fourth layer 39PS may have a stacked-layer structure.

Note that the third layer 37PS may include a layer that functions as a hole-injection layer in a light-emitting device, i.e., a layer that contains a substance having a high hole-injection property. A hole-injection layer can function as a hole-transport layer in a light-receiving device. The fourth layer 39PS may include a layer that functions as an electron-injection layer in a light-emitting device, i.e., a layer that contains a substance having a high electron-injection property. An electron-injection layer can function as an electron-transport layer in a light-receiving device.

As illustrated in FIG. 2B and the like, it is preferable that the EL layer 25R, the EL layer 25G, the EL layer 25B, and the light-receiving layer 35PS not include a layer shared by them. In addition, it is preferable that the EL layer 25R, the EL layer 25G, the EL layer 25B, and the light-receiving layer 35PS not include regions in contact with one another. That is, it is preferable that the EL layer 25R, the EL layer 25G, the EL layer 25B, and the light-receiving layer 35PS be separated from one another.

Separation of the EL layers 25 of two adjacent light-emitting devices 20 can inhibit generation of a leakage current between the light-emitting devices. That is, a phenomenon in which a light-emitting device other than a desired light-emitting device emits light (also referred to as crosstalk) can be inhibited; thus, a display apparatus with high display quality can be achieved.

Separation of the light-receiving layer 35PS of the light-receiving device 30PS from the EL layer 25 of the adjacent light-emitting device 20 can inhibit a leakage current from flowing from the light-emitting device 20 to the light-receiving device 30PS (also referred to as a side leakage). Thus, the light-receiving device 30PS can have a high SN ratio (Signal to Noise Ratio) and high accuracy.

In the display apparatus of one embodiment of the present invention, the side leakage between the light-emitting device 20 and the light-receiving device 30PS can be inhibited, which allows a short distance between the light-emitting device 20 and the light-receiving device 30PS. That is, the proportions of the light-emitting devices 20 and the light-receiving device 30PS in a pixel (hereinafter, also referred to as an aperture ratio) can be increased. In addition, the size of a pixel can be reduced, so that the resolution of the display apparatus can be increased. Thus, a display apparatus having a light detection function and a high aperture ratio can be achieved. In addition, a display apparatus having a light detection function and a high resolution can be achieved.

Note that the light-receiving devices 30PS can be arranged at a resolution higher than or equal to 100 ppi, preferably higher than or equal to 200 ppi, more preferably higher than or equal to 300 ppi, further preferably higher than or equal to 400 ppi, still further preferably higher than or equal to 500 ppi and lower than or equal to 2000 ppi, lower than or equal to 1000 ppi, or lower than or equal to 600 ppi, for example. In particular, when the light-receiving devices 30PS are arranged at a resolution higher than or equal to 200 ppi and lower than or equal to 600 ppi, preferably higher than or equal to 300 ppi and lower than or equal to 600 ppi, the light-receiving devices 30PS can be suitably used for capturing a fingerprint image.

In the case where fingerprint authentication is performed with the display apparatus of one embodiment of the present invention, the increased resolution of the light-receiving devices 30PS enables, for example, highly accurate extraction of the minutiae of fingerprints; thus, the accuracy of the fingerprint authentication can be increased. The resolution is preferably higher than or equal to 500 ppi, in which case the authentication conforms to the standard by the National Institute of Standards and Technology (NIST) or the like. On the assumption that the resolution at which the light-receiving devices are arranged is 500 ppi, the size of each pixel is 50.8 μm, which indicates that the resolution is adequate for image capturing of a fingerprint ridge distance (typically, greater than or equal to 300 μm and less than or equal to 500 μm).

### Structure Example 2-2

FIG. 2C illustrates a structure different from the structures illustrated in FIG. 2A and FIG. 2B. The display apparatus illustrated in FIG. 2C schematically shows that the electrode 21a, the electrode 21b, and the electrode 21c function as anodes and the electrode 23 function as a cathode in the light-emitting device 20R, the light-emitting device 20G, and the light-emitting device 20B; the electrode 21d functions as a cathode and the electrode 23 functions as an anode in the light-receiving device 30PS.

The electrode 21a, the electrode 21b, and the electrode 21c, which function as anodes in the light-emitting device 20R, the light-emitting device 20G, and the light-emitting device 20B, are electrically connected to a first wiring that supplies a first potential. The electrode 23, which functions as a cathode in the light-emitting device 20R, the light-emitting device 20G, and the light-emitting device 20B and functions as an anode in the light-receiving device 30PS, is electrically connected to a second wiring that supplies a second potential. The second potential is a potential lower than the first potential. The electrode 21d, which functions as a cathode in the light-receiving device 30PS, is electrically connected to a third wiring that supplies a third potential. The third potential is a potential higher than the second potential.

As illustrated in FIG. 2C, the electrode 23 functioning as a common electrode can function as one of the anode and the cathode in the light-emitting device 20R, the light-emitting device 20G, and the light-emitting device 20B and functions as the other of the anode and the cathode in the light-receiving device 30PS. Such a structure can reduce a potential difference between the pixel electrodes (the electrode 21a, the electrode 21b, and the electrode 21c) of the light-emitting devices 20 and the pixel electrode (the electrode 21d) of the light-receiving device 30PS, thereby inhibiting a leakage between the pixel electrodes (hereinafter, referred to as a side leakage). Therefore, the light-receiving device 30PS can have a high SN ratio and high accuracy.

For example, the first potential (a potential supplied to the electrode 21a, the electrode 21b, and the electrode 21c) can be 12 V, the second potential (a potential supplied to the electrode 23) can be 0 V, and the third potential (a potential supplied to the electrode 21d) can be 4 V. Such a structure can reduce a potential difference between the pixel electrodes (the electrode 21a, the electrode 21b, and the electrode 21c) of the light-emitting devices 20 and the pixel electrode (the electrode 21d) of the light-receiving device 30PS, thereby inhibiting a side leakage between the light-emitting devices 20 and the light-receiving device 30PS.

Furthermore, the difference between the highest one and the lowest one of the first potential, the second potential, and the third potential can be small, whereby a display apparatus with low power consumption can be achieved.

FIG. 2D illustrates a specific example of the structure illustrated in FIG. 2C. For the light-emitting device 20R, the light-emitting device 20G, and the light-emitting device 20B, the above description can be referred to and detailed description is omitted.

The third layer 37PS positioned on the electrode 21d side (the electrode 21d functions as the cathode of the light-receiving device 30PS) can be an electron-transport layer. The substance having an electron-transport property contained in the third layer 37PS may differ from the substance having an electron-transport property contained in the second layer 29a, the second layer 29b, and the second layer 29c. A material usable for the second layer 29a, the second layer 29b, and the second layer 29c can be used for the third layer 37PS. The substance having an electron-transport property contained in the third layer 37PS may be the same as the substance having an electron-transport property contained in the second layer 29a, the second layer 29b, and the second layer 29c.

The fourth layer 39PS positioned on the electrode 23 side (the electrode 23 functions as the anode of the light-receiving device 30PS) can be a hole-transport layer. The substance having a hole-transport property contained in the fourth layer 39PS may differ from the substance having a hole-transport property contained in the first layer 27a, the first layer 27b, and the first layer 27c. A materials usable for the first layer 27a, the first layer 27b, and the first layer 27c can be used for the fourth layer 39PS. The substance having a hole-transport property contained in the fourth layer 39PS may be the same as the substance having a hole-transport property contained in the first layer 27a, the first layer 27b, and the first layer 27c.

Note that the third layer 37PS may include a layer that functions as an electron-injection layer in a light-emitting device, i.e., a layer containing a substance having a high electron-injection property. The fourth layer 39PS may include a layer that functions as a hole-injection layer in a light-emitting device, i.e., a layer containing a substance having a hole-injection property.

Although the electrode 21a, the electrode 21b, and the electrode 21c function as anodes and the electrode 23 functions as a cathode in the light-emitting devices 20 in the structure described in this embodiment, one embodiment of the present invention is not limited thereto. A structure in which the electrode 21a, the electrode 21b, and the electrode 21c function as cathodes and the electrode 23 functions as an anode in the light-emitting devices 20 may be employed. In this case, the first layer 27a, the first layer 27b, and the first layer 27c can be one or both of an electron-transport layer and an electron-injection layer. In this case, the second layer 29a, the second layer 29b, and the second layer 29c can be one or both of a hole-transport layer and a hole-injection layer.

### Structure Example 2-3

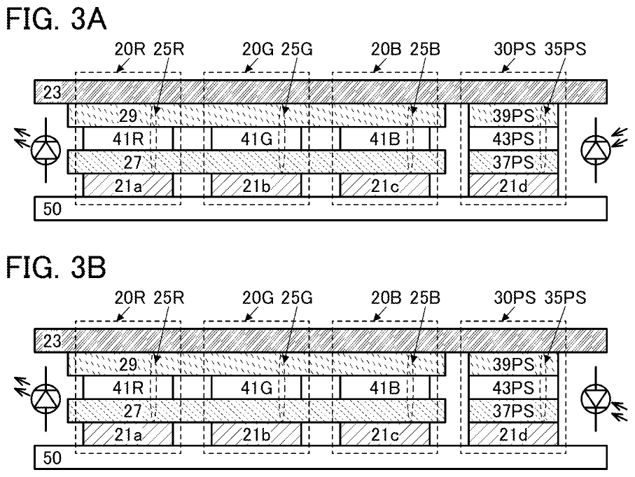

FIG. 3A illustrates a structure different from the structures illustrated in FIG. 2B. The light-emitting device 20R, the light-emitting device 20G, and the light-emitting device 20B illustrated in FIG. 3A include a first layer 27 instead of the first layer 27a, the first layer 27b, and the first layer 27c and include a second layer 29 instead of the second layer 29a, the second layer 29b, and the second layer 29c. The first layer 27 is a layer shared by the light-emitting device 20R, the light-emitting device 20G, and the light-emitting device 20B and can be referred to as a first common layer. Similarly, the second layer 29 is a layer shared by the light-emitting device 20R, the light-emitting device 20G, and the light-emitting device 20B and can be referred to as a second common layer.

As illustrated in FIG. 3A, the first layer 27 positioned on the electrodes 21a, 21b, and 21c side (the electrodes 21a, 21b, and 21c function as the anodes of the light-emitting device 20R, the light-emitting device 20G, and the light-emitting device 20B) can be a hole-transport layer or a hole-injection layer. Alternatively, the first layer 27 may have a stacked-layer structure of a hole-injection layer and a hole-transport layer over the hole-injection layer. For the first layer 27, the description of the first layer 27a, the first layer 27b, and the first layer 27c can be referred to, and thus detailed description is omitted.

The second layer 29 positioned on the electrode 23 side (the electrode 23 functions as the cathode of the light-emitting device 20R, the light-emitting device 20G, and the light-emitting device 20B) can be an electron-transport layer or an electron-injection layer. Alternatively, the second layer 29 may have a stacked-layer structure of an electron-transport layer and an electron-injection layer over the electron-transport layer. For the second layer 29, the description of the second layer 29a, the second layer 29b, and the second layer 29c can be referred to, and detailed description is omitted.

Note that a third common layer may be provided between the electrode 23 and the second layer 29 and between the electrode 23 and the fourth layer 39PS. The third common layer includes an electron-injection layer, for example. Alternatively, the third common layer may have a stacked-layer structure of an electron-transport layer and an electron-injection layer over the electron-transport layer. The third common layer is a layer shared by the light-emitting device 20R, the light-emitting device 20G, the light-emitting device 20B, and the light-receiving device 30PS. Note that in the case where an electron-injection layer is used as the third common layer, the electron-injection layer functions as an electron-transport layer in the light-receiving device 30PS.

Note that as illustrated in FIG. 3B, the electrode 21d may function as a cathode and the electrode 23 may function as an anode in the light-receiving device 30PS.

Note that the third common layer may be provided between the electrode 23 and the second layer 29 and between the electrode 23 and the fourth layer 39PS. For the third common layer, the above description can be referred to, and thus detailed description is omitted. Note that in the case where an electron-injection layer is used as the third common layer, the electron-injection layer does not necessarily have a specific function in the light-receiving device 30PS.

The hole-injection layer is a layer that injects holes from an anode to a hole-transport layer and contains a material having a high hole-injection property. Examples of the material having a high hole-injection property include an aromatic amine compound and a composite material containing a hole-transport material and an acceptor material (electron-accepting material).

In the light-emitting device, the hole-transport layer transports holes injected from the anode by the hole-injection layer, to the light-emitting layer. In the light-receiving device, the hole-transport layer is a layer that transports holes generated in the active layer on the basis of incident light, to the anode. The hole-transport layer is a layer that contains a hole-transport material. As the hole-transport material, a substance having a hole mobility greater than or equal to 1×10⁻⁶ cm²/Vs is preferable. Note that other substances can also be used as long as the substances have a hole-transport property higher than an electron-transport property. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferred.

In the light-emitting device, the electron-transport layer transports electrons injected from the cathode by the electron-injection layer, to the light-emitting layer. In the light-receiving device, the electron-transport layer is a layer that transports electrons generated in the active layer on the basis of incident light, to the cathode. The electron-transport layer is a layer that contains an electron-transport material. As the electron-transport material, a substance having an electron mobility greater than or equal to 1×10⁻⁶ cm²/Vs is preferable. Note that other substances can also be used as long as the substances have an electron-transport property higher than a hole-transport property. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer that injects electrons from the cathode to the electron-transport layer and contains a material having a high electron-injection property. As the material having a high electron-injection property, an alkali metal, an alkaline earth metal, or a compound thereof can be used. As the material having a high electron-injection property, a composite material containing an electron-transport material and a donor material (electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOr), or cesium carbonate. The electron-injection layer may have a stacked-layer structure of two or more layers. The stacked-layer structure can be, for example, a structure where lithium fluoride is used for the first layer and ytterbium is provided for the second layer.

Alternatively, an electron-transport material may be used for the electron-injection layer. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

For the charge-generation layer, for example, a material that can be used for an electron-injection layer, such as lithium, can be suitably used. For the charge-generation layer, for example, a material that can be used for a hole-injection layer can be suitably used. For the charge-generation layer, a layer containing a hole-transport material and an acceptor material (electron-accepting material) can be used. For the charge-generation layer, a layer containing an electron-transport material and a donor material can be used. Forming the charge-generation layer including such a layer can inhibit an increase in the driving voltage that would be caused by stacking light-emitting units.

The active layer contains a semiconductor. Examples of the semiconductor include an inorganic semiconductor such as silicon and an organic semiconductor including an organic compound. This embodiment shows an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When T-electron conjugation (resonance) spreads in a plane as in benzene, an electron-donating property (donor property) usually increases; however, having a spherical shape, fullerene has a high electron-accepting property although π-electron conjugation widely spreads therein. The high electron-accepting property efficiently causes rapid charge separation and is useful for the light-receiving device. Both C₆₀ and C₇₀ have a wide absorption band in the visible light region, and C₇₀ is especially preferable because of having a larger π-electron conjugation system and a wider absorption band in the long wavelength region than C₆₀. Other examples of the fullerene derivative include [6,6]-phenyl-C71-butyric acid methyl ester (abbreviation: PC70BM), [6,6]-phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Another example of an n-type semiconductor material is a perylenetetracarboxylic derivative such as N,N′-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Examples of a p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

Either a low molecular compound or a high molecular compound can be used for the light-emitting devices and the light-receiving device, and an inorganic compound may also be included. Each of the layers included in the light-emitting devices and the light-receiving device can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (Cul) can be used, for example. As the electron-transport material or the hole-blocking material, an inorganic compound such as zinc oxide (ZnO) or an organic compound such as polyethylenimine ethoxylated (PEIE) can be used. The light-receiving device may include a mixed film of PEIE and ZnO, for example.

For the active layer, a high molecular compound such as poly[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

A more specific structure example of the display apparatus of one embodiment of the present invention will be described below.

### Structure Example 3

### Structure Example 3-1

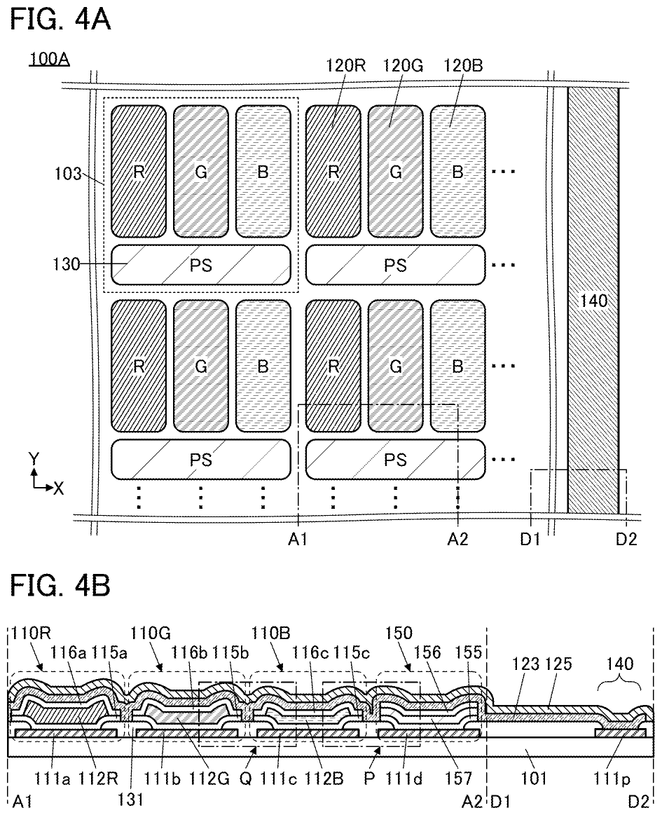

FIG. 4A is a schematic top view illustrating a structure example of a display apparatus 100A of one embodiment of the present invention. The display apparatus 100A includes a display portion where a plurality of pixels 103 are arranged in a matrix, and a connection portion 140 outside the display portion.

Each of the pixels 103 includes a plurality of subpixels. In the example illustrated FIG. 4A, the pixel 103 includes a subpixel 120R, a subpixel 120G, a subpixel 120B, and a subpixel 130. The subpixel 120R includes a light-emitting device 110R that emits red light. The subpixel 120G includes a light-emitting device 110G that emits green light. The subpixel 120B includes a light-emitting device 110B that emits blue light. The subpixel 130 includes a light-receiving device 150. In FIG. 4A, light-emitting regions of the light-emitting devices 110 are denoted by R, G, and B to easily differentiate the devices. In addition, light-receiving regions of the light-receiving devices 150 are denoted by PS.

FIG. 4B is a cross-sectional view taken along a dashed-dotted line A1-A2 and a dashed-dotted line D1-D2 in FIG. 4A. The light-emitting device 110R, the light-emitting device 110G, the light-emitting device 110B, and the light-receiving device 150 are provided over a substrate 101.

Note that in the case where the expression “B over A” or “B under A” is used in this specification and the like, for example, A and B do not always need to include a region where they are in contact with each other.

The light-emitting device 110R includes an electrode 111a, a first layer 115a, a light-emitting layer 112R, a second layer 116a, and a common electrode 123. The light-emitting device 110G includes an electrode 111b, a first layer 115b, a light-emitting layer 112G, a second layer 116b, and the common electrode 123. The light-emitting device 110B includes an electrode 111c, a first layer 115c, a light-emitting layer 112B, a second layer 116c, and the common electrode 123. The light-receiving device 150 includes an electrode 111d, a third layer 155, an active layer 157, a fourth layer 156, and the common electrode 123. The electrode 111a, the electrode 111b, the electrode 111c, and the electrode 111d function as pixel electrodes.

The above-described structures of the light-emitting device 20R, the light-emitting device 20G, and the light-emitting device 20B can be used for the light-emitting device 110R, the light-emitting device 110G, and the light-emitting device 110B. The above-described structure of the light-receiving device 30PS can be used for the light-receiving device 150.

The common electrode 123 is provided to be shared by the light-emitting devices and the light-receiving device. The components included in the light-emitting devices and the light-receiving device other than the common electrode 123 are not shared by the light-emitting devices and the light-receiving device and are provided separately.

Specifically, the electrode 111a, the electrode 111b, the electrode 111c, and the electrode 111d are not shared by the light-emitting devices 110 and the light-receiving device 150 and are provided separately. The first layer 115a, the first layer 115b, and the first layer 115c are not shared by the light-emitting devices 110 and are provided separately. Similarly, the light-emitting layer 112R, the light-emitting layer 112G, and the light-emitting layer 112B are not shared by the light-emitting devices 110 and are provided separately. Similarly, the second layer 116a, the second layer 116b, and the second layer 116c are not shared by the light-emitting devices 110 and are provided separately.

The third layer 155, the active layer 157, and the fourth layer 156 of the light-receiving device 150 are not shared with the light-emitting devices 110 and are provided separately. Since the third layer 155, the active layer 157, and the fourth layer 156 of the light-receiving device 150 are provided separately from the light-emitting devices 110, a leakage current can be inhibited from flowing from the light-emitting devices 110 to the light-receiving device 150. Therefore, the light-receiving device 150 can have a high SN ratio and high accuracy.

The third layer 155 of the light-receiving device 150 is preferably formed through a process different from processes for the functional layers (e.g., the first layer 115a, the first layer 115b, and the first layer 115c) of the light-emitting devices 110. When the third layer 155 is formed through a different process, a material more suitable for the light-receiving device 150 can be used for the third layer 155. In other words, the third layer 155 can contain an organic compound different from the organic compound contained in the functional layers of the light-emitting devices 110.

Similarly, the fourth layer 156 of the light-receiving device 150 is preferably formed through a process different from processes for the functional layers (e.g., the second layer 116a, the second layer 116b, and the second layer 116c) of the light-emitting devices 110. When the fourth layer 156 is formed through a different process, a material more suitable for the light-receiving device 150 can be used for the fourth layer 156. In other words, the fourth layer 156 can contain an organic compound different from the organic compound contained in the functional layers of the light-emitting devices 110.

An insulating layer 131 is provided to cover the end portion of the electrode 111a, the end portion of the electrode 111b, the end portion of the electrode 111c, and the end portion of the electrode 111d. The end portion of the insulating layer 131 is preferably tapered. Note that the insulating layer 131 is not necessarily provided when not needed.

In this specification and the like, a tapered shape indicates a shape in which at least part of the side surface of a structure is inclined to a substrate surface. For example, a region where the angle between the inclined side surface and the substrate surface (also referred to as a taper angle) is less than 90° is preferably included.

The first layer 115a, the first layer 115b, the first layer 115c, and the third layer 155 each include a region in contact with the top surface of the electrode 111 and a region in contact with the surface of the insulating layer 131. The end portion of the first layer 115a, the end portion of the first layer 115b, the end portion of the first layer 115c, and the end portion of the third layer 155 are positioned over the insulating layer 131.

A conductive film having a property of transmitting visible light is used for either one of the electrodes 111 or the common electrode 123, and a conductive film with a property of reflecting visible light is used for the other. When a conductive film having a property of transmitting visible light is used for the electrodes 111 and a conductive film having a reflective property is used for the common electrode 123, the display apparatus 100A can have a bottom emission structure. In contrast, when a conductive film having a reflective property is used for the electrodes 111 and a conductive film having a light-transmitting property is used for the common electrode 123, the display apparatus 100A can have a top emission structure. Note that when a conductive film having a light-transmitting property is used for both the electrodes 111 and the common electrode 123, the display apparatus 100A can have a dual emission structure.

A protective layer 125 is provided over the common electrode 123. The protective layer 125 has a function of preventing diffusion of impurities such as water into the light-emitting devices from above.

The protective layer 125 can have a single-layer structure or a stacked-layer structure including at least an inorganic insulating film. For the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 125.

Note that in this specification and the like, oxynitride refers to a material that contains more oxygen than nitrogen, and nitride oxide refers to a material that contains more nitrogen than oxygen. For example, a silicon oxynitride refers to a material that contains oxygen at a higher proportion than nitrogen, and a silicon nitride oxide refers to a material that contains nitrogen at a higher proportion than oxygen.

As the protective layer 125, a stacked-layer film of an inorganic insulating film and an organic insulating film can be used. For example, a structure in which an organic insulating film is sandwiched between a pair of inorganic insulating films is preferable. Furthermore, it is preferable that the organic insulating film function as a planarization film. With this structure, the top surface of the organic insulating film can be flat, and accordingly, coverage with the inorganic insulating film over the organic insulating film is improved, leading to an improvement in barrier properties. Moreover, the top surface of the protective layer 125 is flat, which is preferable because the influence of an uneven shape due to a lower structure can be reduced in the case where a component (e.g., a color filter, an electrode of a touch sensor, a lens array, or the like) is provided above the protective layer 125.

As illustrated in FIG. 4B, the connection portion 140 includes the common electrode 123 and a connection electrode 111p. The connection portion 140 can be referred to as a cathode contact portion. The same material as the electrode 111a, the electrode 111b, the electrode 111c, and the electrode 111d can be used for the connection electrode 111p. The connection electrode 111p can be formed through the same process as the electrode 111a, the electrode 111b, the electrode 111c, and the electrode 111d. The insulating layer 131 is provided to cover the end portion of the connection electrode 111p. The protective layer 125 is provided to cover the common electrode 123.

Although the connection portion 140 is positioned on the right side of the display portion in the top view in the example illustrated in FIG. 4A, there is no particular limitation on the position of the connection portion 140. The connection portion 140 only needs to be provided on at least one of the top, right, left, and bottom sides of the display portion in the top view and may be provided to surround the four sides of the display portion. The number of connection portions 140 may be one or more.

The connection portion 140 can be provided along the outer periphery of the display portion. For example, the connection portion 140 may be provided along one side of the outer periphery of the display portion or two or more sides of the outer periphery of the display portion. Note that there is no particular limitation on the top surface shape of the connection portion 140. In the case where the top surface shape of the display portion is a rectangle, the top surface shape of the connection portion 140 can be a band shape, an L shape, a square bracket shape, or a quadrangle, for example.

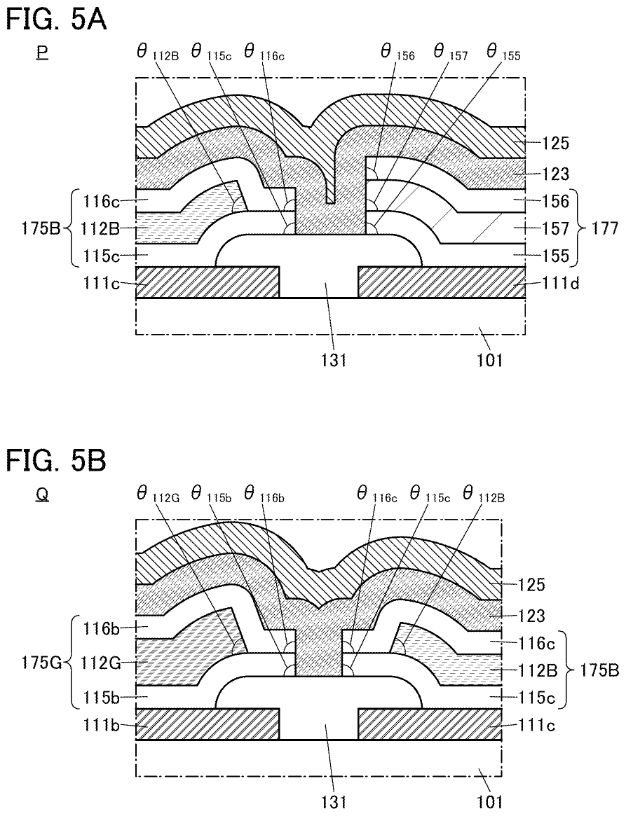

FIG. 5A is an enlarged view of a region P indicated by a dashed-dotted line in FIG. 4B, and FIG. 5B is an enlarged view of a region Q. The light-emitting device 110B and the light-receiving device 150 are shown on the left side and the right side in FIG. 5A, respectively. The light-emitting device 110G and the light-emitting device 110B are shown on the left side and the right side in FIG. 5B, respectively.

As illustrated in FIG. 5A, the end portion of the light-emitting layer 112B is positioned inward from the end portion of the first layer 115c in the light-emitting device 110B. In addition, the end portion of the light-emitting layer 112B is positioned inward from the end portion of the second layer 116c. The top surface and side surface of the light-emitting layer 112B are in contact with the second layer 116c. That is, the top surface and side surface of the light-emitting layer 112B are covered with the second layer 116c. Since the top surface and side surface of the light-emitting layer 112B are covered with the second layer 116c, impurities can be inhibited from diffusing to the light-emitting layer 112B. Therefore, the reliability of the light-emitting device 110B can be increased. Examples of the impurities include a metal component included in the common electrode 123.

The side surface of the light-emitting layer 112B is preferably tapered. An angle θ112B formed by the side surface of the light-emitting layer 112B and a formation surface (here, the first layer 115c) is preferably small. Specifically, the angle θ112B is preferably greater than 0° and less than 90° C., further preferably greater than 0° and less than 60°, still further preferably greater than 0° and less than 50°, yet still further preferably greater than 0° and less than 40°, yet still further preferably greater than 0° and less than 30°. Such a small angle θ112B can improve the step coverage with the layer (e.g., the second layer 116c) formed over the light-emitting layer 112B and the first layer 115c, thereby inhibiting generation of defects such as disconnection and a void in the layer.

Note that the light-emitting layer 112B can be formed using an FMM. When the light-emitting layer 112B is formed using an FMM, its thickness becomes smaller as closer to its end portion and the angle θ112B becomes extremely small in some cases. For example, the angle θ112B is sometimes greater than 0° and less than 30°. Therefore, the side surface and top surface of the light-emitting layer 112B are connected continuously and difficult to clearly distinguish from each other in some cases.

The end portion of the second layer 116c is aligned or substantially aligned with the end portion of the first layer 115c. In other words, the second layer 116c has the same or substantially the same top surface shape as the first layer 115c. For example, the first layer 115c and the second layer 116c can be formed by forming a first film to be the first layer 115c and a second film to be the second layer 116c and then processing them with the use of the same mask.

Note that in this specification and the like, the expression “having the same or substantially the same top surface shape” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “having the same or substantially the same top surface shape”.

Note that the side surfaces of the first layer 115c and the second layer 116c are preferably perpendicular or substantially perpendicular to their formation surfaces. For example, an angle 0115c formed by the side surface of the first layer 115c and the formation surface (here, the insulating layer 131) is preferably greater than or equal to 60° and less than or equal to 90°. An angle θ116c formed by the side surface of the second layer 116c and the formation surface (here, the first layer 115c) is preferably greater than or equal to 60° and less than or equal to 90°.

Note that although the light-emitting device 110B is described as an example here, the same applies to the light-emitting device 20R and the light-emitting device 20B.

As illustrated in FIG. 5A, the end portion of the third layer 155, the end portion of the active layer 157, and the end portion of the fourth layer 156 are aligned or substantially aligned with one another in the light-receiving device 150. In other words, the third layer 155, the active layer 157, and the fourth layer 156 have the same or substantially the same top surface shape. For example, the third layer 155, the active layer 157, and the fourth layer 156 can be formed by forming a third film that is to be the third layer 155, an active film that is to be the active layer 157, and a fourth film that is to be the fourth layer 156 and then processing them with the use of the same mask.

The side surfaces of the third layer 155, the active layer 157, and the fourth layer 156 are preferably perpendicular or substantially perpendicular to their formation surfaces. For example, an angle θ₁₅₅ formed by the side surface of the third layer 155 and the formation surface (here, the insulating layer 131) is preferably greater than or equal to 60° and less than or equal to 90°. An angle θ₁₅₇ formed by the side surface of the active layer 157 and the formation surface (here, the third layer 155) is preferably greater than or equal to 60° and less than or equal to 90°. An angle θ₁₅₆ formed by the side surface of the fourth layer 156 and the formation surface (here, the active layer 157) is preferably greater than or equal to 60° and less than or equal to 90°. The angle θ₁₅₅, the angle θ₁₅₆, and the angle θ₁₅₇ are each preferably greater than the angle θ₁₁₂B. Similarly, the angle θ₁₅₅, the angle θ₁₅₆, and the angle θ₁₅₇ are each preferably greater than the angle formed by the side surface of the light-emitting layer 112R and the formation surface. The angle θ₁₅₅, the angle θ₁₅₆, and the angle θ₁₅₇ are each preferably greater than the angle formed by the side surface of the light-emitting layer 112G and the formation surface.

It is preferable that a light-receiving layer 177 of the light-receiving device 150 not include a layer shared with an EL layer 175B of the light-emitting device 110B and not include a region in contact with the EL layer 175B as illustrated in FIG. 5A. That is, it is preferable that the light-receiving layer 177 be separated from the EL layer 175B. Note that the light-emitting device 110B is illustrated as the light-emitting device adjacent to the light-receiving device 150 in FIG. 5A; however, one embodiment of the present invention is not limited thereto. A light-receiving layer included in a light-receiving device is preferably separated from an EL layer included in a light-emitting device adjacent to the light-receiving device. Note that the same applies to the case where two light-receiving devices are adjacent to each other; a light-receiving layer included in one of the light-receiving devices is preferably separated from a light-receiving layer included in the other of the light-receiving devices.

It is preferable that an EL layer 175G of the light-emitting device 110G not include a layer shared with the EL layer 175B of the light-emitting device 110B and not include a region in contact with the EL layer 175B as illustrated in FIG. 5B. That is, it is preferable that the EL layer 175G be separated from the EL layer 175B. Note that the light-emitting device 110B is illustrated as the light-emitting device adjacent to the light-emitting device 110G in FIG. 5B; however, one embodiment of the present invention is not limited thereto. An EL layer included in a light-emitting device is preferably separated from an EL layer included in a light-emitting device adjacent to the light-emitting device.

### Structure Example 3-2

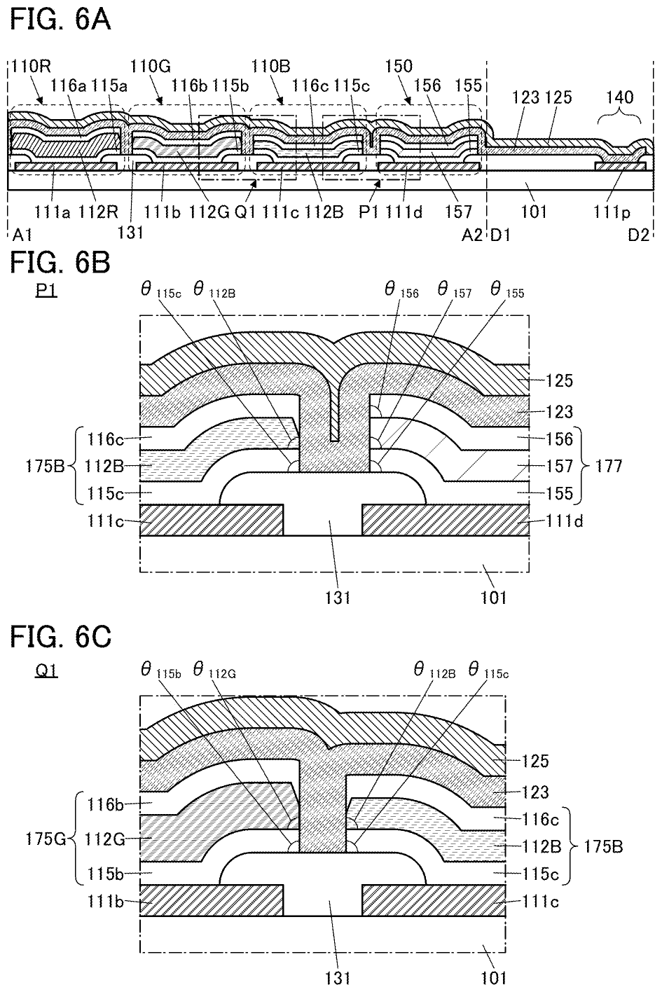

FIG. 6A illustrates a structure different from the structure illustrated in FIG. 4B. The light-emitting device 110R, the light-emitting device 110G, and the light-emitting device 110B illustrated in FIG. 6A differ from the structure illustrated in FIG. 4B mainly in that the light-emitting layer 112R, the light-emitting layer 112G, and the light-emitting layer 112B each include a region in contact with the common electrode 123. Note that in this specification and the like, the light-emitting layer 112R, the light-emitting layer 112G, and the light-emitting layer 112B are collectively referred to as light-emitting layers 112 in some cases.

Specifically, the end portion of the first layer 115a, the end portion of the light-emitting layer 112R, and the end portion of the second layer 116a are aligned or substantially aligned with one another in the light-emitting device 110R. In other words, the first layer 115a, the light-emitting layer 112R, and the second layer 116a have the same or substantially the same top surface shape. The same applies to the light-emitting device 110G and the light-emitting device 110B. Such a structure can increase the areas of the light-emitting layers 112, thereby increasing the areas of the light-emitting regions of the light-emitting devices 110. That is, the display apparatus can have a high aperture ratio.

FIG. 6B is an enlarged view of a region P1 indicated by a dashed-dotted line in FIG. 6A, and FIG. 6C is an enlarged view of a region Q1. The light-emitting device 110B and the light-receiving device 150 are shown on the left side and the right side in FIG. 6B, respectively. The light-emitting device 110G and the light-emitting device 110B are shown on the left side and the right side in FIG. 6C, respectively.

As illustrated in FIG. 6B, the side surfaces of the first layer 115c and the light-emitting layer 112B are preferably perpendicular or substantially perpendicular to their formation surfaces in the light-emitting device 110B. For example, the angle θ₁₁₅c formed by the side surface of the first layer 115c and the formation surface (here, the insulating layer 131) is preferably greater than or equal to 60° and less than or equal to 90°. The angle θ₁₁₂B formed by the side surface of the light-emitting layer 112B and the formation surface (here, the first layer 115c) is preferably greater than or equal to 60° and less than or equal to 90°. Note that the thickness of a portion of the light-emitting layer 112B around the end portion is sometimes smaller than the thickness of a portion positioned inward from the end portion.

As illustrated in FIG. 6C, the side surfaces of the first layer 115b and the light-emitting layer 112G are preferably perpendicular or substantially perpendicular to their formation surfaces in the light-emitting device 110G. For example, an angle θ₁₁₅b formed by the side surface of the first layer 115b and the formation surface (here, the insulating layer 131) is preferably greater than or equal to 60° and less than or equal to 90°. An angle θ₁₁₂G formed by the side surface of the light-emitting layer 112G and the formation surface (here, the first layer 115b) is preferably greater than or equal to 60° and less than or equal to 90°. Note that the thickness of a portion of the light-emitting layer 112G around the end portion is sometimes smaller than the thickness of a portion positioned inward from the end portion. The same applies to the light-emitting device 110R.

### Structure Example 3-3

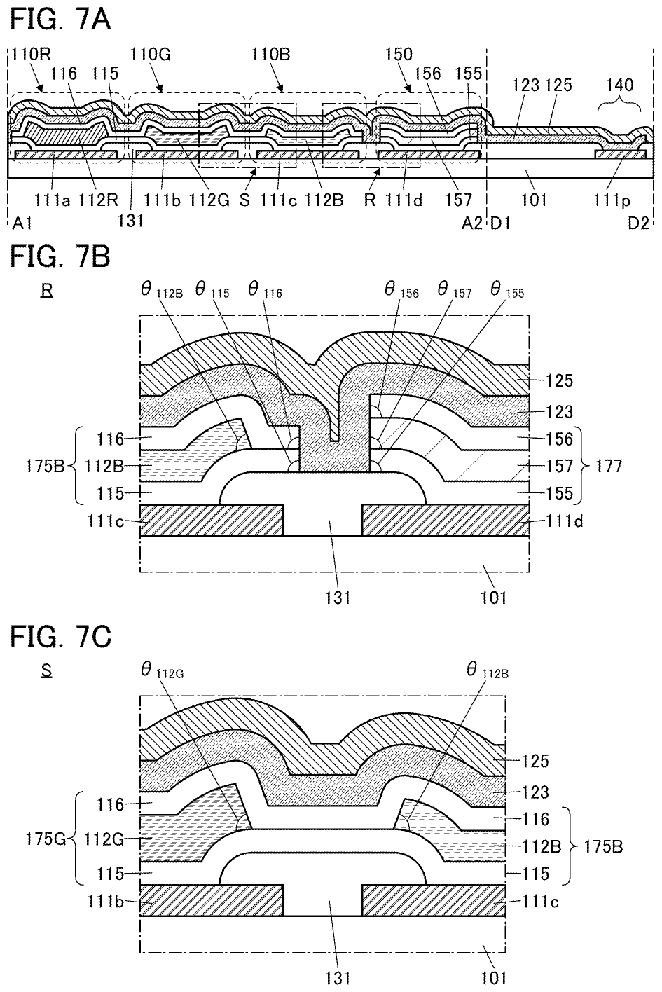

FIG. 7A illustrates a structure different from the structure illustrated in FIG. 4B. The light-emitting device 110R, the light-emitting device 110G, and the light-emitting device 110B illustrated in FIG. 7A differ from the structure illustrated in FIG. 4B mainly in including a first layer 115 instead of the first layer 115a, the first layer 115b, and the first layer 115c and in including a second layer 116 instead of the second layer 116a, the second layer 116b, and the second layer 116c.

Specifically, the light-emitting device 110R includes the first layer 115, the light-emitting layer 112R, and the second layer 116 that are stacked in this order, as an EL layer. The light-emitting device 110G includes the first layer 115, the light-emitting layer 112G, and the second layer 116 that are stacked in this order, as an EL layer. The light-emitting device 110B includes the first layer 115, the light-emitting layer 112B, and the second layer 116 that are stacked in this order, as an EL layer.

The first layer 115 is a layer shared by the light-emitting device 110R, the light-emitting device 110G, and the light-emitting device 110B and can be referred to as a first common layer. Similarly, the second layer 116 can be referred to as a second common layer. A material usable for the first layer 115a, the first layer 115b, and the first layer 115c can be used for the first layer 115. A material usable for the second layer 116a, the second layer 116b, and the second layer 116c can be used for the second layer 116.

FIG. 7B is an enlarged view of a region R indicated by a dashed-dotted line in FIG. 7A, and FIG. 7C is an enlarged view of a region S. The light-emitting device 110B and the light-receiving device 150 are shown on the left side and the right side in FIG. 7B, respectively. The light-emitting device 110G and the light-emitting device 110B are shown on the left side and the right side in FIG. 7C, respectively.

It is preferable that the light-receiving layer 177 of the light-receiving device 150 not include a layer shared with the EL layer 175B of the light-emitting device 110B and not include a region in contact with the EL layer 175B as illustrated in FIG. 7B. In other words, a light-receiving layer included in a light-receiving device is preferably separated from an EL layer included in a light-emitting device adjacent to the light-receiving device. Note that the same applies to the case where two light-receiving devices are adjacent to each other; a light-receiving layer included in one of the light-receiving devices is preferably separated from a light-receiving layer included in the other of the light-receiving devices.

The end portion of the second layer 116 is aligned or substantially aligned with the end portion of the first layer 115 as illustrated in FIG. 7B. In other words, the second layer 116 has the same or substantially the same top surface shape as the first layer 115. For example, the first layer 115 and the second layer 116 can be formed by forming a first film to be the first layer 115 and a second film to be the second layer 116 and then processing them with the use of the same mask.

The side surfaces of the first layer 115 and the second layer 116 are preferably perpendicular or substantially perpendicular to their formation surfaces. For example, an angle 0115 formed by the side surface of the first layer 115 and the formation surface (here, the insulating layer 131) is preferably greater than or equal to 60° and less than or equal to 90°. An angle θ₁₁₆ formed by the side surface of the second layer 116 and the formation surface (here, the first layer 115) is preferably greater than or equal to 60° and less than or equal to 90°.

As illustrated in FIG. 7C, the light-emitting layer 112G of the light-emitting device 110G shares the first layer 115 and the second layer 116 with the EL layer 175B of the light-emitting device 110B. Note that although the light-emitting device 110B is illustrated as a light-emitting device adjacent to the light-emitting device 110G in FIG. 7C, the same applies to the other two adjacent light-emitting devices. The two adjacent light-emitting devices can share the first layer 115 and the second layer 116.

### Structure Example 3-4

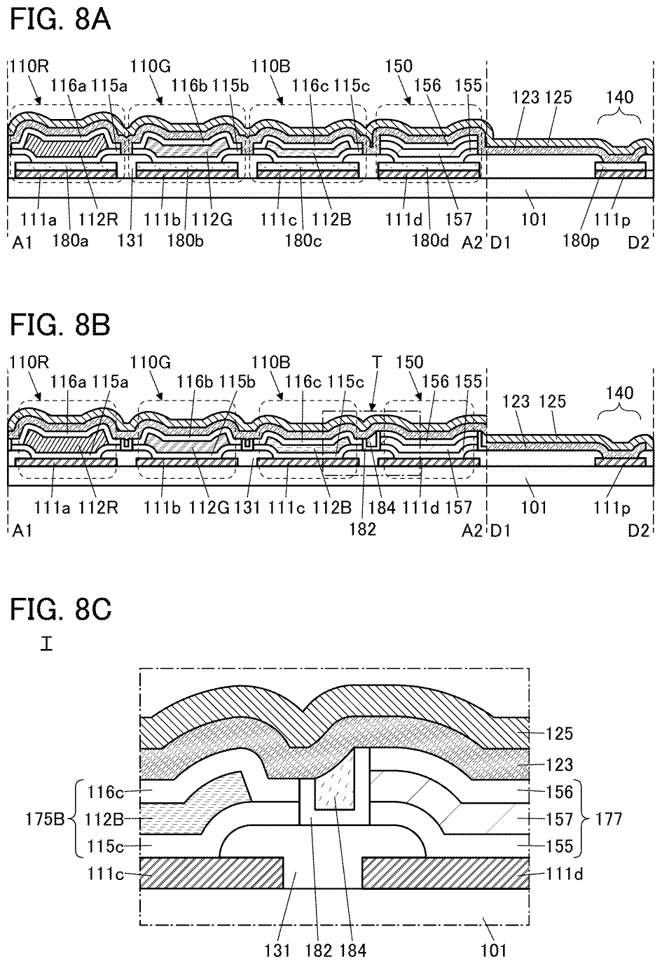

FIG. 8A illustrates a structure different from the structure illustrated in FIG. 4B. The light-emitting device 110R, the light-emitting device 110G, and the light-emitting device 110B illustrated in FIG. 8A differ from the structure illustrated in FIG. 4B mainly in including an optical adjustment layer between the pixel electrode and the EL layer. The light-receiving device 150 differs from the structure illustrated in FIG. 4B mainly in including an optical adjustment layer between the pixel electrode and the light-receiving layer. Specifically, the light-emitting device 110R includes an optical adjustment layer 180a between the electrode 111a and the first layer 115a. The light-emitting device 110G includes an optical adjustment layer 180b between the electrode 111b and the first layer 115b. The light-emitting device 110B includes an optical adjustment layer 180c between the electrode 111c and the first layer 115c. The light-receiving device 150 includes an optical adjustment layer 180d between the electrode 111d and the third layer 155. Furthermore, in the connection portion 140, a conductive layer 180p is provided between the connection electrode 111p and the common electrode 123. The conductive layer 180p can be formed by processing a conductive film that is to be the optical adjustment layer 180a, the optical adjustment layer 180b, the optical adjustment layer 180c, and the optical adjustment layer 180d. In the connection portion 140, the connection electrode 111p and the common electrode 123 are electrically connected through the conductive layer 180p.

It is preferable that a conductive material having a high transmitting property with respect to visible light be used for the optical adjustment layer 180a, the optical adjustment layer 180b, the optical adjustment layer 180c, and the optical adjustment layer 180d. It is further preferable that a conductive material having a high transmitting property with respect to visible light and infrared light be used for the optical adjustment layer 180a, the optical adjustment layer 180b, the optical adjustment layer 180c, and the optical adjustment layer 180d. For example, a conductive oxide such as indium oxide, indium tin oxide, indium zinc oxide, zinc oxide, zinc oxide containing gallium, indium tin oxide containing silicon, or indium zinc oxide containing silicon can be used for the optical adjustment layer 180a, the optical adjustment layer 180b, the optical adjustment layer 180c, and the optical adjustment layer 180d.

Here, a conductive film having a reflecting property with respect to visible light is used for the electrode 111a, the electrode 111b, the electrode 111c, and the electrode 111d, and a conductive film having a reflecting property and a transmitting property with respect to visible light is used for the common electrode 123. In this case, what is called a microcavity structure is achieved in the light-emitting device 110R, the light-emitting device 110G, the light-emitting device 110B, and the light-receiving device 150. The light-emitting device 110R, the light-emitting device 110G, and the light-emitting device 110B can each be a light-emitting device with high color purity, in which light of a specific wavelength is intensified. The light-receiving device 150 can be a light-receiving device with high sensitivity, in which light of a specific wavelength to be detected is intensified.

Note that when the optical adjustment layer 180a, the optical adjustment layer 180b, the optical adjustment layer 180c, and the optical adjustment layer 180d have different thicknesses, their optical lengths can be different from one another. The optical adjustment layers may be formed using conductive films with different thicknesses or may have different structures by employing a single-layer structure and a multi-layer structure.

### Structure Example 3-5

FIG. 8B illustrates a structure different from the structure illustrated in FIG. 4B. The display apparatus illustrated in FIG. 8B differs from the display apparatus illustrated in FIG. 4B in including a resin layer 184 between two adjacent light-emitting devices and between a light-emitting device and a light-receiving device that are adjacent to each other. Note that the same applies to the case where two light-receiving devices are adjacent to each other, and the resin layer 184 may also be provided between two adjacent light-emitting devices.

FIG. 8C illustrates an enlarged view of a region T indicated by a dashed-dotted line in FIG. 8B. The light-emitting device 110B and the light-receiving device 150 are shown on the left side and the right side in FIG. 8C, respectively. An insulating layer 182 may be provided between the light-emitting device 110B and the resin layer 184 and between the light-receiving device 150 and the resin layer 184. The insulating layer 182 is provided along the side surface of the EL layer 175B, the side surface of the light-receiving layer 177, and the top surface of the insulating layer 131. The resin layer 184 has a function of filling a depressed portion located between the light-emitting device 110B and the light-receiving device 150 and planarizing its top surface. Providing the resin layer 184 can increase step coverage with the common electrode 123 and the protective layer 125 formed thereover. Since the insulating layer 182 is provided in contact with the side surface of the EL layer 175B and the side surface of the light-receiving layer 177, a structure in which the resin layer 184 is not in contact with these layers can be achieved. When the EL layer 175B and the light-receiving layer 177 are in contact with the resin layer 184, the EL layer 175B and the light-receiving layer 177 might be dissolved owing to a component (e.g., an organic solvent) contained in the resin layer 184. Providing the insulating layer 182 can protect the side surface of the EL layer 175B and the side surface of the light-receiving layer 177. It is particularly preferable that the insulating layer 182 cover the side surface of the active layer 157. Note that a structure in which no insulating layer 182 is provided may be employed.

The insulating layer 182 can be an insulating layer containing an inorganic material. As the insulating layer 182, an inorganic insulating film such as an oxide insulating film, a nitride insulating film, an oxynitride insulating film, or a nitride oxide insulating film can be used, for example. The insulating layer 182 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when an inorganic insulating film such as an aluminum oxide film, a hafnium oxide film, or a silicon oxide film formed by an ALD method is used as the insulating layer 182, the insulating layer 182 can have few pin holes and an excellent function of protecting the EL layer.

The insulating layer 182 can be formed by a sputtering method, a CVD method, a PLD method, an ALD method, or the like. The insulating layer 182 is preferably formed by an ALD method achieving good coverage.

An insulating layer containing an organic material can be suitably used for the resin layer 184. For example, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used for the resin layer 184. An organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the resin layer 184.

A photosensitive resin can be used for the resin layer 184. A photoresist may be used for the photosensitive resin. The photosensitive resin can be of positive or negative type. A colored material (e.g., a material containing a black pigment) may be used for the resin layer 184 so that the resin layer 184 has a function of blocking stray light from an adjacent pixel and inhibiting color mixture. A reflective film (e.g., a metal film containing one or more selected from silver, palladium, copper, titanium, and aluminum) may be provided between the insulating layer 182 and the resin layer 184 so that light emitted from the light-emitting layer is reflected by the reflective film; thus, the function of improving the light extraction efficiency may be added.

The top surface of the resin layer 184 is preferably as flat as possible but is gently curved in some cases. The top surface of the resin layer 184 may have a wave shape with a depressed portion and a projected portion or may be a convex surface, a concave surface, or a flat surface, for example.

### Structure Example 3-6

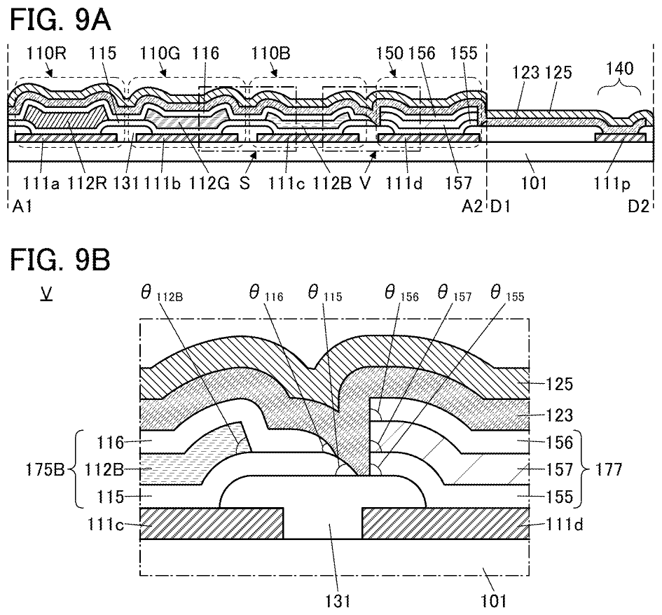

FIG. 9A illustrates a structure different from the structure illustrated in FIG. 7A. The light-emitting device 110R, the light-emitting device 110G, and the light-emitting device 110B illustrated in FIG. 9A differ from the structure illustrated in FIG. 4B mainly in the shapes of the side surface of the first layer 115 and the side surface of the second layer 116.

FIG. 9B is an enlarged view of a region V indicated by a dashed-dotted line in FIG. 9A. FIG. 7C can be referred to for the enlarged view of the region S. The light-emitting device 110B and the light-receiving device 150 are shown on the left side and the right side in FIG. 9B, respectively. The light-emitting device 110G and the light-emitting device 110B are shown on the left side and the right side in FIG. 7C, respectively.

The side surface of the first layer 115 is preferably tapered. The angle θ₁₁₅ formed by the side surface of the first layer 115 and the formation surface (here, the insulating layer 131) is preferably small. Specifically, the angle θ₁₁₅ is preferably greater than 0° and less than 90° C., further preferably greater than 0° and less than 60°, still further preferably greater than 0° and less than 50°, yet still further preferably greater than 0° and less than 40°, yet still further preferably greater than 0° and less than 30°. Such a small angle θ₁₁₅ can improve the step coverage with the layer (e.g., the second layer 116) formed over the insulating layer 131 and the first layer 115, thereby inhibiting generation of defects such as disconnection and a void.

The side surface of the second layer 116 is preferably tapered. The angle θ₁₁₆ formed by the side surface of the second layer 116 and the formation surface (here, the first layer 115) is preferably small. Specifically, the angle θ₁₆ is preferably greater than 0° and less than 90° C., further preferably greater than 0° and less than 60°, still further preferably greater than 0° and less than 50°, yet still further preferably greater than 0° and less than 40°, yet still further preferably greater than 0° and less than 30°. Such a small angle θ₁₁₆ can improve the step coverage with the layer (e.g., the common electrode 123) formed over the first layer 115 and the second layer 116, thereby inhibiting generation of defects such as disconnection and a void.

As illustrated in FIG. 9B, the end portion of the second layer 116 is positioned inward from the end portion of the first layer 115. Alternatively, the end portion of the second layer 116 is aligned or substantially aligned with the end portion of the first layer 115.

### Manufacturing Method Example 1

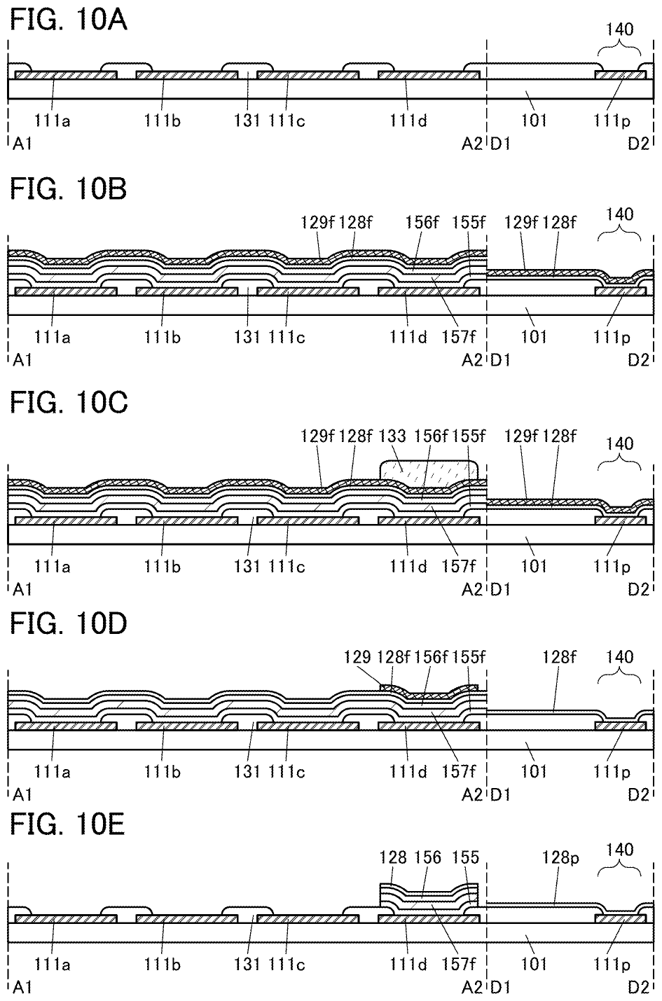

An example of a method for manufacturing the display apparatus of one embodiment of the present invention will be described below with reference to drawings. Here, a method for manufacturing the display apparatus 100 illustrated in FIG. 4B is described as an example. FIG. 10A to FIG. 13D are schematic cross-sectional views in processes of the method for manufacturing the display apparatus 100. FIG. 10A to FIG. 13D each show a cross section corresponding to a dashed-dotted line A1-A2 and a cross section corresponding to a dashed-dotted line D1-D2 in FIG. 4A.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method, a thermal CVD method, and the like. As an example of the thermal CVD method, a metal organic chemical vapor deposition (MOCVD: Metal Organic CVD) method can be given.

Thin films included in the display apparatus (insulating films, semiconductor films, conductive films, and the like) can be formed by a method such as spin coating, dipping, spray coating, ink-jetting, dispensing, screen printing, offset printing, a doctor knife method, slit coating, roll coating, curtain coating, or knife coating.

The thin films included in the display apparatus can be processed by a photolithography method or the like. Besides, the thin films may be processed by a nanoimprinting method, a sandblasting method, a lift-off method, or the like.

There are the following two typical examples of a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. In addition, light exposure may be performed by liquid immersion exposure technique. Alternatively, for the light used for the exposure, extreme ultraviolet (EUV) light, X-rays, or the like may be used. Furthermore, instead of the light used for the light exposure, an electron beam can also be used. Extreme ultraviolet light, X-rays, or an electron beam is preferably used, in which case extremely minute processing can be performed. Note that when light exposure is performed by scanning of a beam such as an electron beam, a photomask is not needed.

For etching of the thin films, a dry etching method, a wet etching method, a sandblast method, or the like can be used.

[Formation of Electrode 111a to Electrode 111d and Connection Electrode 111p]

The electrode 111a, the electrode 111b, the electrode 111c, the electrode 111d, and the connection electrode 111p are formed over the substrate 101. First, a conductive film is deposited, a resist mask is formed by a photolithography method, and an unnecessary portion of the conductive film is removed by etching. After that, the resist mask is removed, whereby the electrode 111a, the electrode 111b, the electrode 111c, and the connection electrode 111p can be formed.

In the case where a conductive film having a reflective property with respect to visible light is used for the pixel electrodes, it is preferable to use a material having reflectance as high as possible in the entire wavelength range of visible light (e.g., silver, aluminum, or the like). This can increase color reproducibility as well as light extraction efficiency of the light-emitting devices.

### [Formation of Insulating Layer 131]

Next, the insulating layer 131 is formed to cover the end portions of the electrode 111a, the electrode 111b, the electrode 111d, the electrode 111c, and the connection electrode 111p (FIG. 10A). An organic insulating film or an inorganic insulating film can be used for the insulating layer 131. The end portion of the insulating layer 131 preferably has a tapered shape to improve step coverage with a film in a later step. In particular, when an organic insulating film is used, a photosensitive material is preferably used, in which case the shape of the edge portion can be easily controlled by the conditions of light exposure and development. Note that for the insulating layer 131, an inorganic insulating film may be used. Using an inorganic insulating film for the insulating layer 131 enables the display apparatus 100 to have high resolution.

[Formation of Functional Film 155f, Active Film 157f, and Functional Film 156f]

Next, a functional film 155f to be the third layer 155 later, an active film 157f to be the active layer 157, and a functional film 156f to be the fourth layer 156 are deposited in this order over the electrode 111a, the electrode 111b, the electrode 111c, the electrode 111d, and the insulating layer 131. The functional film 155f, the active film 157f, and the functional film 156f can each be formed by, for example, an evaporation method, a sputtering method, or an inkjet method. Without limitation to this, the above-described deposition method can be used as appropriate. Note that in this specification and the like, the functional film 155f, the active film 157f, and the functional film 156f are collectively referred to as a light-receiving film in some cases.

It is preferable that the functional film 155f, the active film 157f, and the functional film 156f not be provided over the connection electrode 111p. For example, when the functional film 155f, the active film 157f, and the functional film 156f are each formed by an evaporation method or a sputtering method, a shielding mask may be used such that the functional film 155f, the active film 157f, and the functional film 156f are not deposited over the connection electrode 111p.

[Formation of Sacrificial Film 128f and Sacrificial Film 129f]

Next, a sacrificial film 128f and a sacrificial film 129f are formed in this order over the functional film 156f (FIG. 10B). The sacrificial film 128f is provided in contact with the top surface of the connection electrode 111p.

As the sacrificial film 128f, it is possible to favorably use a film highly resistant to etching treatment on the functional film 156f, the active film 157f, and the functional film 155f, i.e., a film having high etching selectivity. Furthermore, as the sacrificial film 128f, it is possible to favorably use a film having high etching selectivity with respect to the sacrificial film 129f described later. Furthermore, as the sacrificial film 128f, it is particularly preferable to use a film that can be removed by a wet etching method that causes less damage to the functional film 156f, the active film 157f, and the functional film 155f.

As the sacrificial film 128f, an inorganic film such as a metal film, an alloy film, a metal oxide film, a semiconductor film, or an inorganic insulating film can be used, for example. The sacrificial film 128f can be formed by any of a variety of deposition methods such as a sputtering method, an evaporation method, a CVD method, and an ALD method. In particular, an ALD method gives less deposition damage to a formation layer; thus, the sacrificial film 128f, which is directly formed on the functional film 156f, is preferably formed by an ALD method.

For the sacrificial film 128f, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

For the sacrificial film 128f, metal oxide such as indium gallium zinc oxide (In—Ga—Zn oxide, also referred to as IGZO) can be used. It is also possible to use indium oxide, indium zinc oxide (In—Zn oxide), indium tin oxide (In—Sn oxide, also referred to as ITO), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, an indium tin oxide containing silicon can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be used instead of gallium. Specifically, the element M is preferably one or more kinds selected from gallium, aluminum, and yttrium.

For the sacrificial film 128f, oxide such as aluminum oxide, hafnium oxide, or silicon oxide, nitride such as silicon nitride or aluminum nitride, or oxynitride such as silicon oxynitride can be used. Such an inorganic insulating material can be formed by a sputtering method, a CVD method, an ALD method, or the like.

For the sacrificial film 128f, it is preferable to use a material that can be dissolved in a solvent chemically stable with respect to at least the functional film 156f. In particular, a material that is dissolved in water or alcohol can be favorably used for the sacrificial film 128f. In deposition of the sacrificial film 128f, it is preferable that application of such a material that has been dissolved in a solvent such as water or alcohol be performed by a wet deposition method and followed by heat treatment for evaporating the solvent. At this time, the heat treatment is preferably performed in a reduced-pressure atmosphere because the solvent can be removed at a low temperature in a short time and thermal damage to the functional film 156f, the active film 157f, and the functional film 155f can be reduced accordingly.

Examples of the wet deposition method that can be used for forming the sacrificial film 128f include spin coating, dipping, spray coating, ink-jetting, dispensing, screen printing, offset printing, a doctor knife method, slit coating, roll coating, curtain coating, and knife coating.

For the sacrificial film 128f, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

The sacrificial film 129f is used as a hard mask when the sacrificial film 128f is etched later. In a later process of processing the sacrificial film 129f, the sacrificial film 128f is exposed. Thus, the combination of films having high etching selectivity therebetween is selected for the sacrificial film 128f and the sacrificial film 129f. It is thus possible to select a film that can be used for the sacrificial film 129f depending on an etching condition of the sacrificial film 128f and an etching condition of the sacrificial film 129f.

For example, in the case where dry etching using a gas containing fluorine (also referred to as a fluorine-based gas) is used for the etching of the sacrificial film 129f, silicon, silicon nitride, silicon oxide, tungsten, titanium, molybdenum, tantalum, tantalum nitride, an alloy containing molybdenum and niobium, an alloy containing molybdenum and tungsten, or the like can be used for the sacrificial film 129f. Here, a film of metal oxide such as IGZO or ITO is given as a film having high etching selectivity (that is, enabling low etching rate) in dry etching using the fluorine-based gas, and such a film can be used for the sacrificial film 128f.

Without being limited to the above, a material for the sacrificial film 129f can be selected from a variety of materials depending on the etching condition of the sacrificial film 128f and the etching condition of the sacrificial film 129f. For example, any of the films that can be used for the sacrificial film 128f can also be used.

For example, for the sacrificial film 129f, an oxide film can be used. Typically, an oxide film or an oxynitride film such as silicon oxide, silicon oxynitride, aluminum oxide, aluminum oxynitride, hafnium oxide, or hafnium oxynitride can be used.

As the sacrificial film 129f, a nitride film can be used, for example. Specifically, it is also possible to use a nitride such as silicon nitride, aluminum nitride, hafnium nitride, titanium nitride, tantalum nitride, tungsten nitride, gallium nitride, or germanium nitride. Alternatively, for the sacrificial film 129f, a metal such as tungsten, molybdenum, copper, aluminum, titanium, or tantalum or an alloy containing the metal may be used.

For example, it is preferable that an inorganic insulating material such as aluminum oxide, hafnium oxide, or silicon oxide formed by an ALD method be used for the sacrificial film 128f, and a metal oxide containing indium, such as an indium gallium zinc oxide (an In—Ga—Zn oxide, also referred to as IGZO), formed by a sputtering method be used for the sacrificial film 129f.

For the sacrificial film 129f, it is possible to use a material usable for the functional film 155f, the active film 157f, or the functional film 156f, for example. The use of such a material is preferable because in that case the deposition apparatus can be used in common. Furthermore, the sacrificial film 129f can also be removed at the time of later etching of the functional film 155f, the active film 157f, and the functional film 156f with the sacrificial layer used as a mask, whereby the processes can be simplified.

### [Formation of Sacrificial Layer 129 and Sacrificial Layer 128]

Next, a resist mask 133 is formed over the sacrificial film 129f in a region overlapping with the electrode 111d (FIG. 10C).

For the resist mask 133, a resist material containing a photosensitive resin, such as a positive type resist material or a negative type resist material can be used.

Here, in the case where the sacrificial film 129f is not formed and the resist mask 133 is formed over the sacrificial film 128f, when a defect such as a pinhole exists in the sacrificial film 128f, there is a risk of dissolving the functional film 156f and the like due to a solvent of the resist material. Such a defect can be prevented by using the sacrificial film 129f.

Note that in the case where a film that is unlikely to cause a defect such as a pinhole is used as the sacrificial film 128f, the resist mask 133 may be formed directly on the sacrificial film 128f without using the sacrificial film 129f.

Subsequently, the sacrificial film 129f in a region not covered with the resist mask 133 is removed by etching to form a sacrificial layer 129.

In the etching of the sacrificial film 129f, an etching condition with high selectivity is preferably employed so that the sacrificial film 128f is not removed by the etching. Either wet etching or dry etching can be performed for the etching of the sacrificial film 129f; with use of dry etching, a reduction in area of the sacrificial layer 129 can be inhibited.

Then, the resist mask 133 is removed (FIG. 10D).

The resist mask 133 can be removed by wet etching or dry etching. It is particularly preferable to perform dry etching (also referred to as plasma ashing) using an oxygen gas as an etching gas to remove the resist mask 133.

At this time, the removal of the resist mask 133 is performed in the state where the sacrificial film 128f is provided over the functional film 156f; thus, damage to the functional film 156f, the active film 157f, and the functional film 155f can be reduced. This is particularly preferable in the case where etching using an oxygen gas such as plasma ashing is performed because electrical characteristics of the light-receiving device might be adversely affected when the active film 157f is exposed to oxygen.

Next, the sacrificial film 128f in a region not covered with the sacrificial layer 129 is removed by etching using the sacrificial layer 129 as a mask to form a sacrificial layer 128 in a region overlapping with the electrode 111d and form a sacrificial layer 128p in contact with the top surface of the connection electrode 111p.

Either wet etching or dry etching can be performed for the etching of the sacrificial film 128f; the use of a dry etching method is preferable because a reduction in areas of the sacrificial layer 128 and the sacrificial layer 128p can be inhibited.

### [Formation of Third Layer 155, Active Layer 157, and Fourth Layer 156]

Next, the sacrificial layer 129 is removed by etching, and the functional film 156f, the active film 157f, and the functional film 155f in a region covered with neither the sacrificial layer 128 nor the sacrificial layer 128p are removed by etching, whereby the fourth layer 156, the active layer 157, and the third layer 155 are formed (FIG. 10E).

When the functional film 156f, the active film 157f, and the functional film 155f are etched through the same process as that for the sacrificial layer 129, the processes can be simplified, the productivity can be increased, and the manufacturing cost can be reduced.

In particular, for etching of the functional film 156f, the active film 157f, and the functional film 155f, it is preferable to use dry etching using an etching gas that does not contain oxygen as its main component. In this case, a change in qualities of the functional film 156f, the active film 157f, and the functional film 155f can be inhibited, whereby a highly reliable display apparatus can be achieved. Examples of the etching gas that does not contain oxygen as its main component include CF₄, C₄F₈, SF₆, CHF₃, Cl₂, H₂O, BCl₃, H₂, and a noble gas such as He. Alternatively, a mixed gas of the above gas and a dilution gas that does not contain oxygen can be used as the etching gas.

Note that etching of the functional film 156f, the active film 157f, and the functional film 155f may be separately performed from etching of the sacrificial layer 129. For example, the functional film 156f, the active film 157f, and the functional film 155f may be etched, and then the sacrificial layer 129 may be etched.

[Formation of Functional Film 115f]

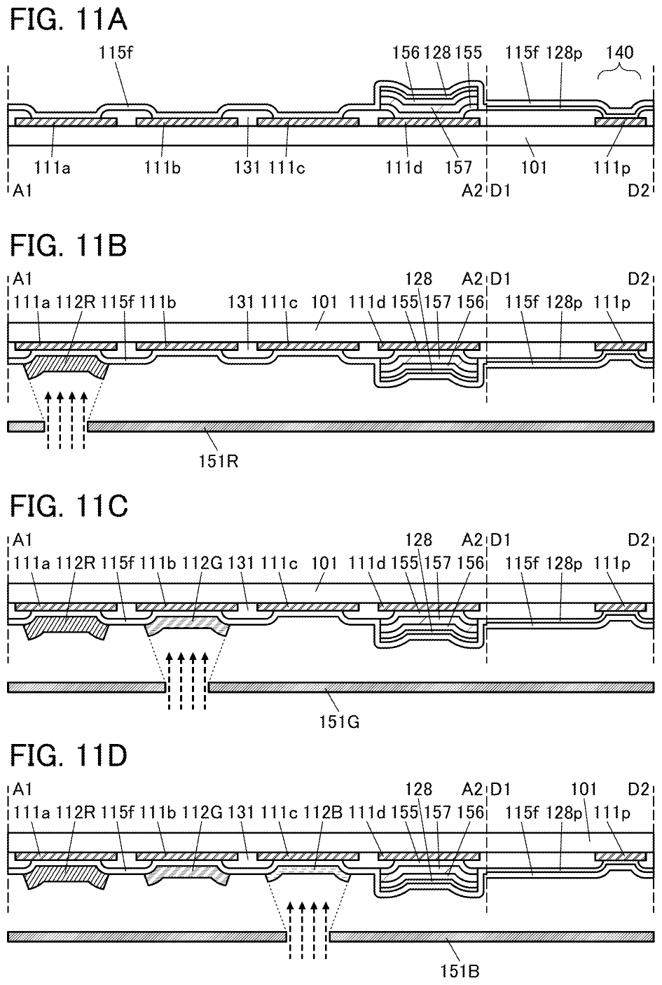

Next, a functional film 115f is deposited to cover the insulating layer 131, the electrode 111a, the electrode 111b, the electrode 111c, the connection electrode 111p, the third layer 155, the active layer 157, the fourth layer 156, and the sacrificial layer 128 (FIG. 11A). The functional film 115f is to be the first layer 115a, the first layer 115b, and the first layer 115c later. The functional film 115f is preferably deposited without using an FMM.

For the deposition of the functional film 115f, a method usable for the above-described deposition of the functional film 155f, the active film 157f, and the functional film 156f can be used. Without limitation to this, the above-described deposition method can be used as appropriate.

### [Formation of Light-Emitting Layer 112R, Light-Emitting Layer 112G, and Light-Emitting Layer 112B]

Next, the light-emitting layer 112R having an island shape is formed over the functional film 115f in a region overlapping with the electrode 111a (FIG. 11B).

The light-emitting layer 112R is preferably formed by a vacuum evaporation method using an FMM. Note that a sputtering method using an FMM or an inkjet method may be used to form the light-emitting layer 112R having an island shape.

FIG. 11B illustrates a state in which the light-emitting layer 112R is formed through an FMM 151R. FIG. 11B illustrates a state of forming the light-emitting layer 112R by a so-called face-down method, in which deposition is performed with the substrate turned upside down so that the surface where the light-emitting layer 112R is formed faces downward.

In a vacuum evaporation method using a FMM, an area wider than an opening portion of the FMM is subjected to evaporation in many cases. As shown by dashed lines in FIG. 11B, the light-emitting layer 112R can be deposited in an area wider than the opening portion of the FMM 151R. In addition, the end portion of the light-emitting layer 112R is tapered.

Then, the light-emitting layer 112G is formed over the functional film 115f in a region overlapping with the electrode 111b with the use of an FMM 151G (FIG. 11C). The end portion of the light-emitting layer 112G is tapered.

Subsequently, the light-emitting layer 112B is formed over the functional film 115f in a region overlapping with the electrode 111c with the use of an FMM 151B (FIG. 11D). The end portion of the light-emitting layer 112B is tapered.

It is preferable that the light-emitting layer 112R, the light-emitting layer 112G, and the light-emitting layer 112B not be formed over the connection electrode 111p.

Although the light-emitting layer 112R, the light-emitting layer 112G, and the light-emitting layer 112B are formed in this order here, the formation order is not limited thereto.

[Formation of Functional Film 116f, Sacrificial Film 118f, and Sacrificial Film 119f]

Next, a functional film 116f is formed to cover the light-emitting layer 112R, the light-emitting layer 112G, the light-emitting layer 112B, and the functional film 115f. The functional film 116f is to be the second layer 116a, the second layer 116b, and the second layer 116c later. For the formation of the functional film 116f, a method usable for the above-described deposition of the functional film 155f, the active film 157f, and the functional film 156f can be used. Without limitation to this, the above-described deposition method can be used as appropriate.

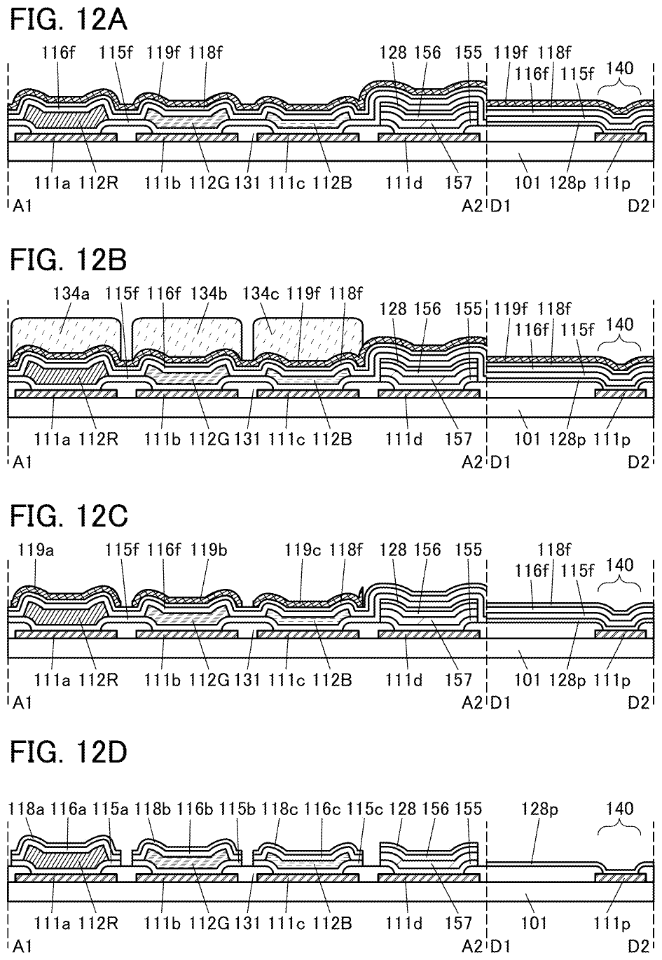

Then, a sacrificial film 118f and a sacrificial film 119f are formed in this order over the functional film 116f (FIG. 12A).

As the sacrificial film 118f, it is possible to favorably use a film highly resistant to etching treatment performed on the functional film 116f and the functional film 115f, i.e., a film having a high etching selectivity. Furthermore, as the sacrificial film 118f, it is possible to favorably use a film having high etching selectivity with respect to the sacrificial film 119f described later. Furthermore, as the sacrificial film 118f, it is particularly preferable to use a film that can be removed by a wet etching method that causes less damage to the functional film 156f and the functional film 155f.

For the sacrificial film 118f, it is possible to use a material usable for the sacrificial film 128f. In addition, for the formation of the sacrificial film 118f, it is possible to use a method usable for the formation of the sacrificial film 128f. Without limitation to this, the above-described deposition method can be used as appropriate.

For the sacrificial film 118f, the same material as the sacrificial film 128f is preferably used. Furthermore, it is preferable that the thickness of the sacrificial film 118f be approximately the same as the thickness of the sacrificial film 128f.

The sacrificial film 119f is used as a hard mask when the sacrificial film 118f is etched later. In a later process of processing the sacrificial film 119f, the sacrificial film 118f is exposed. Thus, the combination of films having high etching selectivity therebetween is selected for the sacrificial film 118f and the sacrificial film 119f. It is thus possible to select a film that can be used for the sacrificial film 119f depending on an etching condition of the sacrificial film 118f and an etching condition of the sacrificial film 119f.

For the sacrificial film 119f, it is possible to use a material usable for the sacrificial film 129f. In addition, for the formation of the sacrificial film 118f, it is possible to use a method usable for the formation of the sacrificial film 128f. Without limitation to this, the above-described deposition method can be used as appropriate. For the sacrificial film 119f, either the same material as the sacrificial film 129f or a different material may be used. The thickness of the sacrificial film 118f may be approximately the same as or different from the thickness of the sacrificial film 128f

For the etching of the sacrificial film 119f, the description of etching of the sacrificial film 129f can be referred to, and thus detailed description is omitted.

[Formation of Sacrificial Layers 119a to 119c and Sacrificial Layers 118a to 118c]

Next, a resist mask 134a, a resist mask 134b, and a resist mask 134c are formed over the sacrificial film 119f in a region overlapping with the electrode 111a, over the sacrificial film 119f in a region overlapping with the electrode 111b, and over the sacrificial film 119f in a region overlapping with the electrode 111d (FIG. 12B).

The resist mask 134a is made larger than the light-emitting layer 112R. That is, the end portion of the resist mask 134a is positioned outward from the end portion of the light-emitting layer 112R. Similarly, the resist mask 134b is made larger than the light-emitting layer 112G. That is, the end portion of the resist mask 134b is positioned outward from the end portion of the light-emitting layer 112G. The resist mask 134c is made larger than the light-emitting layer 112B. That is, the end portion of the resist mask 134c is positioned outward from the end portion of the light-emitting layer 112B.

For the resist mask 134a, the resist mask 134b, and the resist mask 134c, the description of the resist mask 133 can be referred to, and thus detailed description thereof is omitted.

Here, in the case where the sacrificial film 119f is not formed and the resist mask 134a, the resist mask 134b, and the resist mask 134c are formed over the sacrificial film 118f, when a defect such as a pinhole exists in the sacrificial film 118f, there is a risk of dissolving the functional film 116f and the like due to a solvent of the resist material. Such a defect can be prevented by using the sacrificial film 119f.

Note that in the case where a film that is unlikely to cause a defect such as a pinhole is used as the sacrificial film 118f, the resist mask 134a, the resist mask 134b, and the resist mask 134c may be formed directly on the sacrificial film 118f without using the sacrificial film 119f.

Next, the sacrificial film 119f in a region covered with none of the resist mask 134a, the resist mask 134b, and the resist mask 134c is removed by etching to form a sacrificial layer 119a, a sacrificial layer 119b, and a sacrificial layer 119c.

In the etching of the sacrificial film 119f, an etching condition with high selectivity is preferably employed so that the sacrificial film 118f is not removed by the etching. Either wet etching or dry etching can be performed for the etching of the sacrificial film 119f; with use of dry etching, a reduction in areas of the sacrificial layer 119a, the sacrificial layer 119b, and the sacrificial layer 119c can be inhibited.

Subsequently, the resist mask 134a, the resist mask 134b, and the resist mask 134c are removed (see FIG. 12C).

The same method as that for the removal of the resist mask 133 can be used for the removal of the resist mask 134a, the resist mask 134b, and the resist mask 134c.

At this time, since the removal of the resist mask 134a, the resist mask 134b, and the resist mask 134c is performed in the state where the sacrificial film 118f is provided over the functional film 116f; thus, damage to the functional film 156f, the light-emitting layer 112R, the light-emitting layer 112G, the light-emitting layer 112B, and the functional film 155f can be reduced. This is particularly preferable in the case where etching using an oxygen gas such as plasma ashing is performed because electrical characteristics of the light-emitting devices might be adversely affected when the light-emitting layer 112R, the light-emitting layer 112G, and the light-emitting layer 112B are exposed to oxygen.

Then, the sacrificial film 118f in a region covered with none of the sacrificial layer 119a, the sacrificial layer 119b, and the sacrificial layer 119c is removed by etching using the sacrificial layer 119a, the sacrificial layer 119b, and the sacrificial layer 119c as masks, whereby a sacrificial layer 118a, a sacrificial layer 118b, and a sacrificial layer 118c are formed.

For the etching of the sacrificial film 118f, the description of etching of the sacrificial film 128f can be referred to, and thus detailed description is omitted.

[Formation of First Layers 115a to 115c and Second Layers 116a to 116c]

Next, the sacrificial layer 119a, the sacrificial layer 119b, and the sacrificial layer 119c are removed by etching, and the functional film 116f and the functional film 115f in a region covered with none of the sacrificial layer 118a, the sacrificial layer 118b, and the sacrificial layer 118c are removed by etching, whereby the second layer 116a, the second layer 116b, the second layer 116c, the first layer 115a, the first layer 115b, and the first layer 115c are formed (FIG. 12D).

When the functional film 116f and the functional film 115f are etched through the same process as that for the sacrificial layer 119a, the sacrificial layer 119b, and the sacrificial layer 119c, the processes can be simplified, the productivity can be increased, and the manufacturing cost can be reduced.

In particular, for etching of the functional film 116f and the functional film 115f, it is preferable to use dry etching using an etching gas that does not contain oxygen as its main component. In this case, a change in qualities of the functional film 156f and the functional film 155f can be inhibited, whereby a highly reliable display apparatus can be achieved.

Note that etching of the functional film 116f and the functional film 115f may be separately performed from etching of the sacrificial layer 119a, the sacrificial layer 119b, and the sacrificial layer 119c. For example, the functional film 116f and the functional film 115f may be etched, and then the sacrificial layer 119a, the sacrificial layer 119b, and the sacrificial layer 119c may be etched

[Removal of Sacrificial Layers 118a to 118c, Sacrificial Layer 128, and Sacrificial Layer 128p]

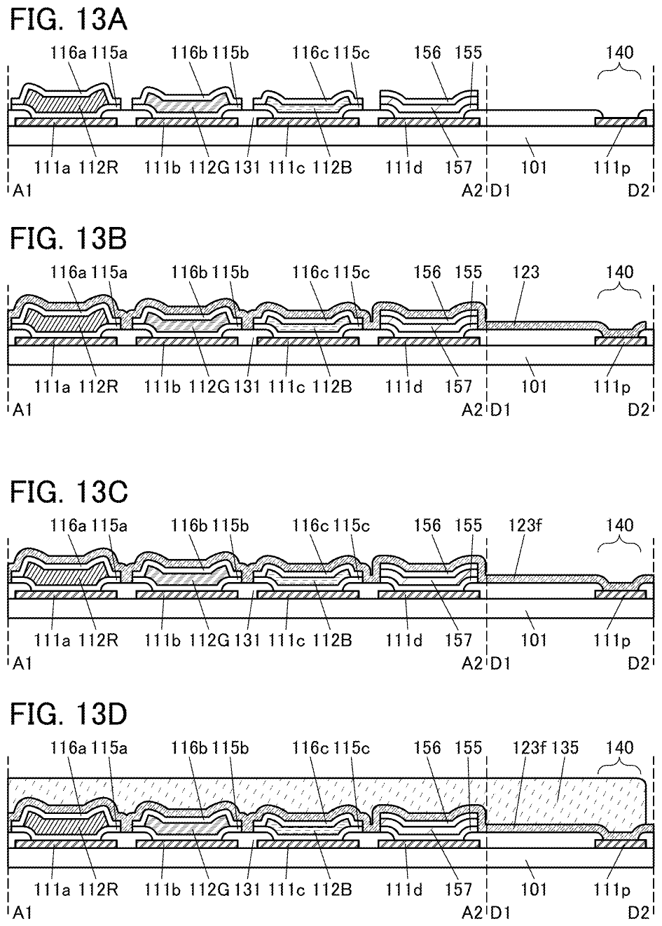

Next, the sacrificial layer 118a, the sacrificial layer 118b, the sacrificial layer 118c, the sacrificial layer 128, and the sacrificial layer 128p are removed to expose the top surface of the second layer 116a, the top surface of the second layer 116b, the top surface of the second layer 116c, the top surface of the fourth layer 156, and the top surface of the connection electrode 111p (FIG. 13A).

The sacrificial layer 118a, the sacrificial layer 118b, the sacrificial layer 118c, the sacrificial layer 128, and the sacrificial layer 128p can be removed by wet etching or dry etching. At this time, it is preferable to use a method that causes as less damage to the light-emitting layer 112, the active layer 157, the first layer 115, the second layer 116, the third layer 155, the fourth layer 156, and the connection electrode 111p as possible. In particular, a wet etching method is preferably used. For example, wet etching using a tetramethyl ammonium hydroxide (TMAH) aqueous solution, diluted hydrofluoric acid, oxalic acid, phosphoric acid, acetic acid, nitric acid, or a mixed solution thereof is preferably used.

Alternatively, the sacrificial layer 118a, the sacrificial layer 118b, the sacrificial layer 118c, the sacrificial layer 128, and the sacrificial layer 128p are preferably removed by being dissolved in a solvent such as water or alcohol. Here, as alcohol in which the sacrificial layer 118a, the sacrificial layer 118b, the sacrificial layer 118c, the sacrificial layer 128, and the sacrificial layer 128p can be dissolved, a variety of alcohols such as ethyl alcohol, methyl alcohol, isopropyl alcohol (IPA), and glycerin can be used.

In order that the sacrificial layers 118a to 118c be removed at the same time as the sacrificial layer 128 and the sacrificial layer 128p, it is preferable that etching times required for removing them be substantially the same as one another. For example, the same material is preferably used for the sacrificial layers 118a to 118c, the sacrificial layer 128, and the sacrificial layer 128p. Furthermore, the sacrificial layers 118a to 118c preferably have substantially the same thicknesses as the sacrificial layer 128 and the sacrificial layer 128p.

After the sacrificial layer 118a, the sacrificial layer 118b, the sacrificial layer 118c, the sacrificial layer 128, and the sacrificial layer 128p are removed, drying treatment is preferably performed in order to remove water contained in the light-emitting layer 112, the active layer 157, the first layer 115, the second layer 116, the third layer 155, the fourth layer 156, and the connection electrode 111p and water adsorbed on their surfaces. For example, heat treatment is preferably performed in an inert gas atmosphere or a reduced-pressure atmosphere. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

### [Formation of Common Electrode 123]

Next, the common electrode 123 is formed to cover the second layer 116a, the second layer 116b, the second layer 116c, the fourth layer 156, and the connection electrode 111p (FIG. 13B). The common electrode 123 is electrically connected to the connection electrode 111p in the connection portion 140.

The common electrode 123 can be formed by an evaporation method or a sputtering method. Alternatively, the common electrode 123 may be formed by stacking a film formed by an evaporation method and a film formed by a sputtering method. The common electrode 123 is preferably formed using a shielding mask. It is preferable that the shielding mask be provided such that the common electrode 123 is not exposed at the end portion of the display apparatus 100, that is, the end portion of the common electrode 123 is located inward from the end portion of the display apparatus 100.

Note that the shielding mask is not necessarily used at the time of deposition of the common electrode 123. As illustrated in FIG. 13C, a conductive layer 123f to be the common electrode 123 is formed. Then, as illustrated in FIG. 13D, a resist mask 135 is formed over the conductive layer 123f, and the conductive layer 123f is processed, whereby the common electrode 123 can be formed. In this case, it is preferable that the processing be performed such that the common electrode 123 is not exposed at the end portion of the display apparatus, that is, the end portion of the common electrode 123 is located inward from the end portion of the display apparatus.

### [Formation of Protective Layer 125]

Next, the protective layer 125 is formed over the common electrode 123. An inorganic insulating film used for the protective layer 125 is preferably deposited by a sputtering method, a PECVD method, or an ALD method. In particular, an ALD method is preferable because it provides excellent step coverage and is less likely to cause a defect such as a pinhole. In addition, an organic insulating film is preferably deposited by an inkjet method because a uniform film can be formed in a desired region.

Through the above-described processes, the display apparatus illustrated in FIG. 4B can be manufactured.

In the display apparatus of one embodiment of the present invention, the light-emitting layer of the light-emitting device can be used using an FMM and the active layer of the light-receiving device can be formed without using an FMM. With such a structure, a display apparatus having a light detection function with high accuracy can be provided.

### Manufacturing Method Example 2

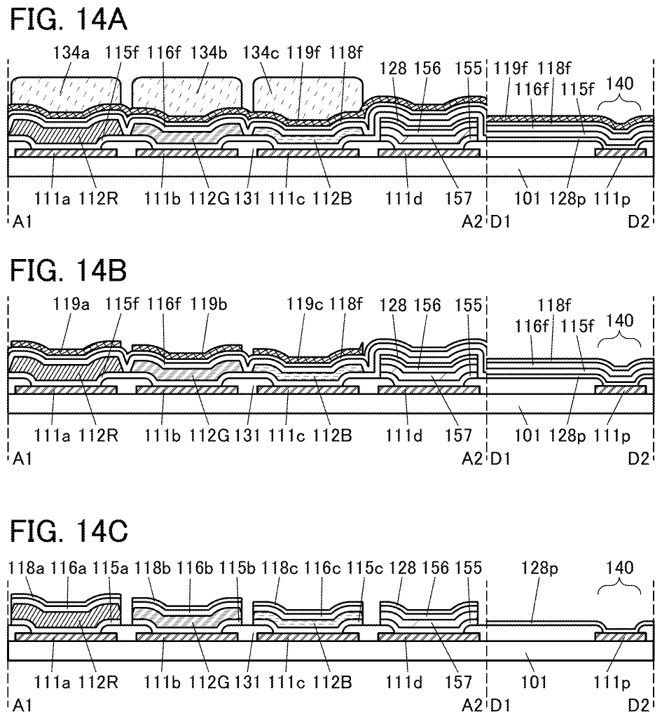

A method for manufacturing a display apparatus illustrated in FIG. 6A is described. FIG. 14A to FIG. 14C are schematic cross-sectional views in processes of the method for manufacturing the display apparatus. Note that description of the same portions as the manufacturing method example 1 described above is omitted and different portions are described.

First, as in the manufacturing method example 1, the processes up to the formation of the sacrificial film 119f are performed (FIG. 12A).

[Formation of Sacrificial Layers 119a to 119c and Sacrificial Layers 118a to 118c]

Next, the resist mask 134a, the resist mask 134b, and the resist mask 134c are formed over the sacrificial film 119f in a region overlapping with the electrode 111a, over the sacrificial film 119f in a region overlapping with the electrode 111b, and over the sacrificial film 119f in a region overlapping with the electrode 111d (FIG. 14A).

The resist mask 134a is made smaller than the light-emitting layer 112R. That is, the end portion of the resist mask 134a is positioned inward from the end portion of the light-emitting layer 112R. Similarly, the resist mask 134b is made smaller than the light-emitting layer 112G. That is, the end portion of the resist mask 134b is positioned inward from the end portion of the light-emitting layer 112G. The resist mask 134c is made smaller than the light-emitting layer 112B. That is, the end portion of the resist mask 134c is positioned inward from the end portion of the light-emitting layer 112B.

Next, the sacrificial film 119f in a region covered with none of the resist mask 134a, the resist mask 134b, and the resist mask 134c is removed by etching to form the sacrificial layer 119a, the sacrificial layer 119b, and the sacrificial layer 119c.

Subsequently, the resist mask 134a, the resist mask 134b, and the resist mask 134c are removed (see FIG. 14B).

Then, the sacrificial film 118f in a region covered with none of the sacrificial layer 119a, the sacrificial layer 119b, and the sacrificial layer 119c is removed by etching using the sacrificial layer 119a, the sacrificial layer 119b, and the sacrificial layer 119c as masks, whereby the sacrificial layer 118a, the sacrificial layer 118b, and the sacrificial layer 118c are formed.

[Formation of First Layers 115a to 115c and Second Layers 116a to 116c]

Next, the sacrificial layer 119a, the sacrificial layer 119b, and the sacrificial layer 119c are removed by etching, and the functional film 116f and the functional film 115f in a region covered with none of the sacrificial layer 118a, the sacrificial layer 118b, and the sacrificial layer 118c are removed by etching, whereby the second layer 116a, the second layer 116b, the second layer 116c, the first layer 115a, the first layer 115b, and the first layer 115c are formed (FIG. 14C). At this time, the light-emitting layer 112R, the light-emitting layer 112G, and the light-emitting layer 112B in a region not covered with the sacrificial layer 118a, the sacrificial layer 118b, or the sacrificial layer 118c are also etched, whereby the light-emitting layer 112R, the light-emitting layer 112G, and the light-emitting layer 112B are partly exposed.

In particular, for etching of the light-emitting layer 112R, the light-emitting layer 112G, the light-emitting layer 112B, the functional film 116f, and the functional film 115f, it is preferable to use dry etching using an etching gas that does not contain oxygen as its main component. In this case, a change in qualities of the light-emitting layer 112R, the light-emitting layer 112G, the light-emitting layer 112B, the functional film 156f, and the functional film 155f can be inhibited, whereby a highly reliable display apparatus can be achieved.

For the processes after the removal of the sacrificial layer 118a, the sacrificial layer 118b, the sacrificial layer 118c, the sacrificial layer 128, and the sacrificial layer 128p, the above-described manufacturing method example 1 can be referred to, and thus detailed description is omitted.

Through the above-described processes, the display apparatus illustrated in FIG. 6A can be manufactured.

### Manufacturing Method Example 3

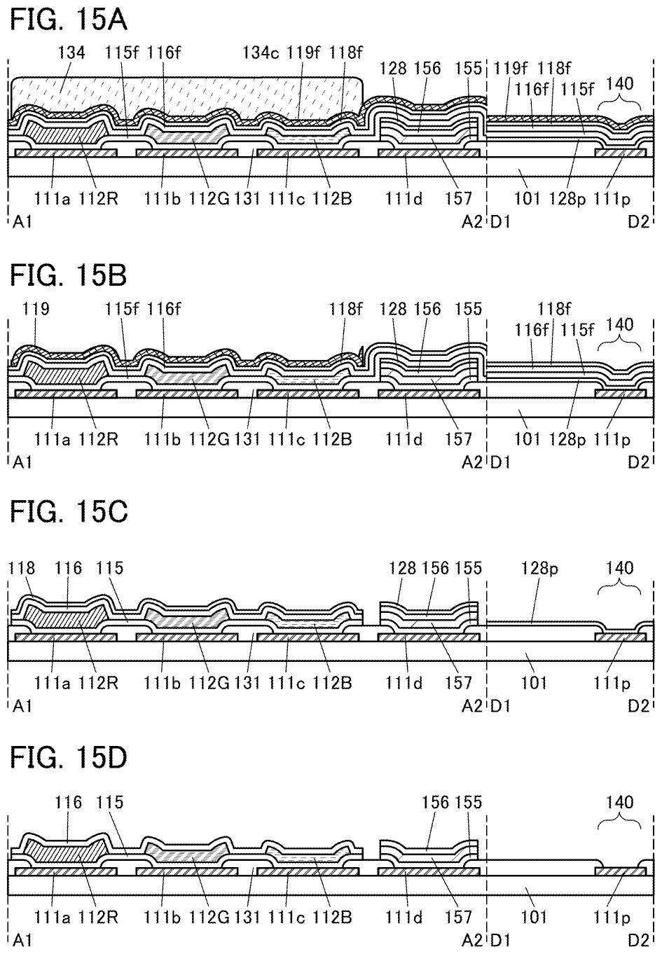

A method for manufacturing a display apparatus illustrated in FIG. 7A is described. FIG. 15A to FIG. 15D are schematic cross-sectional views in processes of the method for manufacturing the display apparatus. Note that description of the same portions as the manufacturing method example 1 described above is omitted and different portions will be described.

First, as in the manufacturing method example 1, the processes up to the formation of the sacrificial film 119f are performed (FIG. 12A).

### [Formation of Sacrificial Layer 119 and Sacrificial Layer 118]

Next, a resist mask 134 is formed over the sacrificial film 119f in a region overlapping with the electrode 111a, the electrode 111b, and the electrode 111c (FIG. 15A).

Then, the sacrificial film 119f in a region not covered with the resist mask 134 is removed by etching to form a sacrificial layer 119.

After that, the resist mask 134 is removed (FIG. 15B).

Subsequently, the sacrificial film 118f in a region not covered with the sacrificial layer 119 is removed by etching using the sacrificial layer 119 as a mask, whereby a sacrificial layer 118 is formed.

### [Formation of First Layer 115 and Second Layer 116]

Next, the sacrificial layer 119 is removed by etching, and the functional film 116f and the functional film 115f in a region not covered with the sacrificial layer 118 are removed by etching, whereby the second layer 116 and the first layer 115 are formed (FIG. 15C).

[Removal of Sacrificial Layer 118, Sacrificial Layer 128, and Sacrificial Layer 128p]

Next, the sacrificial layer 118, the sacrificial layer 128, and the sacrificial layer 128p are removed (FIG. 15D). For the removal of the sacrificial layer 118, the sacrificial layer 128, and the sacrificial layer 128p, the above description can be referred to, and thus detailed description is omitted.

For the processes after the formation of the common electrode 123, the above-described manufacturing method example 1 can be referred to, and thus detailed description is omitted.

Through the above-described processes, the display apparatus illustrated in FIG. 7A can be manufactured.

### <Manufacturing Method Example 4>

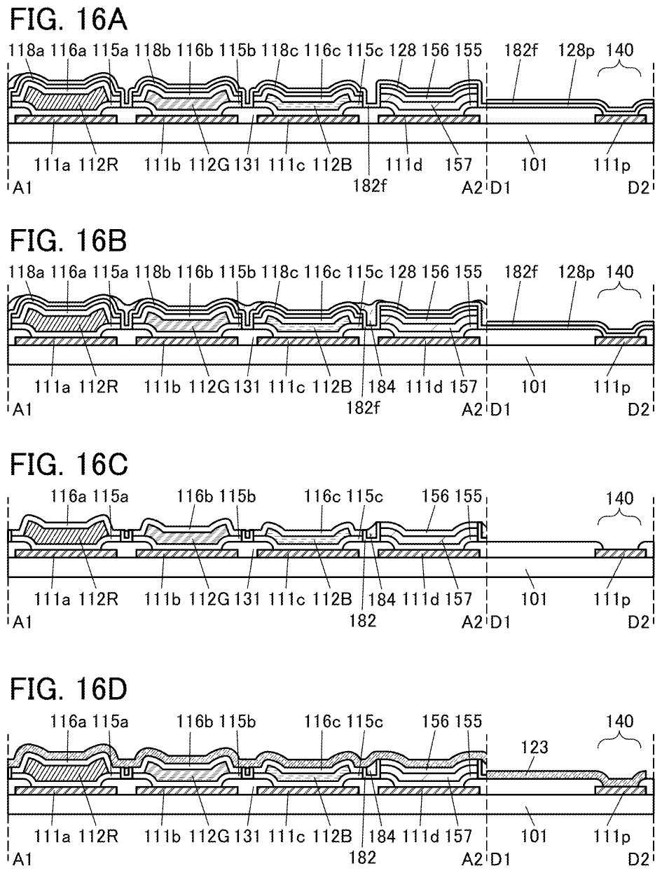

A method for manufacturing a display apparatus illustrated in FIG. 8B is described. FIG. 16A to FIG. 16D are schematic cross-sectional views in processes of the method for manufacturing the display apparatus. Note that description of the same portions as the manufacturing method example 1 described above is omitted and different portions will be described.

First, as in the manufacturing method example 1, the processes up to the formation of the second layer 116a, the second layer 116b, the second layer 116c, the first layer 115a, the first layer 115b, and the first layer 115c are performed (FIG. 12D).

[Formation of Insulating Film 182f]

Next, an insulating film 182f is deposited to cover the sacrificial layer 118a, the sacrificial layer 118b, the sacrificial layer 118c, the sacrificial layer 128, the sacrificial layer 128p, and the insulating layer 131 (FIG. 16A).

The insulating film 182f functions as a barrier layer that prevents diffusion of impurities into the EL layers and the light-receiving layer. Examples of the impurities include water. The insulating film 182f is preferably formed by an ALD method providing excellent step coverage because the insulating film 182f can favorably cover the side surfaces of the EL layers and the side surface of the light-receiving layer.

The same film as the sacrificial layer 118 is preferably used for the insulating film 182f because they can be etched at the same time in a later process. For example, an inorganic insulating material such as aluminum oxide, hafnium oxide, or silicon oxide formed by an ALD method is preferably used for the insulating film 182f and the sacrificial layer 118.

The material that can be used for the insulating film 182f is not limited to the above, and a material usable for the sacrificial layer 119 can be used as appropriate.

### [Formation of Resin Layer 184]

Next, the resin layer 184 is formed between two adjacent light-emitting devices and between a light-emitting device and a light-receiving device that are adjacent to each other (FIG. 16B). FIG. 16B illustrates an example in which the resin layer 184 is formed to have a width larger than the width of the space between the devices.

A photosensitive resin is preferably used for the resin layer 184. In this case, after a resin film is first deposited, the resin film is exposed to light through a photomask and then subjected to development treatment, whereby the resin layer 184 can be formed. After that, an upper portion of the resin layer 184 may be removed by ashing or the like in order that the top surface level of the resin layer 184 be adjusted.

In the case where a nonphotosensitive resin is used for the resin layer 184, after a resin film is deposited, an upper portion of the resin film is removed by ashing until the film has an optimal thickness and the surfaces of the sacrificial layer 118 and the sacrificial layer 128 are exposed, whereby the resin layer 184 can be formed.

### [Etching of Insulating Film 182f and Sacrificial Layers]

Next, the insulating film 182f, the sacrificial layer 118a, the sacrificial layer 118b, the sacrificial layer 118c, the sacrificial layer 128, and the sacrificial layer 128p in a region not covered with the resin layer 184 are removed by etching to expose the top surface of the second layer 116, the top surface of the fourth layer 156, and the top surface of the connection electrode 111p. In addition, the insulating layer 182 is formed in a region covered with the resin layer 184 (FIG. 16C).

At this time, an upper portion of the resin layer 184 is removed and the level of the top surface of the resin layer 184 is lowered in some cases.

It is preferable that the insulating film 182f, the sacrificial layer 118a, the sacrificial layer 118b, the sacrificial layer 118c, the sacrificial layer 128, and the sacrificial layer 128p be etched through the same process. In particular, wet etching that causes less etching damage to the second layer 116a, the second layer 116b, the second layer 116c, and the fourth layer 156 can be preferably used for the etching of the sacrificial layer 118a, the sacrificial layer 118b, the sacrificial layer 118c, the sacrificial layer 128, and the sacrificial layer 128p. For example, wet etching using a tetramethyl ammonium hydroxide (TMAH) aqueous solution, diluted hydrofluoric acid, oxalic acid, phosphoric acid, acetic acid, nitric acid, or a mixed solution thereof is preferably performed.

Alternatively, one or both of the insulating film 182f and the sacrificial layer 118 are preferably removed by being dissolved in a solvent such as water or alcohol. For the alcohol in which the insulating film 182f and the sacrificial layer 118 can be dissolved, any of various alcohols such as ethyl alcohol, methyl alcohol, isopropyl alcohol (IPA), and glycerin can be used.

After the sacrificial layer 118a, the sacrificial layer 118b, the sacrificial layer 118c, the sacrificial layer 128, and the sacrificial layer 128p are removed, drying treatment is preferably performed in order to remove water contained in the light-emitting layer 112, the active layer 157, the first layer 115, the second layer 116, the third layer 155, the fourth layer 156, and the connection electrode 111p and water adsorbed on their surfaces.

### [Formation of Common Electrode 123]

Next, the common electrode 123 is formed to cover the insulating layer 182, the resin layer 184, the second layer 116, the fourth layer 156, and the connection electrode 111p (FIG. 16D).

### [Formation of Protective Layer 125]

Next, the protective layer 125 is formed over the common electrode 123.

Through the above-described processes, the display apparatus illustrated in FIG. 8B can be manufactured.

### Manufacturing Method Example 5

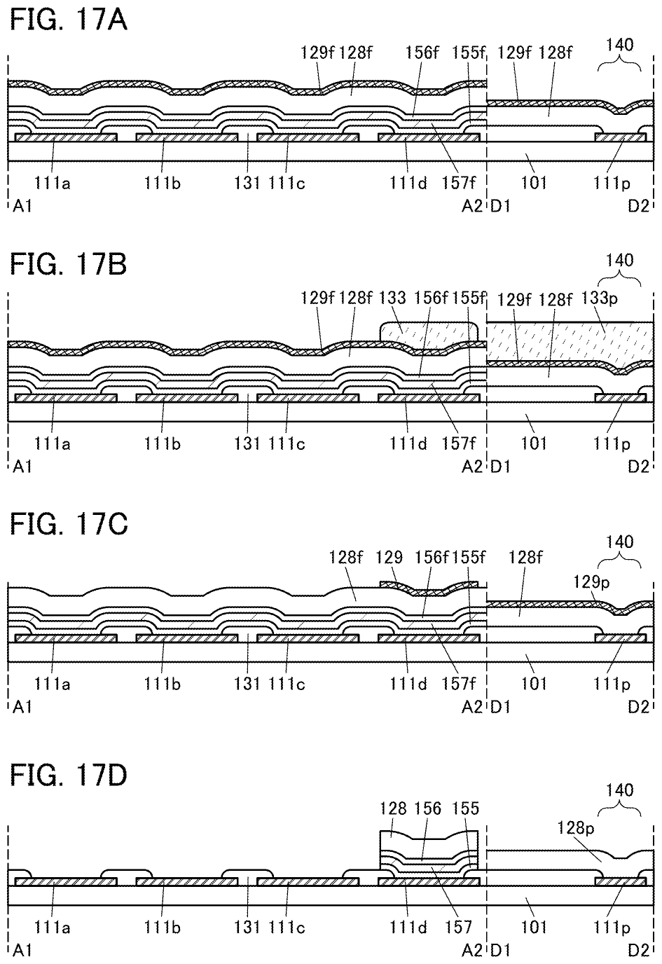

A method for manufacturing a display apparatus illustrated in FIG. 9A is described. FIG. 17A to FIG. 19B are schematic cross-sectional views in processes of the method for manufacturing the display apparatus. Note that description of the same portions as the manufacturing method example 1 described above is omitted and different portions will be described.

First, as in the manufacturing method example 1, the processes up to the formation of the insulating layer 131 are performed (FIG. 10A).

[Formation of Functional Film 155f, Active Film 157f, and Functional Film 156f]

Next, the functional film 155f to be the third layer 155 later, the active film 157f to be the active layer 157, and the functional film 156f to be the fourth layer 156 are deposited in this order over the electrode 111a, the electrode 111b, the electrode 111c, the electrode 111d, and the insulating layer 131. For the formation of the functional film 155f, the active film 157f, and the functional film 156f, the above description can be referred to, and thus detailed description is omitted.

[Formation of Sacrificial Film 128f and Sacrificial Film 129f]

Next, the sacrificial film 128f and the sacrificial film 129f are formed in this order over the functional film 156f (FIG. 17A).

The thickness of the sacrificial film 128f is preferably greater than or equal to 10 nm and less than or equal to 3 μm, further preferably greater than or equal to 10 nm and less than or equal to 2 μm, still further preferably greater than or equal to 10 nm and less than or equal to 1 μm, yet still further preferably greater than or equal to 20 nm and less than or equal to 1 μm, yet still further preferably greater than or equal to 20 nm and less than or equal to 500 nm, yet still further preferably greater than or equal to 30 nm and less than or equal to 500 nm, yet still further preferably greater than or equal to 30 nm and less than or equal to 400 nm, yet still further preferably greater than or equal to 40 nm and less than or equal to 400 nm, yet still further preferably greater than or equal to 40 nm and less than or equal to 300 nm, yet still further preferably greater than or equal to 50 nm and less than or equal to 300 nm, yet still further preferably greater than or equal to 50 nm and less than or equal to 200 nm, and yet still further preferably greater than or equal to 50 nm and less than or equal to 100 nm. Furthermore, the thickness of the sacrificial film 128f is preferably larger than the thickness of the first layer 115.

For the sacrificial film 129f, the above description can be referred to, and thus the detailed description thereof is omitted.

### [Formation of Sacrificial Layer 129 and Sacrificial Layer 128]

Next, the resist mask 133 and a resist mask 133p are formed over the sacrificial film 129f in a region overlapping with the electrode 111d and over the sacrificial film 129f in a region overlapping with the connection portion 140 (FIG. 17B).

Next, the sacrificial film 129f in a region covered with neither the resist mask 133 nor the resist mask 133p is removed by etching to form the sacrificial layer 129 and a sacrificial layer 129p.

Then, the resist mask 133 is removed (FIG. 17C).

Subsequently, the sacrificial film 128f in a region covered with neither the sacrificial layer 129 nor the sacrificial layer 129p is removed by etching using the sacrificial layer 129 and the sacrificial layer 129p as masks, whereby the sacrificial layer 128 is formed in a region overlapping with the electrode 111d, and the sacrificial layer 128p in contact with the top surface of the connection electrode 111p is formed.

### [Formation of Third Layer 155, Active Layer 157, and Fourth Layer 156]

Next, the sacrificial layer 129 and the sacrificial layer 129p are removed by etching, and the functional film 156f, the active film 157f, and the functional film 155f in a region covered with neither the sacrificial layer 128 nor the sacrificial layer 128p are removed by etching, whereby the fourth layer 156, the active layer 157, and the third layer 155 are formed (FIG. 17D).

When the functional film 156f, the active film 157f, and the functional film 155f are etched through the same process as that for the sacrificial layer 129 and the sacrificial layer 129p, the processes can be simplified, the productivity can be increased, and the manufacturing cost can be reduced.

In particular, for the etching of the functional film 156f, the active film 157f, and the functional film 155f, the above description can be referred to, and thus detailed description is omitted.

### [Formation of First Layer 115]

Next, a functional film to be the first layer 115 is deposited to cover the insulating layer 131, the electrode 111a, the electrode 111b, the electrode 111c, the connection electrode 111p, the third layer 155, the active layer 157, the fourth layer 156, the sacrificial layer 128, and the sacrificial layer 128p.

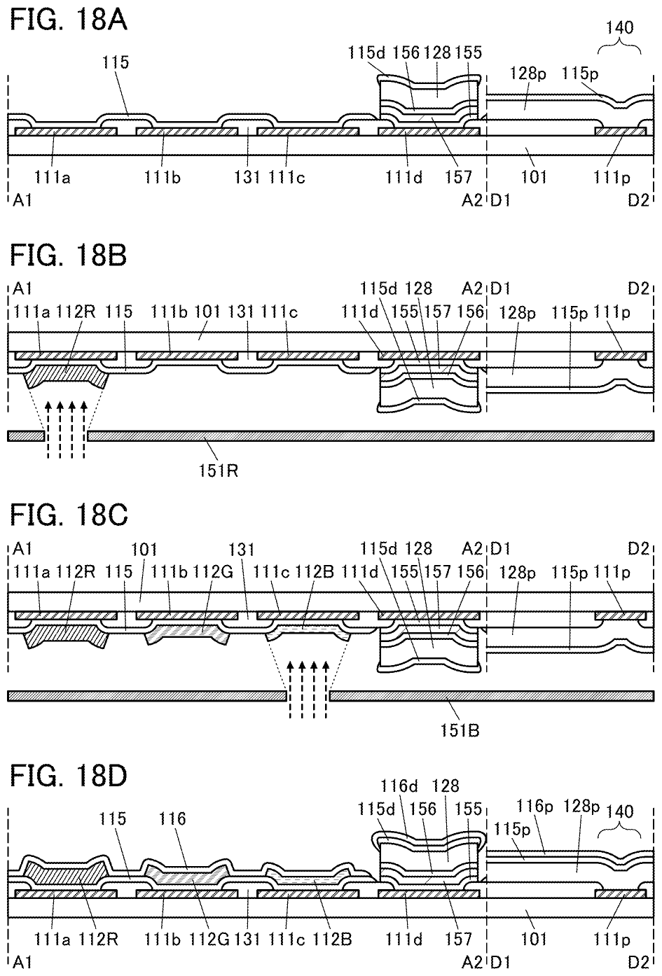

Here, a region where the functional film is not deposited is formed between a region where the sacrificial layer 128 or the sacrificial layer 128p is provided and a region where neither the sacrificial layer 128 nor the sacrificial layer 128p is provided. In other words, the functional film is divided between the region where the sacrificial layer 128 or the sacrificial layer 128p is provided and the region where the sacrificial layer 128 or the sacrificial layer 128p is not provided. FIG. 18A illustrates, as the divided functional films, a first layer 115d deposited over the sacrificial layer 128, a first layer 115p deposited over the sacrificial layer 128p, and the first layer 115p deposited in the region where neither the sacrificial layer 128 nor the sacrificial layer 128p is provided. Note that the first layer 115 is provided in contact with the top surfaces of the electrode 111a, the electrode 111b, and the electrode 111c.

The thickness of the sacrificial film 128f to be the sacrificial layer 128 or the sacrificial layer 128p is preferably within the above range. When the thickness of the sacrificial film 128f is small, the functional film to be the first layer 115 cannot be divided in some cases. When the thickness of the sacrificial film 128f is large, the sacrificial film 128f is difficult to process in some cases. The thickness of the sacrificial film 128f falls within the above range, whereby the functional film to be the first layer 115 can be divided and processing of the sacrificial film 128f can be facilitated.

### [Formation of Light-Emitting Layer 112R, Light-Emitting Layer 112G, and Light-Emitting Layer 112B]

Next, the light-emitting layer 112R having an island shape is formed over the first layer 115 in a region overlapping with the electrode 111a with the use of the FMM 151R (FIG. 18B)

Then, the light-emitting layer 112G is formed over the first layer 115 in a region overlapping with the electrode 111b with the use of the FMM 151G.

Subsequently, the light-emitting layer 112B is formed over the first layer 115 in a region overlapping with the electrode 111c with the use of the FMM 151B (FIG. 18C).

For the formation of the light-emitting layer 112R, the light-emitting layer 112G, and the light-emitting layer 112B, the above description can be referred to, and thus detailed description is omitted.

Note that the formation order of the light-emitting layer 112R, the light-emitting layer 112G, and the light-emitting layer 112B is not particularly limited.

### [Formation of Second Layer 116]

Next, a functional film to be the second layer 116 is formed to cover the light-emitting layer 112R, the light-emitting layer 112G, the light-emitting layer 112B, the first layer 115, the first layer 115d, and the first layer 115p.

Here, a region where the functional film is not deposited is formed between a region where the sacrificial layer 128 or the sacrificial layer 128p is provided and a region where neither the sacrificial layer 128 nor sacrificial layer 128p is provided. In other words, the functional film is divided (also referred to as disconnected) between the region where the sacrificial layer 128 or the sacrificial layer 128p is provided and the region where the sacrificial layer 128 or the sacrificial layer 128p is not provided. FIG. 18D illustrates, as the divided functional films, a second layer 116d deposited over the sacrificial layer 128, a second layer 116p deposited over the sacrificial layer 128p, and the second layer 116 deposited in the region where neither the sacrificial layer 128 nor the sacrificial layer 128p is provided. Note that the second layer 116d is provided in contact with the first layer 115d. The second layer 116p is provided in contact with the first layer 115p. The second layer 116 is provided in contact with the first layer 115. At this time, the end portion of the second layer 116 may be positioned inward from the end portion of the first layer 115.

The thickness of the sacrificial film 128f to be the sacrificial layer 128 or the sacrificial layer 128p is preferably within the above range. When the thickness of the sacrificial film 128f is small, the functional film to be the second layer 116 cannot be divided in some cases. The thickness of the sacrificial film 128f falls within the above range, whereby the functional film to be the second layer 116 can be divided.

[Removal of Sacrificial Layer 128 and Sacrificial Layer 128p]

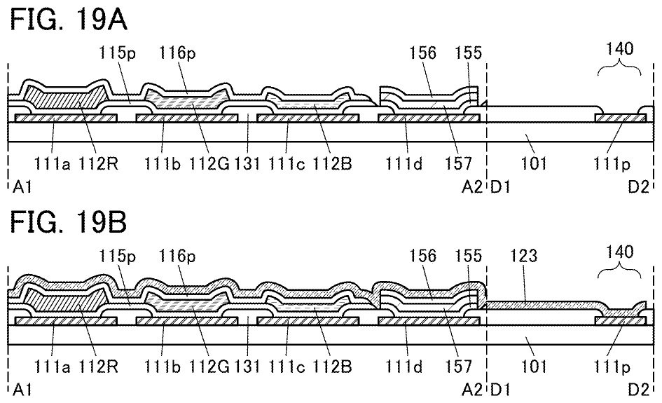

Next, the sacrificial layer 128 and the sacrificial layer 128p are removed. At this time, the first layer 115d and the second layer 116d which are over the sacrificial layer 128, and the first layer 115p and the second layer 116p which are over the sacrificial layer 128p are also removed, whereby the top surface of the second layer 116a, the top surface of the second layer 116b, the top surface of the second layer 116c, the top surface of the fourth layer 156, and the top surface of the connection electrode 111p are exposed (FIG. 19A).

It is preferable that a method that causes as less damage to the first layer 115, the second layer 116, the third layer 155, the active layer 157, the fourth layer 156, and the connection electrode 111p as possible be used for the removal of the sacrificial layer 128 and the sacrificial layer 128p. Wet etching can be preferably used for the removal of the sacrificial layer 128 and the sacrificial layer 128p. When the sacrificial layer 128 is dissolved, both the first layer 115d and the second layer 116d over the sacrificial layer 128 are removed (also referred to as lifted off). Similarly, when the sacrificial layer 128p is dissolved, both the first layer 115p and the second layer 116p over the sacrificial layer 128p are removed (lifted off). The use of the lifting off makes it possible to remove the first layer 115d, the second layer 116d, the first layer 115p, and the second layer 116p without causing damage to the first layer 115 and the second layer 116.

After the sacrificial layer 128 and the sacrificial layer 128p are removed, drying treatment is preferably performed in order to remove water contained in the light-emitting layer 112, the active layer 157, the first layer 115, the second layer 116, the third layer 155, the fourth layer 156, and the connection electrode 111p and water adsorbed on their surfaces.

### [Formation of Common Electrode 123]

Next, the common electrode 123 is formed to cover the second layer 116, the fourth layer 156, and the connection electrode 111p (FIG. 19B). The common electrode 123 is electrically connected to the connection electrode 111p in the connection portion 140.

### [Formation of Protective Layer 125]

Next, the protective layer 125 is formed over the common electrode 123.

Through the above-described processes, the display apparatus illustrated in FIG. 9A can be manufactured.

The above is the description of the examples of the method for manufacturing a display apparatus.

As described above, it is possible to separately form the light-emitting devices and the light-receiving device over the same substrate by the method for manufacturing a display apparatus of one embodiment of the present invention. Furthermore, it is possible to obtain the structure in which the light-emitting devices and the light-receiving layer have no common component other than a common electrode. This can increase the SN ratio of the light-receiving device, whereby the display apparatus can have the light-receiving device with high accuracy. Furthermore, the display apparatus can have low power consumption.

### <Pixel Layouts>

Pixel layouts will be described below. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

Examples of a top surface shape of the subpixel include polygons such as a triangle, a quadrangle (including a rectangle and a square), and a pentagon; polygons with rounded corners; an ellipse; and a circle. Here, the top surface shape of the subpixel corresponds to the top surface shape of a light-emitting region of a light-emitting device or a light-receiving region of a light-receiving device.

In the display apparatus 100A illustrated in FIG. 4A, one pixel 103 is composed of two rows and three columns. The pixel 103 includes three subpixels (the subpixels 120R, 120G, and 120B) in the upper row (first row) and one subpixel (the subpixel 130) in the lower row (second row). In other words, the pixel 103 includes the subpixel 120R in the left column (first column), the subpixel 120G in the center column (second column), the subpixel 120B in the right column (third column), and the subpixel 130 across these three columns.

In this embodiment and the like, for clear explanation of the pixel layout, the horizontal direction (X direction) in the drawing is the row direction and the vertical direction (Y direction) is the column direction; however, one embodiment of the present invention is not limited thereto and the row direction and the column direction can be replaced with each other. Thus, in this specification and the like, one of the row direction and the column direction is referred to as a first direction and the other of the row direction and the column direction is referred to as a second direction, in some cases. The second direction is orthogonal to the first direction. Note that in the case where the top surface shape of the display portion is a rectangular shape, each of the first direction and the second direction is not necessarily parallel to a straight line portion of the outline of the display portion. The top surface shape is not limited to a rectangular shape, and may be a polygonal shape or a shape with curve (e.g., circle or ellipse). The first direction and the second direction may be a given direction with respect to the display portion.

In this specification and the like, for clear explanation of pixel layout, the subpixels are illustrated in the order from the left of a diagram; however, without limitation thereto, the order can be changed into the order from the right. Similarly, the subpixels are illustrated in the order from the top of a diagram; however, without limitation thereto, the order can be changed into the order from the bottom.

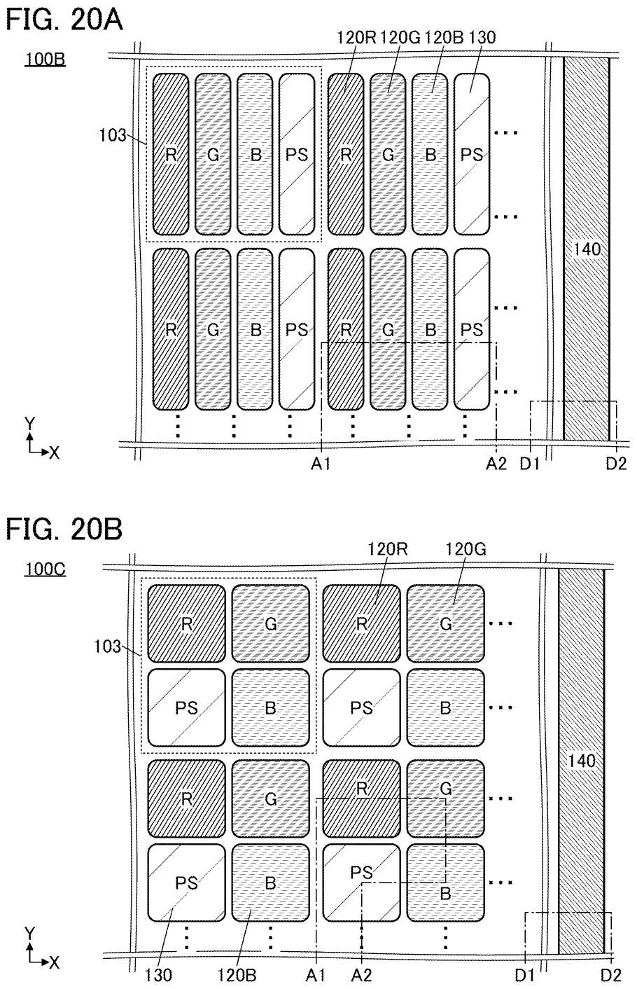

FIG. 20A and FIG. 20B each illustrate pixel arrangement different from FIG. 4A.

In a display apparatus 100B illustrated in FIG. 20A, the pixel 103 employs stripe arrangement. The pixel 103 includes the subpixel 120R, the subpixel 120G, the subpixel 120B, and the subpixel 130 in the row direction.

In a display apparatus 100C illustrated in FIG. 20B, the pixel 103 employs matrix arrangement. The pixel 103 is composed of two rows and two columns and includes two subpixels (the subpixels 120R and 120G) in the upper row (first row) and two subpixels (the subpixels 120B and 130) in the lower row (second row). In other words, the pixel 103 includes two subpixels (the subpixels 120R and 130) in the left column (the first column) and two subpixels (the subpixels 120G and 120B) in the right column (the second column).

Note that there is no particular limitation on the positions of the subpixels. For example, the positions of the subpixel 120R and the subpixel 130 may be interchanged.

The areas of the light-emitting regions of the light-emitting devices included in the subpixels may be the same as or different from one another. For example, the area of the light-emitting region can be determined depending on the lifetime of the light-emitting device. The area of the light-emitting region of the light-emitting device with a short lifetime is preferably made larger than the area of the light-emitting region of the other light-emitting devices. An increase in area of the light-emitting region lowers current density applied to the light-emitting device, whereby the lifetime of the light-emitting device can be longer. That is, the display apparatus can have high reliability.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 2

In this embodiment, structure examples of a display apparatus of one embodiment of the present invention are described.

### Structure Example 1

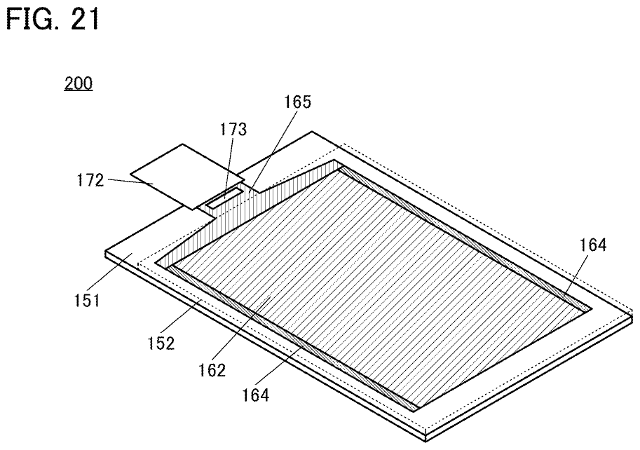

FIG. 21 is a perspective view illustrating a structure example of a display apparatus 200. In the display apparatus 200, a substrate 151 and a substrate 152 are bonded to each other. In FIG. 21, the substrate 152 is denoted by a dashed line.

The display apparatus 200 includes a display portion 162, a circuit 164, a wiring 165, and the like. In the example illustrated in FIG. 21, an IC (integrated circuit) 173 and an FPC 172 are mounted on the display apparatus 200. Therefore, the structure illustrated in FIG. 21 can be regarded as a display module including the display apparatus, the IC, and the FPC.

The circuit 164 can be a gate driver, for example. A signal and power can be supplied to the circuit 164 through the wiring 165, for example. The signal and power can be input to the wiring 165 through the FPC 172 from the outside of the display apparatus 100, for example. Alternatively, the IC 173 can generate the signal and power and can output the signal and power to the wiring 165.

Although the IC 173 is provided on the substrate 151 by a COG (Chip On Glass) method in the example illustrated in FIG. 21, a TCP (Tape Carrier Package) method, a COF (Chip On Film) method, or the like may be used.

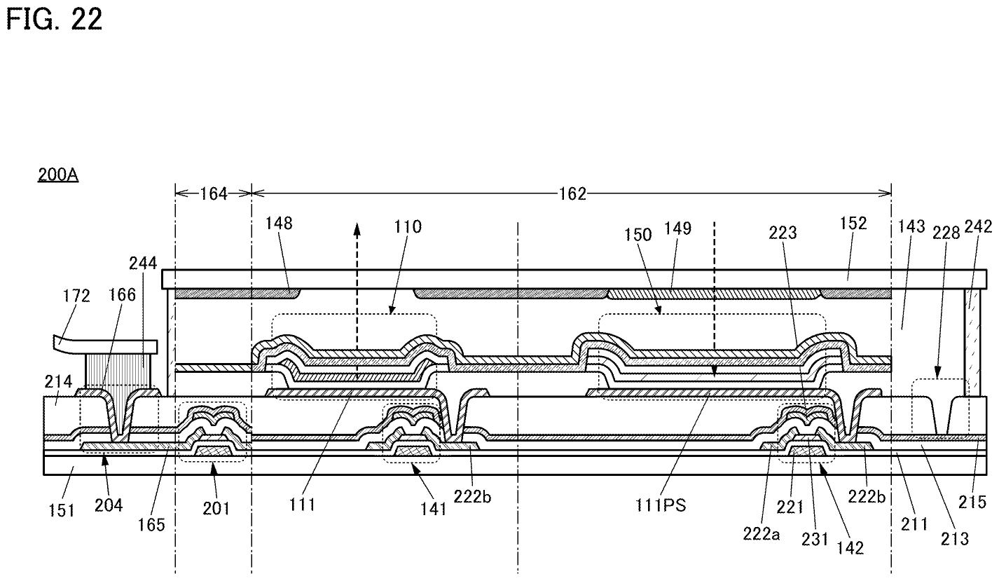

FIG. 22 is a diagram illustrating an example of cross sections of part of a region including the FPC 172, part of a region including the circuit 164, part of a region including the display portion 162, and part of a region including an end portion in the display apparatus 200 illustrated in FIG. 21. Note that the display apparatus 200 illustrated in FIG. 22 is a display apparatus 200A.

The display apparatus 200A includes a transistor 201, a transistor 141, a transistor 142, the light-emitting device 110, the light-receiving device 150, and the like between the substrate 151 and the substrate 152.

The substrate 152 and an insulating layer 214 are attached to each other with an adhesive layer 242. A solid sealing structure, a hollow sealing structure, or the like can be employed to seal the light-emitting device 110 and the light-receiving device 150. A hollow sealing structure is employed in which a space 143 surrounded by the substrate 152, the adhesive layer 242, and the insulating layer 214 is filled with an inert gas (nitrogen, argon, or the like). The adhesive layer 242 may be provided to overlap with the light-emitting device 110. In addition, a region surrounded by the substrate 152, the adhesive layer 242, and the insulating layer 214 may be filled with a resin different from that of the adhesive layer 242.

The electrode 111 included in the light-emitting device 110 is electrically connected to a conductive layer 222b included in the transistor 142 through an opening provided in the insulating layer 214. The transistor 142 has a function of controlling the driving of the light-emitting device 110. An electrode 111PS included in the light-receiving device 150 is electrically connected to the conductive layer 222b included in the transistor 141 through an opening provided in the insulating layer 214.

Light emitted by the light-emitting device 110 is emitted toward the substrate 152 side. Light is incident on the light-receiving device 150 through the substrate 152 and the space 143. For the substrate 152, a material having a high transmitting property with respect to visible light and infrared light is preferably used.

A light-blocking layer 148 is provided on a surface of the substrate 152 on the substrate 151 side. The light-blocking layer 148 has an opening in the position overlapping with the light-receiving device 150 and an opening in the position overlapping with the light-emitting device 110. A filter 149 that filters out ultraviolet light is provided in a position overlapping with the light-receiving device 150. Note that a structure without the filter 149 can be employed.

The transistor 201, the transistor 141, and the transistor 142 are all formed over the substrate 151. These transistors can be manufactured using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material into which impurities such as water and hydrogen are less likely to diffuse is preferably used for at least one of the insulating layers that cover the transistors. This allows the insulating layer to serve as a barrier layer. Such a structure can effectively inhibit diffusion of impurities into the transistors from the outside and increase the reliability of a display apparatus.

An inorganic insulating film is preferably used for the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. A stack including two or more of the above insulating films may also be used.

An organic insulating film is preferably used for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property against impurities than an inorganic insulating film. Therefore, the organic insulating film preferably has an opening in the vicinity of an end portion of the display apparatus 200A. This can inhibit diffusion of impurities from the end portion of the display apparatus 200A through the organic insulating film. Alternatively, in order to prevent the organic insulating film from being exposed at the end portion of the display apparatus 200A, the organic insulating film may be formed so that its end portion is positioned inward from the end portion of the display apparatus 200A.

In a region 228 illustrated in FIG. 22, an opening is formed in the insulating layer 214. This can inhibit diffusion of impurities into the display portion 162 from the outside through the insulating layer 214 even when an organic insulating film is used as the insulating layer 214. Thus, the reliability of the display apparatus 200A can be increased.

The transistor 201, the transistor 141, and the transistor 142 each include a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer where a channel is formed.

A structure in which the semiconductor layer where a channel is formed is sandwiched between the two gates is used for the transistor 201, the transistor 141, and the transistor 142. The two gates may be connected to each other and supplied with the same signal to drive the transistor. Alternatively, one of the two gates may be supplied with a potential for controlling the threshold voltage of the transistor and the other may be supplied with a potential for driving.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The semiconductor layer of the transistor preferably includes a metal oxide (also referred to as an oxide semiconductor). Alternatively, the semiconductor layer of the transistor may contain silicon. Examples of silicon include amorphous silicon and crystalline silicon (e.g., low-temperature polysilicon or single crystal silicon).

When the semiconductor layer contains a metal oxide, the metal oxide preferably contains at least indium or zinc as described above. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The transistors included in the circuit 164 and the transistors included in the display portion 162 may have either the same structure or different structures. One structure or two or more types of structures may be employed for a plurality of transistors included in the circuit 164. Similarly, one structure or two or more types of structures may be employed for a plurality of transistors included in the display portion 162.

A connection portion 204 is provided in a region that is over the substrate 151 and does not overlap with the substrate 152. In the connection portion 204, the wiring 165 is electrically connected to the FPC 172 through a conductive layer 166 and a connection layer 244. On the top surface of the connection portion 204, the conductive layer 166 obtained by processing the same conductive film as the electrode 111 is exposed. Thus, the connection portion 204 and the FPC 172 can be electrically connected to each other through the connection layer 244.

A variety of optical members can be arranged on an outer side of the substrate 152. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 152.

Glass, quartz, ceramic, sapphire, a resin, or the like can be used for the substrate 151 and the substrate 152.

As the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet or the like may be used.

As the connection layer 244, an anisotropic conductive film (ACF), an anisotropic conductive paste (ACP), or the like can be used.

As materials that can be used for conductive layers such as a variety of wirings and electrodes that constitute a display apparatus, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A film containing these materials can be used as a single-layer structure or a stacked-layer structure.

As a light-transmitting conductive material, a conductive oxide such as indium oxide, indium tin oxide, indium zinc oxide, zinc oxide, or zinc oxide containing gallium can be used or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is made thin enough to have a light-transmitting property. A stacked film of any of the above materials can be used as a conductive layer. For example, a stacked-layer film of indium tin oxide and an alloy of silver and magnesium, or the like is preferably used for increased conductivity. They can also be used for conductive layers such as a variety of wirings and electrodes that constitute a display apparatus, and conductive layers (conductive layers functioning as a pixel electrode or a common electrode) included in a display element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### Structure Example 2

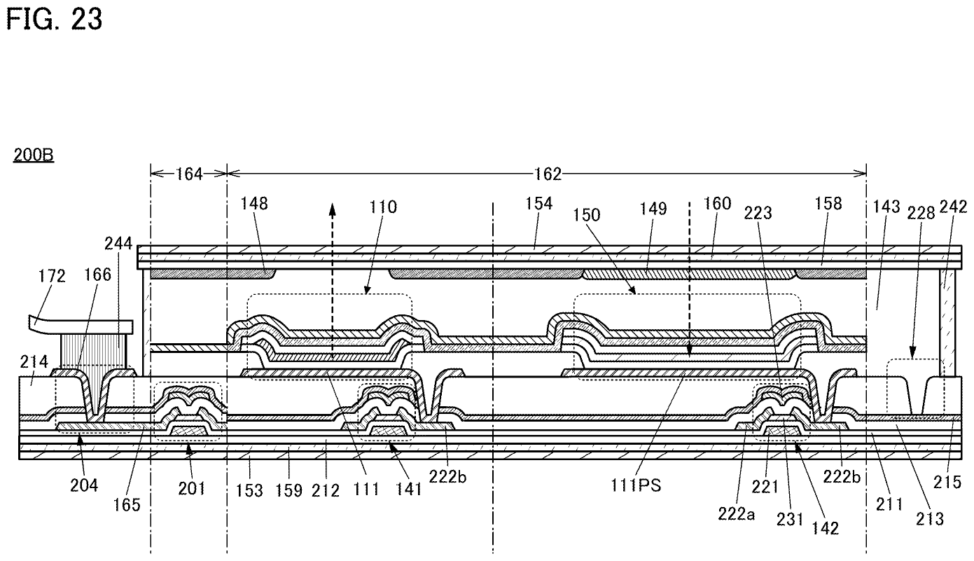

FIG. 23 is a cross-sectional view illustrating a structure example of a display apparatus 200B and is a modification example of the display apparatus 200A. The display apparatus 200B differs from the display apparatus 200A in that a substrate 153 instead of the substrate 151, an adhesive layer 159, and an insulating layer 212 are included and that a substrate 154 instead of the substrate 152, an adhesive layer 160, and an insulating layer 158 are included.

In the display apparatus 200B, the substrate 153 and the insulating layer 212 are bonded to each other with the adhesive layer 159. In addition, the substrate 154 and the insulating layer 158 are bonded to each other with the adhesive layer 160.

When the display apparatus 200B illustrated in FIG. 23 is manufactured, first, a first manufacture substrate provided with the insulating layer 212, each transistor, the light-emitting device 110, the light-receiving device 150, and the like and a second manufacture substrate provided with the insulating layer 158, the light-blocking layer 148, the filter 149, and the like are bonded to each other with the adhesive layer 242. Then, the substrate 153 is bonded to a surface where the first manufacture substrate is separated and exposed with the adhesive layer 159. Accordingly, each component formed over the first manufacture substrate is transferred onto the substrate 153. In addition, the substrate 154 is bonded to a surface where the second manufacture substrate is separated and exposed with the adhesive layer 160. Accordingly, each component formed over the second manufacture substrate is transferred onto the substrate 154. The substrate 153 and the substrate 154 are preferably flexible. Thus, the display apparatus 200B can be flexible. That is, the display apparatus 200B can be a flexible display.

The inorganic insulating film that can be used for the insulating layer 211, the insulating layer 213, and the insulating layer 215 can be used for the insulating layer 212 and the insulating layer 158.

### Structure Example 3

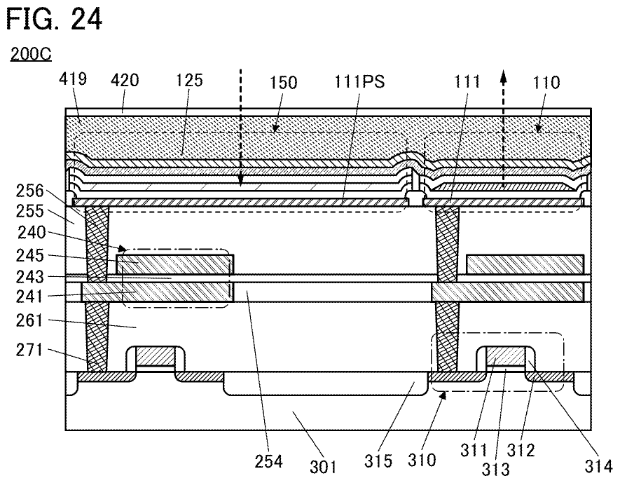

FIG. 24 is a cross-sectional view illustrating a structure example of a display apparatus 200C. The display apparatus 200C includes a substrate 301, the light-emitting device 110, the light-receiving device 150, a capacitor 240, and a transistor 310. The substrate 301 corresponds to the substrate 151 in FIG. 21 and the like.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to the source or the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the light-emitting device 110, the light-receiving device 150, and the like are provided over the insulating layer 255. The protective layer 125 is provided over the light-emitting device 110 and the light-receiving device 150, and a substrate 420 is bonded to the top surface of the protective layer 125 with a resin layer 419. The substrate 420 corresponds to the substrate 152 in FIG. 21 and the like.

The electrode 111 of the light-emitting device 110 and the electrode 111PS of the light-receiving device 150 are electrically connected to the source or the drain of the transistor 310 through a plug 256 embedded in the insulating layer 255, the conductive layer 241 embedded in the insulating layer 254, and the plug 271 embedded in the insulating layer 261.

### Structure Example 4

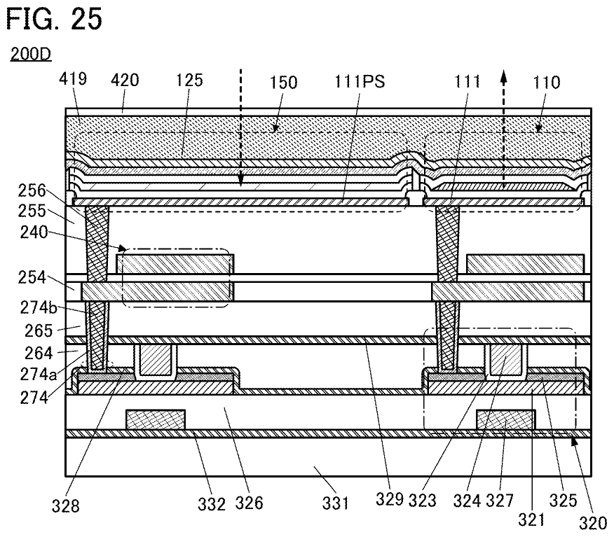

FIG. 25 is a cross-sectional view illustrating a structure example of a display apparatus 200D. The display apparatus 200D differs from the display apparatus 200C mainly in a transistor structure. Note that portions similar to those of the display apparatus 200C are not described in some cases.

A transistor 320 is a transistor that contains a metal oxide in a semiconductor layer where a channel is formed (also referred to as an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 151 in FIG. 21 and the like. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. For the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics is preferably used as the semiconductor layer 321. A material that can be suitably used for the semiconductor layer 321 will be described in detail later.

The pair of conductive layers 325 are provided on and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water or hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material through which hydrogen and oxygen are less likely to diffuse is preferably used for the conductive layer 274a.

The structures of the insulating layer 254 and the components thereover up to the substrate 420 in the display apparatus 200D are similar to those in the display apparatus 200C.

### Structure Example 5

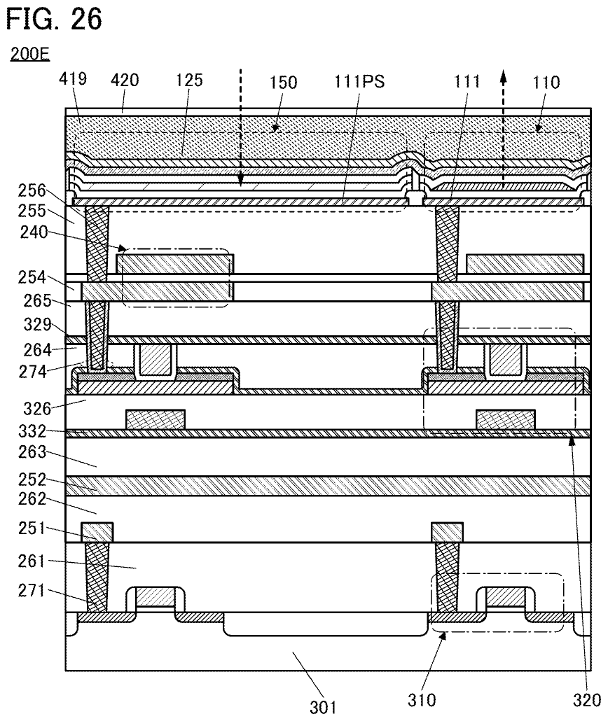

FIG. 26 is a cross-sectional view illustrating a structure example of a display apparatus 200E. The display apparatus 200E has a structure in which the transistor 310 whose channel is formed in the substrate 301 and the transistor 320 including a metal oxide in the semiconductor layer where the channel is formed are stacked. Note that the description of portions similar to those in the display apparatus 200C or the display apparatus 200D is omitted in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit for driving the pixel circuit (a gate line driver circuit or a source line driver circuit). Furthermore, the transistor 310 and the transistor 320 can be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display portion.

Note that the lay apparatus 200C, the display apparatus 200D, and the display apparatus 200E can be flexible like the display apparatus 200B.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 3

In this embodiment, a light-emitting device that can be used in the display apparatus of one embodiment of the present invention is described.

### <Structure Example of Light-Emitting Device>

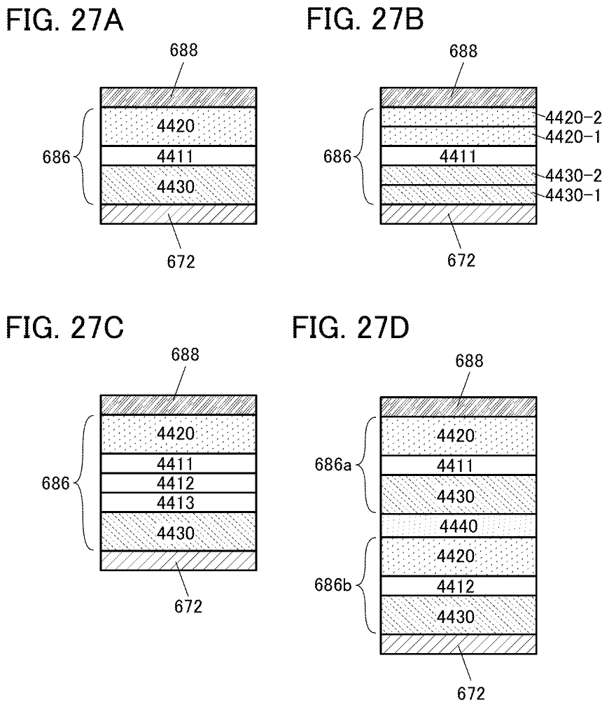

As illustrated in FIG. 27A, a light-emitting device includes an EL layer 686 between a pair of electrodes (an electrode 672 and an electrode 688). The EL layer 686 can be formed of a plurality of layers such as a layer 4420, a light-emitting layer 4411, and a layer 4430. The layer 4420 can include, for example, a layer containing a substance having a high electron-injection property (an electron-injection layer) and a layer containing a substance having a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between the pair of electrodes, can serve as a single light-emitting unit, and the structure in FIG. 27A is referred to as a single structure in this specification.

FIG. 27B is a modification example of the EL layer 686 included in the light-emitting device illustrated in FIG. 27A. Specifically, the light-emitting device illustrated in FIG. 27B includes a layer 4430-1 over the electrode 672, a layer 4430-2 over the layer 4430-1, the light-emitting layer 4411 over the layer 4430-2, a layer 4420-1 over the light-emitting layer 4411, a layer 4420-2 over the layer 4420-1, and the electrode 688 over the layer 4420-2. For example, in the case where the electrode 672 is an anode and the electrode 688 is a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the electrode 672 is as a cathode and the electrode 688 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 27C is a variation of the single structure.

The structure in which a plurality of light-emitting units (an EL layer 686a and an EL layer 686b) are connected in series with an intermediate layer (charge-generation layer) 4440 therebetween as illustrated in FIG. 27D is referred to as a tandem structure in this specification. Note that in this specification and the like, the structure illustrated in FIG. 27D is referred to as a tandem structure; however, without being limited to this, a tandem structure may be referred to as a stack structure, for example. The tandem structure enables a light-emitting device capable of high-luminance light emission.

In FIG. 27C and FIG. 27D, the layer 4420 and the layer 4430 may each have a stacked-layer structure of two or more layers as illustrated in FIG. 27B.

A structure in which light emission colors (here, blue (B), green (G), and red (R)) are separately formed for the light-emitting devices is referred to as an SBS (Side By Side) structure in some cases.

In the case where the single structure and the tandem structure described above and the SBS structure are compared with each other, the SBS structure, the tandem structure, and the single structure have lower consumption in this order. To reduce power consumption, the SBS structure is preferably used. Meanwhile, the single structure and the tandem structure are preferable in terms of lower manufacturing cost or higher manufacturing yield because the manufacturing processes for the single structure and the tandem structure are simpler than that for the SBS structure.

The emission colors of the light-emitting devices can be changed to red, green, blue, cyan, magenta, yellow, white, or the like depending on a material of the EL layer 686. Furthermore, the color purity can be further increased when the light-emitting device has a microcavity structure.

The light-emitting device that emits white light preferably contains two or more kinds of light-emitting substances in the light-emitting layer. To obtain white light emission, two kinds of light-emitting substances are selected so that their emission colors have a relationship of complementary colors. For example, when emission colors of a first light-emitting layer and a second light-emitting layer are complementary colors, the light-emitting device as a whole can be configured to emit white light. When three or more kinds of light-emitting substances are used, the light-emitting device is configured to emit white light as a whole by combining their emission colors. The same applies to a light-emitting device including three or more light-emitting layers.

The light-emitting layer preferably contains two or more selected from light-emitting substances that emit light of red (R), green (G), blue (B), yellow (Y), orange (O), and the like. Alternatively, a light-emitting layer preferably contains two or more light-emitting substances each of which emits light containing two or more of spectral components of R, G, and B.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 4

In this embodiment, a structure of a light-emitting and light-receiving device that can be used in a display apparatus of one embodiment of the present invention is described. The structure can be the one in which a light-emitting and light-receiving device is added to the above-described display apparatus. Alternatively, the structure can be the one in which the light-receiving device is replaced with a light-emitting and light-receiving device. The display apparatus of one embodiment of the present invention can have a structure including a light-emitting device, a light-receiving device, and a light-emitting and light-receiving device. Alternatively, the display apparatus of one embodiment of the present invention can have a structure including a light-emitting device and a light-emitting and light-receiving device.

The light-emitting and light-receiving device has a light-emitting function and a light-receiving function. Here, a light-emitting and light-receiving device that emits red light and has a light-receiving function is described as an example. Note that for a method for manufacturing the light-emitting and light-receiving device, the above description of the method for manufacturing a light-receiving device can be referred to, and thus detailed description is omitted. Alternatively, for the method for manufacturing the light-emitting and light-receiving device, the above description of the method for manufacturing a light-emitting device can be referred to, and thus detailed description is omitted.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, a top-emission display apparatus is described as an example.

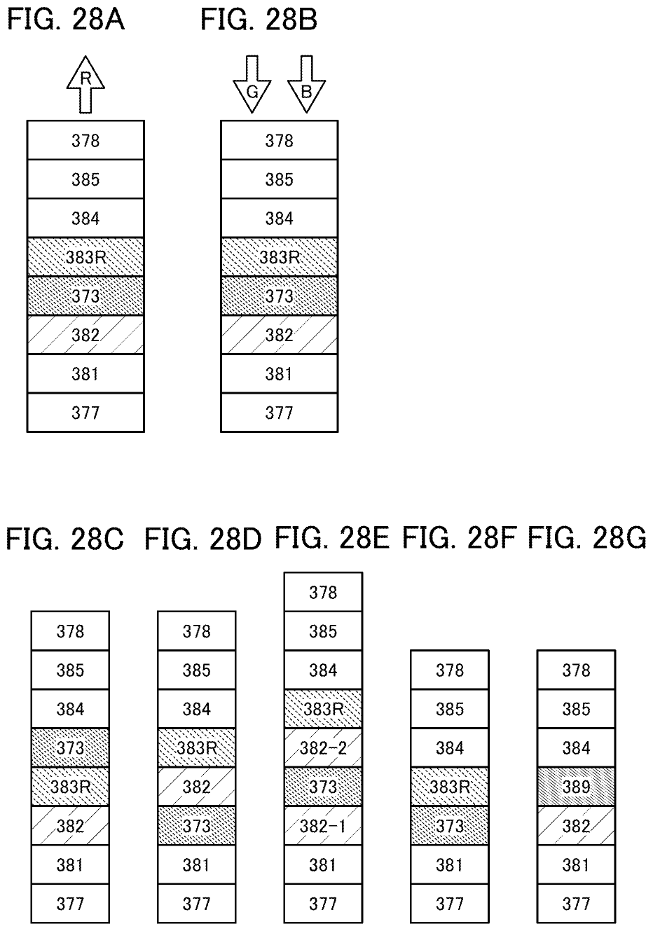

A light-emitting and light-receiving device illustrated in FIG. 28A includes an electrode 377, a hole-injection layer 381, a hole-transport layer 382, an active layer 373, a light-emitting layer 383R, an electron-transport layer 384, an electron-injection layer 385, and an electrode 378 that are stacked in this order.

The light-emitting layer 383R includes a light-emitting material that emits red light. The active layer 373 contains an organic compound that absorbs visible light. Alternatively, the active layer 373 may contain an organic compound that absorbs visible light and infrared light. Alternatively, the active layer 373 may contain an organic compound that absorbs visible light and an organic compound that absorbs infrared light. Note that it is preferable that the organic compound contained in the active layer 373 hardly absorbs at least light emitted by the light-emitting layer 383R. Thus, red light can be efficiently extracted from the light-emitting and light-receiving device, and one or more of light having a shorter wavelength than red light (e.g., green light and blue light) and light having a longer wavelength than red light (e.g., infrared light) can be detected with high accuracy.

FIG. 28A schematically shows that the light-emitting and light-receiving device functions as a light-emitting device. In FIG. 28A, red (R) light emitted from the light-emitting and light-receiving device is indicated by an arrow.

FIG. 28B schematically shows that the light-emitting and light-receiving device functions as a light-receiving device. In FIG. 28B, blue light (B) and green light (G) that are incident on the light-emitting and light-receiving device are indicated by arrows.

When voltage is applied between the electrode 377 and the electrode 378 in the light-emitting and light-receiving device, light incident on the light-emitting and light-receiving device can be detected and charge can be generated and extracted as current.

The light-emitting and light-receiving device can be regarded as having a structure of a light-emitting device to which the active layer 373 is added. That is, the light-emitting and light-receiving device can be formed concurrently with formation of a light-emitting device only by adding a step of depositing the active layer 373 in the manufacturing process of the light-emitting device. The light-emitting device and the light-emitting and light-receiving device can be formed over the same substrate. Thus, one or both of an image capturing function and a sensing function can be provided to the display portion without a significant increase in the number of manufacturing steps.

The stacking order of the light-emitting layer 383R and the active layer 373 is not limited. In the example illustrated in FIG. 28A and FIG. 28B, the active layer 373 is provided over the hole-transport layer 382, and the light-emitting layer 383R is provided over the active layer 373. The stacking order of the light-emitting layer 383R and the active layer 373 may be reversed, for example.

The light-emitting and light-receiving device may exclude at least one of the hole-injection layer 381, the hole-transport layer 382, the electron-transport layer 384, and the electron-injection layer 385. Furthermore, the light-emitting and light-receiving device may include another functional layer such as a hole-blocking layer or an electron-blocking layer.

In the light-emitting and light-receiving device, a conductive film that transmits visible light is used as the electrode through which light is extracted. A conductive film that reflects visible light is preferably used as the electrode through which light is not extracted.

The functions and materials of the layers constituting the light-emitting and light-receiving device are similar to those of the layers constituting the light-emitting devices and the light-receiving device and not described in detail here.

FIG. 28C to FIG. 28G illustrate examples of a stacked-layer structure of the light-emitting and light-receiving device.

A light-emitting and light-receiving device illustrated in FIG. 28C includes the electrode 377, the hole-injection layer 381, the hole-transport layer 382, the light-emitting layer 383R, the active layer 373, the electron-transport layer 384, the electron-injection layer 385, and the electrode 378.

In the example illustrated in FIG. 28C, the light-emitting layer 383R is provided over the hole-transport layer 382, and the active layer 373 is stacked over the light-emitting layer 383R.

As illustrated in FIG. 28A to FIG. 28C, the active layer 373 and the light-emitting layer 383R may be in contact with each other.

A buffer layer is preferably provided between the active layer 373 and the light-emitting layer 383R. In that case, the buffer layer preferably has a hole-transport property and an electron-transport property. For example, a bipolar substance is preferably used for the buffer layer. Alternatively, as the buffer layer, at least one of a hole-injection layer, a hole-transport layer, an electron-transport layer, an electron-injection layer, a hole-blocking layer, an electron-blocking layer, and the like can be used. FIG. 28D illustrates an example where the hole-transport layer 382 is used as the buffer layer.

The buffer layer provided between the active layer 373 and the light-emitting layer 383R can inhibit transfer of excitation energy from the light-emitting layer 383R to the active layer 373. Furthermore, the optical path length (cavity length) of the microcavity structure can be adjusted with the buffer layer. Thus, a high emission efficiency can be obtained from the light-emitting and light-receiving device including the buffer layer between the active layer 373 and the light-emitting layer 383R.

FIG. 28E illustrates an example in which a hole-transport layer 382-1, the active layer 373, a hole-transport layer 382-2, and the light-emitting layer 383R are stacked in this order over the hole-injection layer 381. The hole-transport layer 382-2 functions as a buffer layer. The hole-transport layer 382-1 and a hole-transport layer 281-2 may contain the same material or different materials. Instead of the hole-transport layer 281-2, any of the above layers that can be used as the buffer layer may be used. The positions of the active layer 373 and the light-emitting layer 383R may be interchanged.

The light-emitting and light-receiving device illustrated in FIG. 28F differs from the light-emitting and light-receiving device illustrated in FIG. 28A in not including the hole-transport layer 382. Thus, the light-emitting and light-receiving device may exclude at least one of the hole-injection layer 381, the hole-transport layer 382, the electron-transport layer 384, and the electron-injection layer 385. Furthermore, the light-emitting and light-receiving device may include another functional layer such as a hole-blocking layer or an electron-blocking layer.

The light-emitting and light-receiving device illustrated in FIG. 28G differs from the light-emitting and light-receiving device illustrated in FIG. 28A in including a layer 389 serving as both a light-emitting layer and an active layer instead of including the active layer 373 and the light-emitting layer 383R.

As the layer serving as both a light-emitting layer and an active layer, a layer containing three materials which are an n-type semiconductor that can be used for the active layer 373, a p-type semiconductor that can be used for the active layer 373, and a light-emitting substance that can be used for the light-emitting layer 383R can be used, for example.

An absorption band on the lowest energy side of an absorption spectrum of a mixed material of the n-type semiconductor and the p-type semiconductor and a maximum peak of an emission spectrum (PL spectrum) of the light-emitting substance preferably do not overlap with each other and are further preferably positioned fully apart from each other.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### Embodiment 5

Described in this embodiment is a metal oxide that can be used in an OS transistor described in the above embodiment.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structures>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

A crystal structure of a film or a substrate can be analyzed with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction method (NBED) (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 20) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, or the like.

A crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, or the like, the CAAC-OS can be regarded as an oxide semiconductor that has a small amount of impurities and defects (e.g., oxygen vacancies). Hence, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Hence, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions randomly exist to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of the oxygen gas to the total flow rate of the deposition gas in deposition is preferably as low as possible; for example, the ratio of the flow rate of the oxygen gas to the total flow rate of the deposition gas in deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide as a cloud, high field-effect mobility (u) can be achieved.

The second region has a higher insulating property than the first region. In other words, when the second regions are distributed in a metal oxide, a leakage current can be inhibited.

Thus, in the case where the CAC-OS is used for a transistor, a switching function (On/Off switching function) can be given to the CAC-OS owing to the complementary action of the conductivity derived from the first region and the insulating property derived from the second region. A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and excellent switching operation can be achieved.

A transistor using a CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration measured by secondary ion mass spectrometry (SIMS)) are lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 6

In this embodiment, electronic devices each including a display apparatus of one embodiment of the present invention are described.

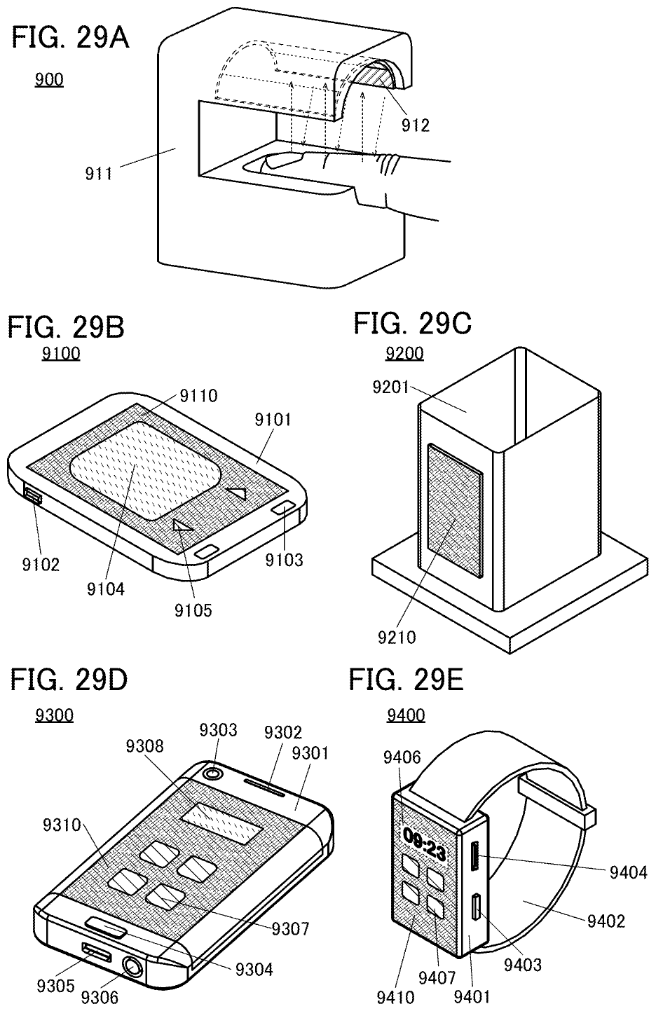

The display apparatus of one embodiment of the present invention can be provided in a variety of electronic devices. For example, the display apparatus of one embodiment of the present invention can be provided in a digital camera, a digital video camera, a digital photo frame, a portable game machine, a portable information terminal, an audio reproducing device, or the like, in addition to an electronic device with a comparatively large screen, such as a television device, a desktop or laptop computer, a tablet computer, a monitor for a computer or the like, digital signage, or a large game machine such as a pachinko machine. Structure examples of electronic device in which the display apparatus of one embodiment of the present invention can be provided are described with reference to FIG. 29A to FIG. 29E.

FIG. 29A is a diagram illustrating an example of an oximeter 900. The oximeter 900 includes a housing 911 and a light-emitting and receiving device 912. The housing 911 is provided with a cavity portion, and the light-emitting and receiving device 912 is provided to be in contact with a wall surface of the cavity portion.

The light-emitting and receiving device 912 has a function of a light source that emits light and a function of a sensor that detects light. For example, in the case where a target is put in the cavity portion of the housing 911, light that is emitted by the light-emitting and receiving device 912, irradiates the target, and is reflected by the target can be detected by the light-emitting and receiving device 912.

For example, in the case where a finger is put in the cavity portion of the housing 911, the color of blood is changed depending on oxygen saturation of hemoglobin contained in the blood (the percentage of oxygen-bound hemoglobin). Thus, the intensity of light reflected by the finger that is detected by the light-emitting and receiving device 912 is changed. For example, the intensity of red light that is detected by the light-emitting and receiving device 912 is changed. Accordingly, the oximeter 900 can measure oxygen saturation through detection of the intensity of reflected light by the light-emitting and receiving device 912. The oximeter 900 can be a pulse oximeter, for example.

The display apparatus of one embodiment of the present invention can be employed in the light-emitting and receiving device 912. In this case, the light-emitting and receiving device 912 includes at least a light-emitting device that emits red light (R). In addition, the light-emitting and receiving device 912 preferably includes a light-emitting device that emits infrared light (IR). There is a large difference between the red light (R) reflectance of oxygen-bound hemoglobin and the red light (R) reflectance of oxygen-unbound hemoglobin. On the other hand, there is a small difference between the infrared light (IR) reflectance of oxygen-bound hemoglobin and the infrared light (IR) reflectance of oxygen-unbound hemoglobin. 1. Therefore, the light-emitting and receiving device 912 includes not only a light-emitting device that emits red light (R) but also a light-emitting device that emits infrared light (IR), so that the oximeter 900 can measure oxygen saturation with high accuracy.

In the case where the display apparatus of one embodiment of the present invention is employed as the light-emitting and receiving device 912, the light-emitting and receiving device 912 is preferably flexible. When the light-emitting and receiving device 912 is flexible, the light-emitting and receiving device 912 can have a curved shape. Accordingly, the finger or the like can be irradiated with light uniformly, and oxygen saturation or the like can be measured with high accuracy.

FIG. 29B is a diagram illustrating an example of a portable data terminal 9100. The portable data terminal 9100 includes a display portion 9110, a housing 9101, a key 9102, a speaker 9103, and the like. The portable data terminal 9100 can be a tablet, for example. Here, the key 9102 can be a key for switching the on/off of a power source, for example. That is, the key 9102 can be a power switch, for example. Alternatively, the key 9102 can be an operation key to be used to make an electronic device perform a desired operation, for example.

The display portion 9110 can display information 9104, operation buttons (also referred to as operation icons or simply icons) 9105, and the like.

When the display apparatus of one embodiment of the present invention is provided in the portable data terminal 9100, the display portion 9110 can have a function of a touch sensor or a near-touch sensor.

FIG. 29C is a diagram illustrating an example of digital signage 9200. The digital signage 9200 can have a structure where a display portion 9210 is attached to a column 9201.

When the display apparatus of one embodiment of the present invention is provided in the digital signage 9200, the display portion 9210 can have a function of a touch sensor or a near-touch sensor.

FIG. 29D is a diagram illustrating an example of a portable information terminal 9300. The portable information terminal 9300 includes a display portion 9310, a housing 9301, a speaker 9302, a camera 9303, a key 9304, a connection terminal 9305, a connection terminal 9306, and the like. For example, the portable information terminal 9300 can be a smartphone. Note that the connection terminal 9305 can be a micro USB terminal, a lightning terminal, or a Type-C terminal, or the like, for example. In addition, the connection terminal 9306 can be an earphone jack, for example.

The display portion 9310 can display, for example, an operation button 9307. The display portion 9310 can also display information 9308. Examples of the information 9308 include display indicating incoming e-mails, SNS (social networking services), phone calls, and the like; the titles of e-mails, SNS, and the like; the senders of e-mails, SNS, and the like; dates; time; remaining battery; the reception strength of an antenna; and the like.

When the display apparatus of one embodiment of the present invention is provided in the portable information terminal 9300, the display portion 9310 can have a function of a touch sensor or a near-touch sensor.

FIG. 29E is a diagram illustrating an example of a wristwatch-type portable information terminal 9400. The portable information terminal 9400 includes a display portion 9410, a housing 9401, a wristband 9402, a key 9403, a connection terminal 9404, and the like. Note that the connection terminal 9404 can be a micro USB terminal, a lightning terminal, or a Type-C terminal, or the like, for example, like the connection terminal 9305 or the like.

The display portion 9410 can display information 9406, operation buttons 9407, and the like. FIG. 29E illustrates an example in which time is displayed on the display portion 9410 as the information 9406.

When the display apparatus of one embodiment of the present invention is provided in the portable information terminal 9400, the display portion 9410 can have a function of a touch sensor or a near-touch sensor.

At least part of the structure examples, the drawings corresponding thereto, and the like illustrated in this embodiment can be combined with the other structure examples, the other drawings, and the like as appropriate.

At least part of this embodiment can be implemented in combination with the other embodiments described in this specification as appropriate.

### REFERENCE NUMERALS

20B: light-emitting device, 20G: light-emitting device, 20R: light-emitting device, 20: light-emitting device, 21a: electrode, 21b: electrode, 21c: electrode, 21d: electrode, 23: electrode, 25B: EL layer, 25G: EL layer, 25R: EL layer, 25: EL layer, 27a: first layer, 27b: first layer, 27c: first layer, 27: first layer, 29a: second layer, 29b: second layer, 29c: second layer, 29: second layer, 30PS: light-receiving device, 35PS: light-receiving layer, 37PS: third layer, 39PS: fourth layer, 41B: light-emitting layer, 41G: light-emitting layer, 41R: light-emitting layer, 43PS: active layer, 50: substrate, 52: finger, 53: layer, 57: layer, 59: substrate, 65: region, 67: fingerprint, 69: contact portion, 100A: display apparatus, 100B: display apparatus, 100C: display apparatus, 100: display apparatus, 101: substrate, 103: pixel, 110B: light-emitting device, 110G: light-emitting device, 110R: light-emitting device, 110: light-emitting device, 111a: electrode, 111b: electrode, 111c: electrode, 111d: electrode, 111p: connection electrode, 111PS: electrode, 111: electrode, 112B: light-emitting layer, 112G: light-emitting layer, 112R: light-emitting layer, 112: light-emitting layer, 115a: first layer, 115b: first layer, 115c: first layer, 115d: first layer, 115f: functional film, 115p: first layer, 115: first layer, 116a: second layer, 116b: second layer, 116c: second layer, 116d: second layer, 116f: functional film, 116p: second layer, 116: second layer, 118a: sacrificial layer, 118b: sacrificial layer, 118c: sacrificial layer, 118f: sacrificial film, 118: sacrificial layer, 119a: sacrificial layer, 119b: sacrificial layer, 119c: sacrificial layer, 119f: sacrificial film, 119: sacrificial layer, 120B: subpixel, 120G: subpixel, 120R: subpixel, 123f: conductive layer, 123: common electrode, 125: protective layer, 128f: sacrificial film, 128p: sacrificial layer, 128: sacrificial layer, 129f: sacrificial film, 129p: sacrificial layer, 129: sacrificial layer, 130: subpixel, 131: insulating layer, 133p: resist mask, 133: resist mask, 134a: resist mask, 134b: resist mask, 134c: resist mask, 134: resist mask, 135: resist mask, 140: connection portion, 141: transistor, 142: transistor, 143: space, 148: light-blocking layer, 149: filter, 150: light-receiving device, 151B: FMM, 151G: FMM, 151R: FMM, 151: substrate, 152: substrate, 153: substrate, 154: substrate, 155f: functional film, 155: third layer, 156f: functional film, 156: fourth layer, 157f: active film, 157: active layer, 158: insulating layer, 159: adhesive layer, 160: adhesive layer, 162: display portion, 164: circuit, 165: wiring, 166: conductive layer, 172: FPC, 173: IC, 175B: EL layer, 175G: EL layer, 177: light-receiving layer, 180a: optical adjustment layer, 180b: optical adjustment layer, 180c: optical adjustment layer, 180d: optical adjustment layer, 180p: conductive layer, 182f: insulating film, 182: insulating layer, 184: resin layer, 200A: display apparatus, 200B: display apparatus, 200C: display apparatus, 200D: display apparatus, 200E: display apparatus, 200: display apparatus, 201: transistor, 204: connection portion, 211: insulating layer, 212: insulating layer, 213: insulating layer, 214: insulating layer, 215: insulating layer, 221: conductive layer, 222a: conductive layer, 222b: conductive layer, 223: conductive layer, 228: region, 231: semiconductor layer, 240: capacitor, 241: conductive layer, 242: adhesive layer, 243: insulating layer, 244: connection layer, 245: conductive layer, 251: conductive layer, 252: conductive layer, 254: insulating layer, 255: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 301: substrate, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 373: active layer, 377: electrode, 378: electrode, 381: hole-injection layer, 382: hole-transport layer, 383R: light-emitting layer, 384: electron-transport layer, 385: electron-injection layer, 389: layer, 419: resin layer, 420: substrate, 672: electrode, 686a: EL layer, 686b: EL layer, 686: EL layer, 688: electrode, 911: housing, 912: light-emitting and receiving device, 4411: light-emitting layer, 4412: light-emitting layer, 4413: light-emitting layer, 4420: layer, 4430: layer, 9100: portable data terminal, 9101: housing, 9102: key, 9103: speaker, 9104: information, 9110: display portion, 9200: digital signage, 9201: column, 9210: display portion, 9300: portable information terminal, 9301: housing, 9302: speaker, 9303: camera, 9304: key, 9305: connection terminal, 9306: connection terminal, 9307: operation button, 9308: information, 9310: display portion, 9400: portable information terminal, 9401: housing, 9402: wristband, 9403: key, 9404: connection terminal, 9406: information, 9407: operation button, 9410: display portion

1. A display apparatus comprising:
a light-receiving device; and
a first light-emitting device,
wherein the light-receiving device comprises a first electrode, a light-receiving layer, and a common electrode that are stacked in this order,
wherein the first light-emitting device comprises a second electrode, a first EL layer, and the common electrode that are stacked in this order,
wherein the light-receiving layer comprises a first layer, a second layer, and an active layer between the first layer and the second layer,
wherein the first layer comprises a first substance having a hole-transport property, wherein the second layer comprises a second substance having an electron-transport property,
wherein an end portion of the active layer, an end portion of the first layer, and an end portion of the second layer are aligned or substantially aligned with one another,
wherein the first EL layer comprises a third layer, a fourth layer, and a first light-emitting layer between the third layer and the fourth layer,
wherein the third layer comprises a third substance having a hole-transport property,
wherein the fourth layer comprises a fourth substance having an electron-transport property, and
wherein an end portion of the first light-emitting layer is positioned inward from an end portion of the third layer and positioned inward from an end portion of the fourth layer.

2. The display apparatus according to claim 1,
wherein the active layer comprises a region overlapping with the first electrode with the first layer therebetween.

3. The display apparatus according to claim 1,
wherein the active layer comprises a region overlapping with the first electrode with the second layer therebetween.

4. The display apparatus according to claim 1,
wherein the first light-emitting layer comprises a region overlapping with the second electrode with the third layer therebetween.

5. The display apparatus according to claim 1,
wherein the first light-emitting layer comprises a region overlapping with the second electrode with the fourth layer therebetween.

6. The display apparatus according to claim 1,
wherein the end portion of the third layer and the end portion of the fourth layer are aligned or substantially aligned with each other.

7. The display apparatus according to claim 1,
wherein the first substance differs from the third substance.

8. The display apparatus according to claim 1,
wherein the second substance differs from the fourth substance.

9. The display apparatus according to claim 1;
wherein the active layer comprises a fifth substance, and
wherein the first light-emitting layer comprises a sixth substance differing from the fifth substance.

10. The display apparatus according to claim 9, further comprising a second light-emitting device,
wherein the second light-emitting device comprises a third electrode, a second EL layer, and the common electrode that are stacked in this order, and
wherein the second EL layer comprises the third layer, the fourth layer, and a second light-emitting layer between the third layer and the fourth layer.

11. The display apparatus according to claim 9, further comprising a second light-emitting device,
wherein the second light-emitting device comprises a third electrode, a second EL layer, and the common electrode that are stacked in this order,
wherein the second EL layer comprises a fifth layer, a sixth layer, and a second light-emitting layer between the fifth layer and the sixth layer,
wherein the fifth layer comprises the third substance, and
wherein the sixth layer comprises the fourth substance.

12. The display apparatus according to claim 10,
wherein the second light-emitting layer comprises a seventh substance differing from the sixth substance.

13. A method for manufacturing a display apparatus, comprising:
forming a first electrode and a second electrode;
forming a light-receiving film over the first electrode and the second electrode;
forming a first sacrificial layer having an island shape comprising a region overlapping with the first electrode, over the light-receiving film;
etching the light-receiving film using the first sacrificial layer as a mask to form a light-receiving layer and expose the second electrode;
forming a first functional film over the first sacrificial layer and the second electrode;
forming a light-emitting layer having an island shape comprising a region overlapping with the second electrode, over the first functional film, with the use of a metal mask;
forming a second functional film over the light-emitting layer and the first functional film;
forming a second sacrificial layer having an island shape comprising a region overlapping with the light-emitting layer, over the second functional film;
etching the first functional film and the second functional film using the second sacrificial layer as a mask to form a first functional layer and a second functional layer and expose the first sacrificial layer;
removing the first sacrificial layer and the second sacrificial layer to expose the light-receiving layer and the second functional layer; and
forming a common electrode over the light-receiving layer and the second functional layer,
wherein the first functional layer comprises a substance having a hole-transport property, and
wherein the second functional layer comprises a substance having an electron-transport property.

14. A method for manufacturing a display apparatus, comprising:
forming a first electrode and a second electrode;
forming a light-receiving film over the first electrode and the second electrode;
forming a sacrificial layer having an island shape comprising a region overlapping with the first electrode, over the light-receiving film;
etching the light-receiving film using the sacrificial layer as a mask to form a light-receiving layer and expose the second electrode;
forming a first functional layer over the sacrificial layer and forming a second functional layer over the second electrode;
forming a light-emitting layer having an island shape comprising a region overlapping with the second electrode, over the second functional layer, with the use of a metal mask;
forming a third functional layer over the first functional layer and forming a fourth functional layer over the light-emitting layer;
removing the sacrificial layer to lift off the first functional layer and the third functional layer and expose the light-receiving layer; and
forming a common electrode over the light-receiving layer and the fourth functional layer,
wherein the second functional layer comprises a substance having a hole-transport property, and
wherein the fourth functional layer comprises a substance having an electron-transport property.

15. The display apparatus according to claim 11,
wherein the second light-emitting layer comprises a seventh substance differing from the sixth substance.
